(19) United States
(12) Patent Application Publication
(10) Pub. No.: US 2020/0203617 A1
(43) Pub. Date: Jun. 25, 2020

(54) ORGANIC ELECTROLUMINESCENT DEVICE, PREPARATION METHOD THEREOF AND DISPLAY APPARATUS

(71) Applicants: KunShan Go-Visionox Opto-Electronics Co., Ltd, Kunshan (CN); TSINGHUA UNIVERSITY, Beijing (CN)

(72) Inventors: Lian DUAN, Kunshan (CN); Xiaozeng SONG, Kunshan (CN); Dongdong ZHANG, Kunshan (CN); Jinbei WEI, Kunshan (CN)

(73) Assignees: KunShan Go-Visionox Opto-Electronics Co., Ltd, Kunshan (CN); TSINGHUA UNIVERSITY, Beijing (CN)

(21) Appl. No.: 16/804,329

(22) Filed: Feb. 28, 2020

Related U.S. Application Data
(63) Continuation of application No. PCT/CN2019/080623, filed on Mar. 29, 2019.

(30) Foreign Application Priority Data
Aug. 31, 2018 (CN) 201811012865.4

(51) Int. Cl. H01L 51/00

(52) U.S. Cl. CPC H01L 51/0058; H01L 51/0055; H01L 51/0054; H01L 51/0073; H01L 51/5016; H01L 51/0067; H01L 51/0072; H01L 51/008; H01L 51/007

(57) ABSTRACT

An organic electroluminescent device, a preparation method thereof, and a display apparatus. The organic electroluminescent device includes a light emitting layer, the light emitting layer includes a host material and a dye, and the host material is a triplet-triplet annihilation material, the dye includes a thermally activated delayed fluorescence material; a singlet energy level of the triplet-triplet annihilation material is greater than a singlet energy level of the thermally activated delayed fluorescence material; and a triplet energy level of the triplet-triplet annihilation material is smaller than a triplet energy level of the thermally activated delayed fluorescence material. The present application can overcome the defect of short device lifetime caused by high-energy excitons in the device at present.

### CROSS-REFERENCE TO RELATED APPLICATIONS

The present application is a continuation of International Application No. PCT/CN2019/080623, filed on Mar. 29, 2019, which claims priority to Chinese Patent Application No. 201811012865.4, filed on Aug. 31, 2018. The contents of the above identified applications are incorporated herein by reference in their entireties.

### FIELD

The present application relates to the field of organic electroluminescent technology, and in particular, to an organic electroluminescent device, a preparation method thereof, and a display apparatus.

### BACKGROUND

Organic light emitting diode (OLED) is a device for achieving the purpose of luminous display by current drive. When an appropriate voltage is applied, electrons and holes combine in a light emitting layer to generate excitons and emit light of different wavelengths according to characteristics of the light emitting layer. At this stage, the light emitting layer is composed of a host material and a doping dye, and the dye is mostly selected from conventional fluorescent materials and conventional phosphorescent materials. Specifically, the conventional fluorescent materials have the defect that triplet excitons cannot be used. Although conventional phosphorescent materials can achieve singlet exciton transition to triplet by doping a heavy metal, such as iridium or platinum, to achieve 100% energy use efficiency. However, heavy metals such as iridium and platinum are very scarce, expensive and easily cause environmental pollution, so phosphorescent materials cannot be a first choice for the dye.

Thermally activated delayed fluorescence (TADF) materials, compared with the conventional phosphorescent materials and the conventional fluorescent materials, can realize reverse intersystem crossing from the triplet excitons to the singlet by absorbing ambient heat, and then emit fluorescence from the singlet, thereby achieving 100% utilization of excitons without the aid of any heavy metals. Therefore, currently, 100% energy use efficiency is mainly achieved by doping a host material with a TADF material.

However, due to a small energy level difference between singlet and triplet of the TADF material, the triplet excitons of the TADF material have generally high energy level. In order to prevent energy from being transmitted back to the host, the triplet and singlet energy levels of the host material of the TADF device will be higher than those of the TADF material. The high-energy triplet excitons often lead to stability degradation and lifetime reduction of the device. In addition, the TADF material has a too high triplet exciton concentration, and the annihilation between the triplet excitons is serious, resulting in a serious efficiency roll-off.

### SUMMARY

The present application provides an organic electroluminescent device, a preparation method thereof, and a display apparatus. The light emitting layer of the device uses a triplet-triplet annihilation material as a host material, a thermally delayed fluorescence material as a dye, and makes the thermally delayed fluorescence material emit light by the triplet-triplet annihilation material sensitizing the thermally delayed fluorescence material, which can significantly enhance the stability of the device and overcome the defects of the short device lifetime caused by the high-energy excitons in the device in the prior art.

The present application provides an organic electroluminescent device including a light emitting layer, the light emitting layer includes a host material and a dye, the host material is a triplet-triplet annihilation material, and the dye includes a thermally activated delayed fluorescence material; a singlet energy level of the triplet-triplet annihilation material is greater than a singlet energy level of the thermally activated delayed fluorescence material; and a triplet energy level of the triplet-triplet annihilation material is smaller than a triplet energy level of the thermally activated delayed fluorescence material.

Optionally, an energy level difference between the singlet energy level and the triplet energy level of the triplet-triplet annihilation material is >0.5 eV.

Optionally, twice of the triplet energy level of the triplet-triplet annihilation material is higher than the singlet energy level of the triplet-triplet annihilation material.

Optionally, an energy level difference between the singlet energy level and the triplet energy level of the thermally activated delayed fluorescence material is ≤0.3 eV.

Optionally, a mass ratio of the thermally activated delayed fluorescence material in the light emitting layer is 0.1 wt %-40 wt %.

Optionally, the mass ratio of the thermally activated delayed fluorescence material in the light emitting layer is 0.1 wt %-20 wt %.

Optionally, the mass ratio of the thermally activated delayed fluorescence material in the light emitting layer is 0.1 wt %-10 wt %.

Optionally, a fluorescence quantum yield of an instantaneous component of the thermally activated delayed fluorescence material is greater than 50%.

Optionally, the fluorescence quantum yield of the instantaneous component of the thermally activated delayed fluorescence material is greater than 75%.

Optionally, the triplet-triplet annihilation material is a compound containing one or more of naphthyl, anthryl, perylenyl, pyrenyl, phenanthryl, fluoranthenyl, triphenylenyl, tetracenyl, pentacenyl, and oxazolyl.

Optionally, the triplet-triplet annihilation material is a compound having one of the structures shown in H1-H69 in the present application.

Optionally, the thermally activated delayed fluorescence material is a compound having one of the structures shown in T1-T102 in the present application.

Optionally, the light emitting layer has a thickness of 1 nm-60 nm.

Optionally, the light emitting layer has a thickness of 30 nm.

The present application also provides a preparation method of an organic electroluminescent device, including the following steps: forming a light emitting layer by co-evaporation of a triplet-triplet annihilation material source and a thermally activated delayed fluorescence material source.

The present application further provides a display apparatus including any one of the organic light emitting devices described above.

The light emitting layer of the organic electroluminescent device of the present application uses the triplet-triplet annihilation material as the host material to sensitize the TADF dye. Due to a low triplet energy level of the triplet-triplet annihilation material, a part of triplet excitons of the TADF dye that has no time to up-convert back to the singlet will transfer to the triplet of the triplet-triplet annihilation material, transferring a higher triplet energy to a lower triplet of the triplet-triplet annihilation material, thus reducing the concentration of the long-lifetime high-energy triplet excitons the TADF dye, thereby suppressing molecular bond breakage caused by high-excitation state energy, and further improving the device stability of the TADF material and extending the lifetime of the device. In addition, the triplet-triplet annihilation material can also convert the triplet energy obtained from the TADF material into singlet by collision, and then transfer the singlet excitons to the singlet of the TADF material through Foster energy transfer to emit fluorescence, which not only reduces the concentration of triplet excitons and thereby reduces the efficiency roll-off at high brightness, but also improves the utilization rate of excitons.

### BRIEF DESCRIPTION OF THE DRAWINGS

FIG. 1 is a schematic structural diagram of an organic electroluminescent device of the present application;

FIG. 2 is a schematic diagram of energy transmission and light emission of a light emitting layer when the light emitting layer is a conventional host material doped with TADF;

FIG. 3 is a schematic diagram of energy transmission and light emission of a light emitting layer when the light emitting layer is a TADF host material doped with TADF; and

FIG. 4 is a schematic diagram of energy transmission and light emission of a light emitting layer of an organic electroluminescent device of the present application.

### DETAILED DESCRIPTION OF THE EMBODIMENTS

In order to make the purpose, technical solution, and advantages of the present application clearer, the technical solutions in the embodiments of the present application will be described clearly and completely in combination with the embodiments of the present application. Obviously, the described embodiments are part of the embodiments of the present application, not all embodiments. Based on the embodiments in the present application, all other embodiments obtained by a person of ordinary skill in the art without creative efforts shall fall within the protection scope of the present application.

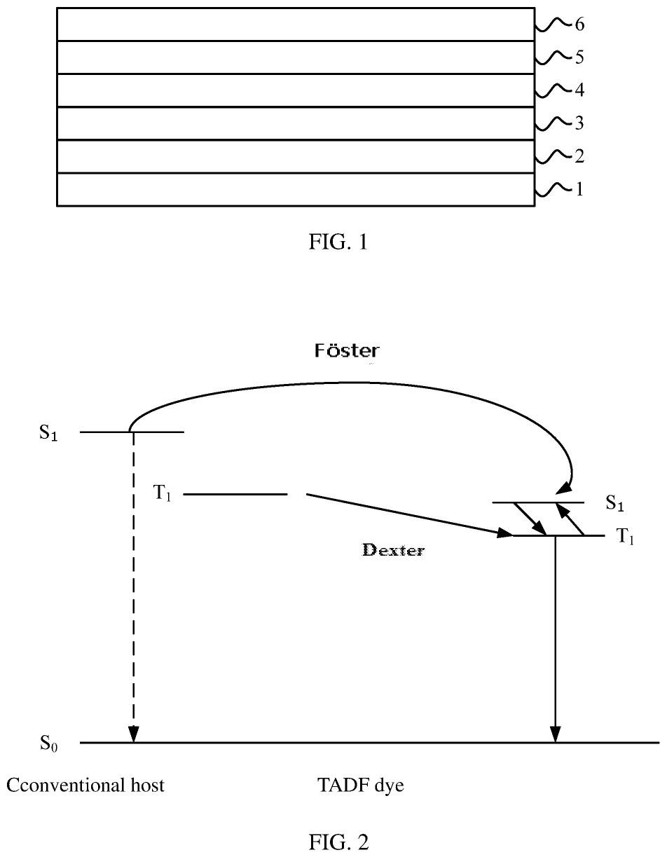

FIG. 1 is a schematic structural diagram of an organic electroluminescent device of the present application. As shown in FIG. 1, the organic electroluminescent device of the present application includes an anode 2, a hole transporting region 3, a light emitting layer 4, an electron transporting region 5 and a cathode 6, which are sequentially deposited on a substrate 1.

Specifically, the substrate 1 may be made of glass or a polymer material having excellent mechanical strength, thermal stability, water resistance, and transparency. In addition, the substrate 1 may be provided with a thin film transistor (TFT).

The anode 2 can be formed by sputtering or depositing an anode material on the substrate 1, where the anode material can be an oxide transparent conductive material such as indium tin oxide (ITO), indium zinc oxide (IZO), tin dioxide (SnO₂), zinc oxide (ZnO), and any combination thereof; the cathode 6 can be a metal or an alloy such as magnesium (Mg), silver (Ag), aluminum (Al), aluminum-lithium (Al—Li), calcium (Ca), magnesium-indium (Mg—In), magnesium-silver (Mg—Ag) and any combination thereof.

The organic material layers of the hole transporting region 3, the light emitting layer 4, and the electron transporting region 5 can be sequentially prepared on the anode 2 by methods such as vacuum thermal evaporation, spin coating, and printing. Among them, compounds used as the organic material layers may be organic small molecules, organic macromolecules and polymers, and combinations thereof.

Hereinafter, the light emitting layer 4 will be described in detail.

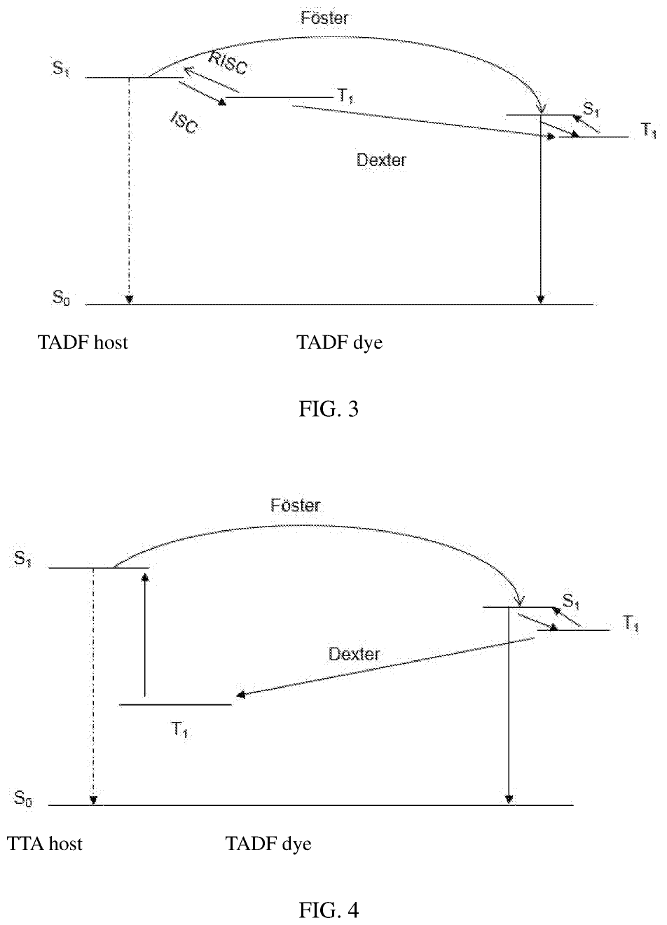

A host material for the light emitting layer of a TADF device includes a conventional host material or a TADF type host material. Among them, the conventional host material is mostly a high triplet material containing carbazolyl, phosphinoxyl and other groups, such as mCP, DPEPO, and CBP. FIG. 2 is a schematic diagram of energy transmission and light emission of a light emitting layer when the light emitting layer is a conventional host material doped with a TADF dye, and FIG. 3 is a schematic diagram of energy transmission and light emission of a light emitting layer when the light emitting layer is a TADF type host material doped with a TADF dye. As shown in FIG. 2, during the light emission process, a triplet energy level of the conventional host material must be higher than a triplet energy level of the TADF dye, preventing triplet excitons of the TADF dye from transferring back to the host material to reduce exciton utilization. As shown in FIG. 3, similar to a conventional host material, in addition to transferring singlet excitons and the triplet excitons to the TADF dye, the TADF type host material can itself convert the triplet excitons into the singlet excitons and then transfer to a singlet energy level of the TADF dye through Foster energy transfer (the dotted line indicates that no actual transition has occurred). Compared with the conventional host material, the TADF type host material can reduce the concentration of the triplet excitons in the light emitting layer, thereby improving device stability and reducing efficiency roll-off.

However, in the above two types of light emitting layers, the triplet energy level of the host materials needs to be greater than the triplet energy level of the TADF dyes. Therefore, high-energy excitons are often generated in this type of device, which shortens the device's own lifetime and leads to serious efficiency roll-off.

Based on this, the light emitting layer 4 of the present application includes a host material and a dye, where the host material is a triplet-triplet annihilation material, and the dye includes a thermally activated delayed fluorescence material; the singlet energy level of the triplet-triplet annihilation material is greater than the singlet energy level of the thermally activated delayed fluorescence material; the triplet energy level of the triplet-triplet annihilation material is smaller than the triplet energy level of the thermally activated delayed fluorescence material.

The triplet-triplet annihilation (TTA) material of the host material is a material capable of emitting fluorescence. Compared with a conventional fluorescence material, an internal quantum efficiency of the TTA material has been increased from 25% to 62.5%. Specifically, two triplet electrons of the TTA material collide with each other to produce annihilation, generating a ground state electron and a singlet electron, the newly generated singlet electron then transitions back to the ground state to emit fluorescence. In the technical solution of the present application, since the singlet energy level of the TTA material is higher than the singlet energy level of the TADF dye, excitons in the singlet of the TTA material are directly transferred to the singlet of the TADF dye through the Foster transition and emits fluorescence while being transferred back from the singlet of the TADF dye to the ground state, which not only suppresses the light emitting of the TTA material itself, but also further improves the sensitization of the TADF dye.

In the light emitting layer, since an energy level difference between the singlet and triplet of the TADF dye is small, the triplet excitons of the TADF dye partly undergo an up-conversion processes by absorbing ambient heat, to convert to singlet excitons and then transition back to the ground state to emit light. In addition, due to the longer triplet exciton lifetime of the TADF material and the triplet energy level of the TADF dye being higher than the triplet energy level of the TTA material, part of the triplet excitons of TADF dyes, when failing to being converted into singlet excitons by an up-conversion in time, will transition to the triplet energy level of TTA material, thereby reducing the concentration of the triplet excitons of TADF dyes and overcoming the problem of serious efficiency roll-off of the device at a high current density caused by TPA (triplet polaron annihilation), TTA of the TADF material, etc. At the same time, since the triplet energy level of the TTA material is lower than the triplet energy level of the TADF dye, the concentration of high-energy excitons in the device is suppressed, and the stability of the device is further improved to a certain extent.

The energy transmission and light emission process of the organic electroluminescent device of the present application will be described in detail below.

FIG. 4 is a schematic diagram of energy transmission and light emission of a light emitting layer of an organic electroluminescent device of the present application. As shown in FIG. 4, the light emitting layer of the present application includes a TTA host material and a TADF dye. On one hand, part of singlet excitons of the TADF material returns directly to the ground state to emit fluorescence, and on the other hand, triplet excitons absorb ambient heat and returns to singlet through the a reverse intersystem crossing and then emits delayed fluorescence. In this process, the triplet excitons have too long lifetimes, there will be some triplet excitons that have no time to up-convert and thus transfer to lower-energy triplet excitons of the TTA host material. TTA triplet excitons collide to form a singlet and then transfer to the singlet of the TADF dye that has a lower energy level than that of the singlet of the TTA material through Foster transition.

Eventually, the excitons of the TTA material and the TADF dye will transition from the singlet of the TADF dye back to the ground state to emit fluorescence. Where due to the lower triplet energy level of the TTA material and the transition of the triplet excitons of the TADF dye to the low triplet energy level of the TTA material, the concentration of the high energy excitons in the device is effectively reduced, that is, shortening the lifetime of high energy excitons in the device and suppressing the intermolecular breakage caused by high excitation energy, so that the device of the present application significantly increases the stability of the device while extending the lifetime, and overcomes the problem of serious efficiency roll-off at a high current density.

In an embodiment of the present application, the TTA material may be a compound containing one or more of naphthyl, anthryl, perylenyl, pyrenyl, phenanthryl, fluoranthenyl, triphenylenyl, tetracenyl, pentacenyl, and oxazolyl.

Generally, an energy level difference between a singlet energy level and a triplet energy level in a TTA material is large. In the present application, it is preferred that the energy level difference between the singlet energy level and the triplet energy level of the TTA material is greater than 0.5 eV. Therefore, the triplet energy level of the host material of the present application is low and does not generate high-energy excitons, thereby suppressing intermolecular breakage caused by high excitation energy, which is beneficial to the improvement of device lifetime. If the energy level difference between the singlet energy level and the triplet energy level of the TTA material is less than or equal to 0.5 eV, triplet excitons with high energy may be generated, thereby causing a problem of poor device stability.

At the same time, twice of the triplet energy level of the TTA material in the present application is higher than the singlet energy level of the triplet-triplet annihilation material, so that every two TTA triplet excitons can collide with each other after obtaining the energy transferred by the TADF triplet and then annihilate to generate an electron that can transition to a singlet.

Specifically, the TTA material of the present application is preferably a compound having one of the following structures:

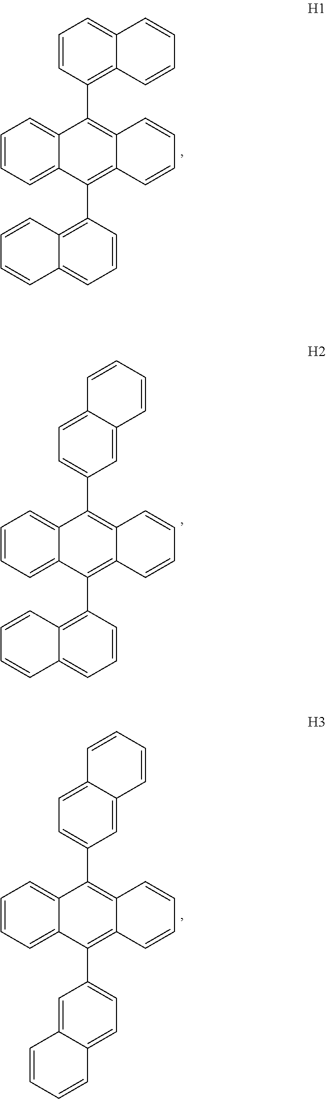

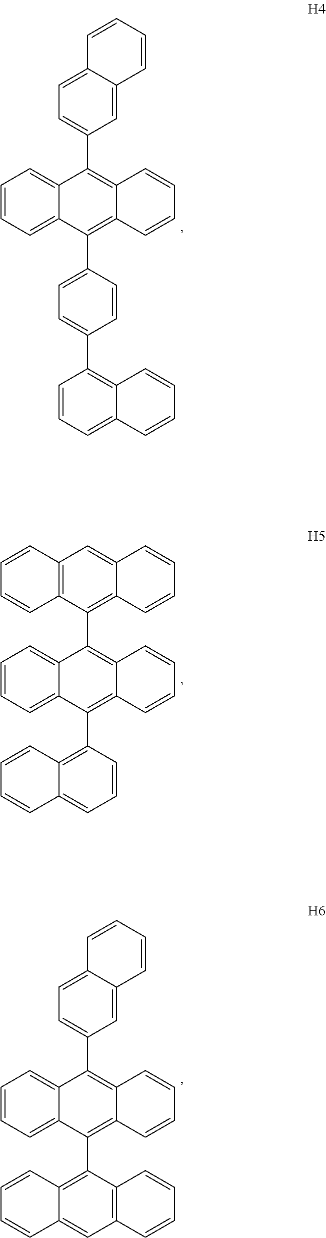

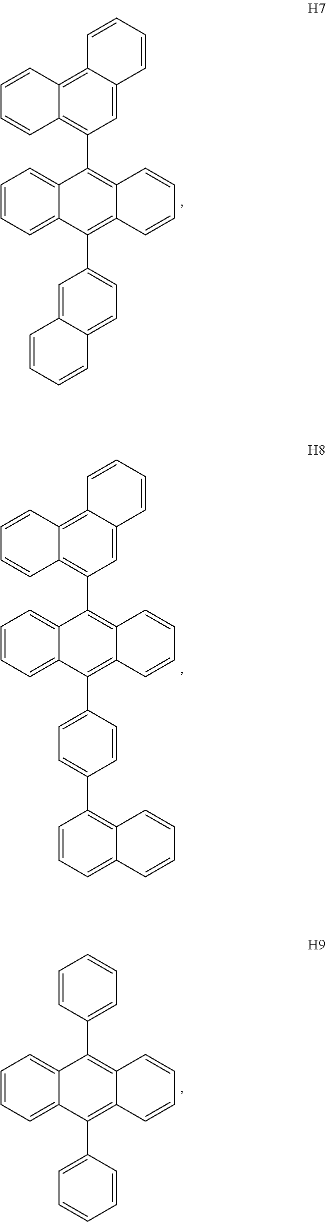

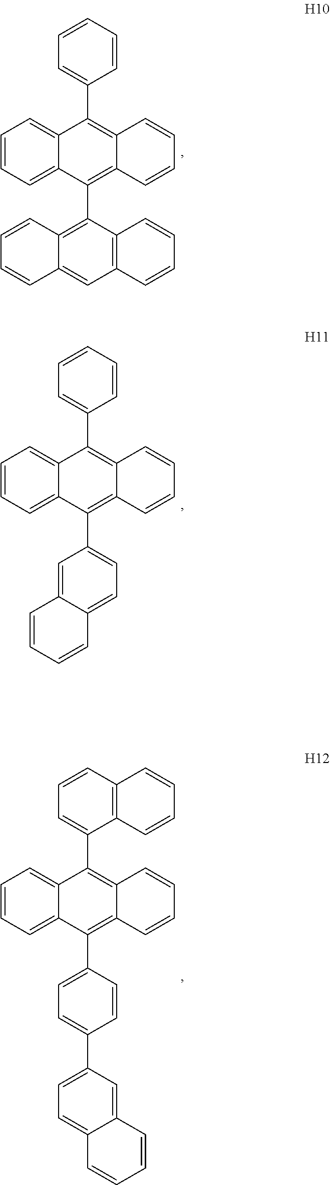

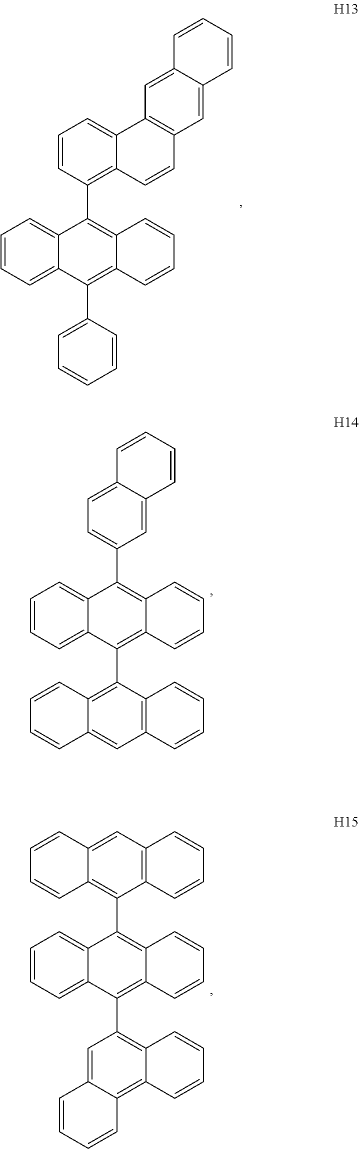

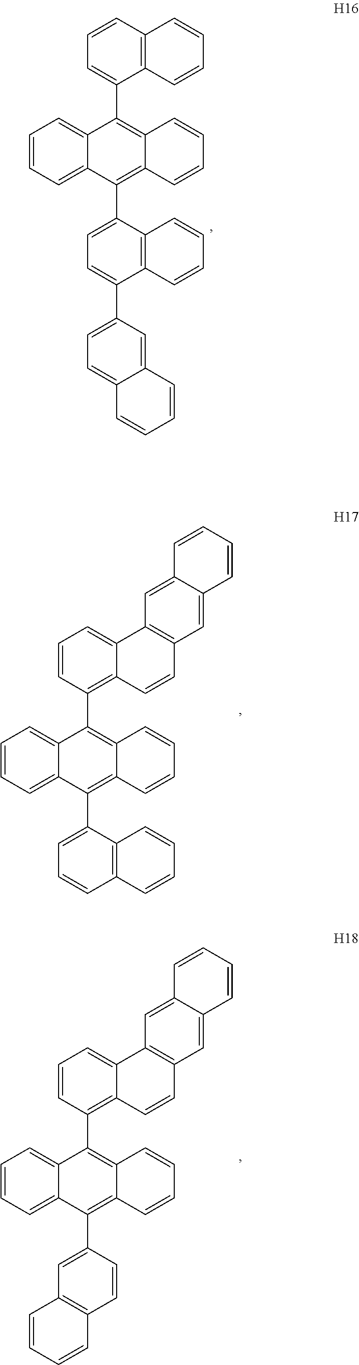

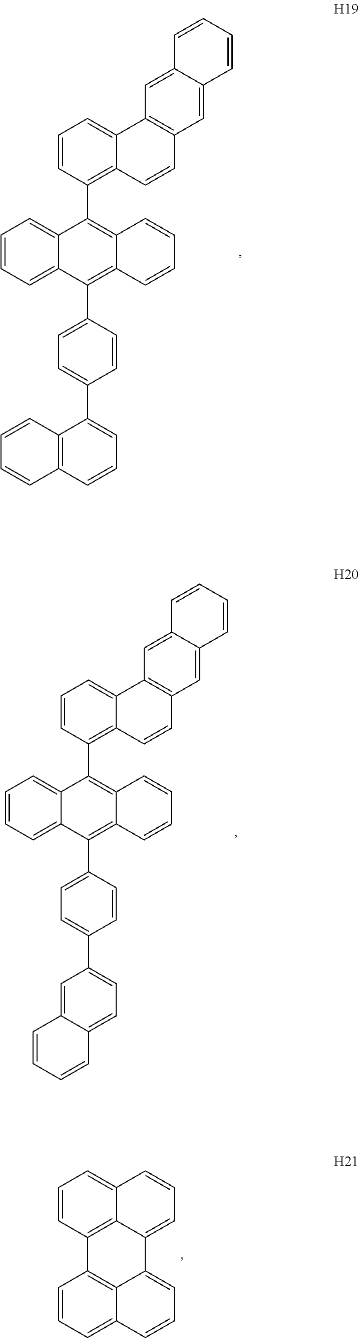

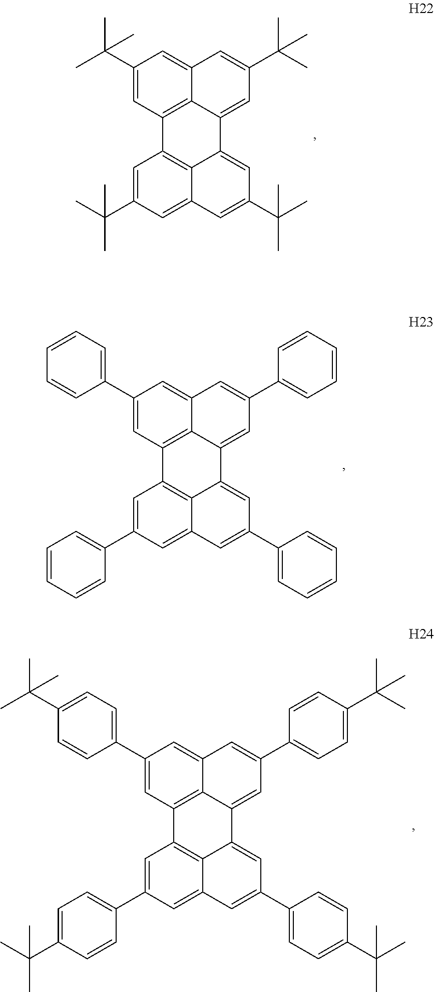

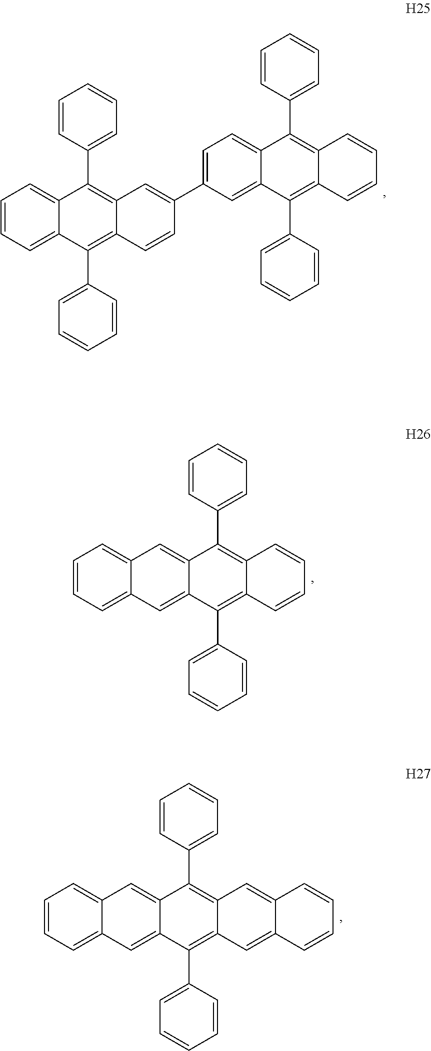

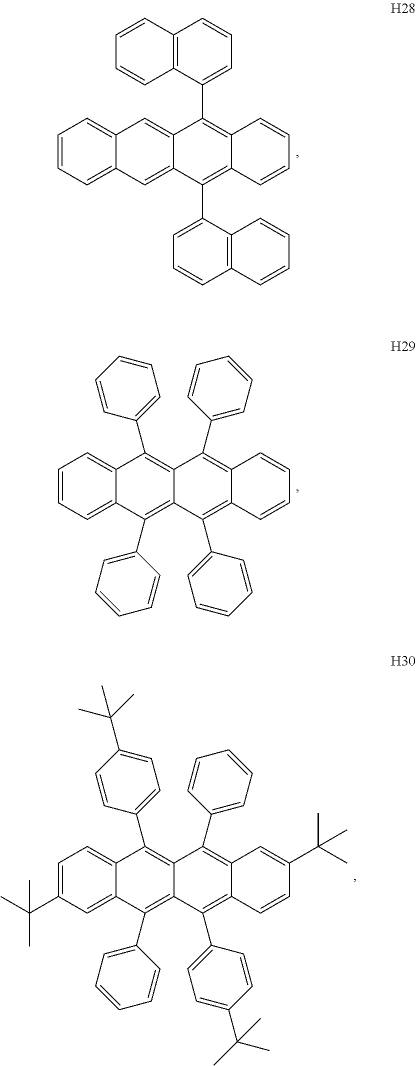

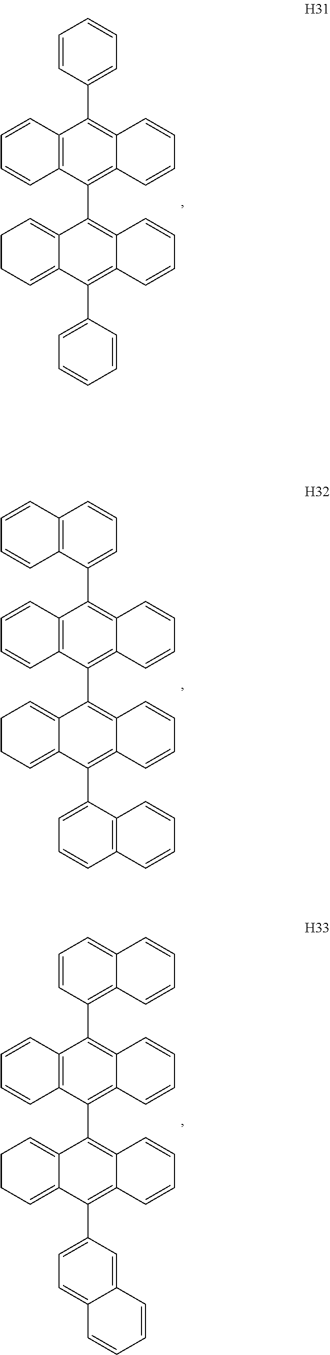

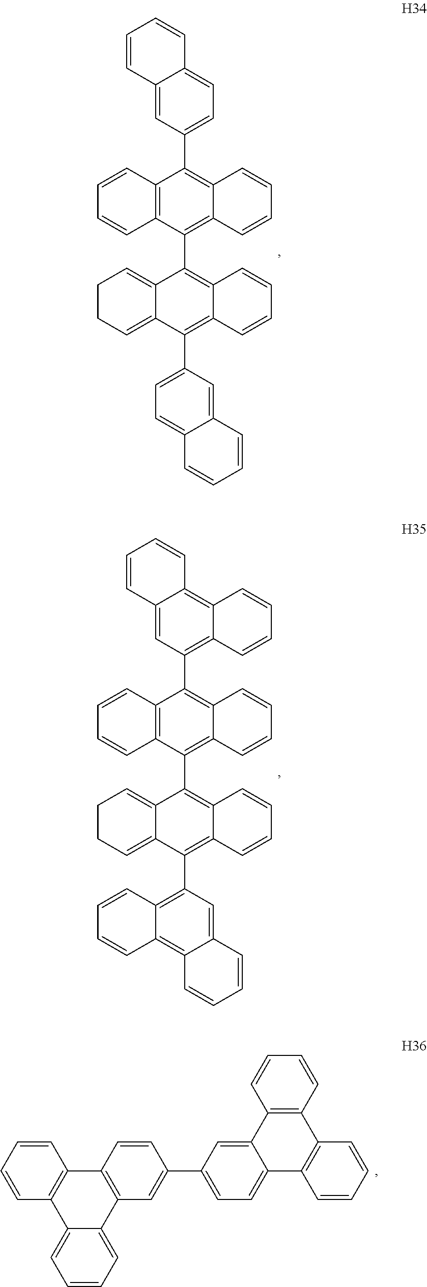

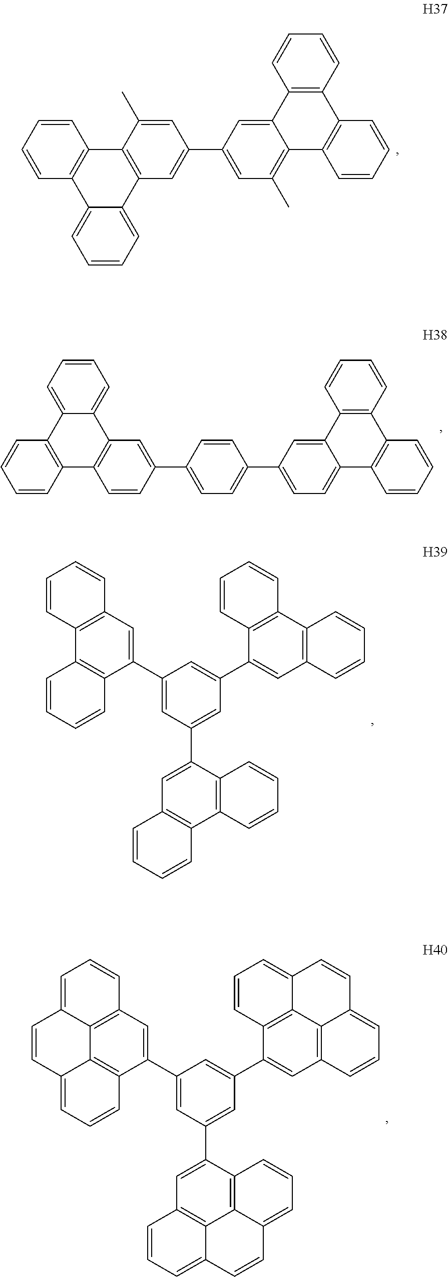

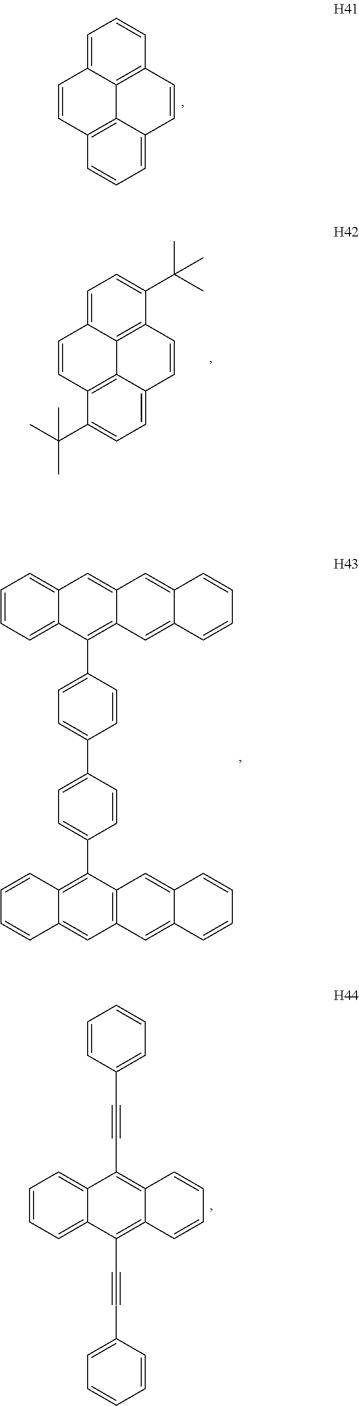

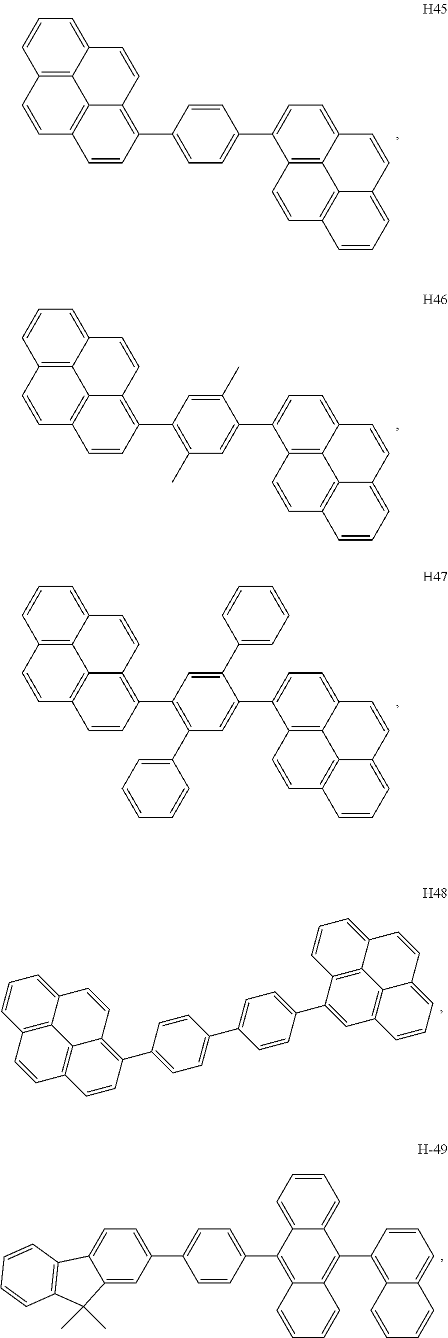

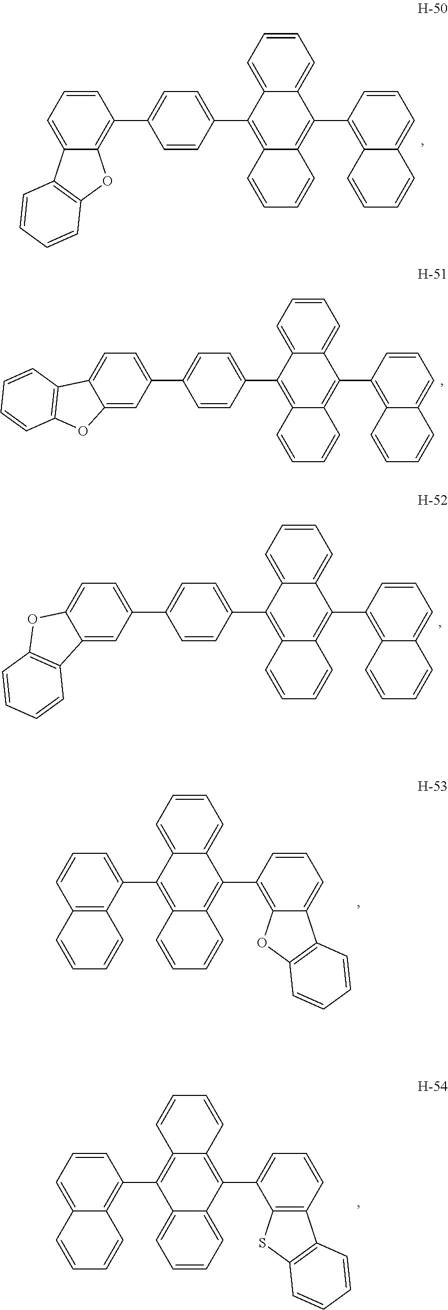 [SMILES: c1ccc2c(-c3c4ccccc4c(-c4ccc(-c5cccc6c5oc5ccccc56)cc4)c4ccccc34)cccc2c1 ; c1ccc2c(-c3c4ccccc4c(-c4ccc(-c5ccc6c(c5)oc5ccccc56)cc4)c4ccccc34)cccc2c1 ; c1ccc2c(-c3c4ccccc4c(-c4ccc(-c5ccc6oc7ccccc7c6c5)cc4)c4ccccc34)cccc2c1 ; c1ccc2c(-c3c4ccccc4c(-c4cccc5c4oc4ccccc45)c4ccccc34)cccc2c1 ; c1ccc2c(-c3c4ccccc4c(-c4cccc5c4sc4ccccc45)c4ccccc34)cccc2c1]

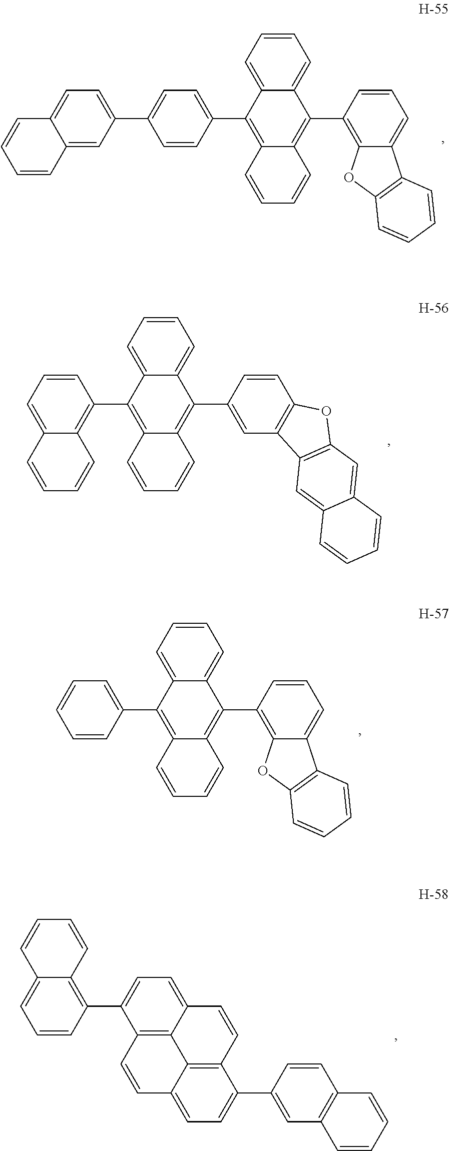

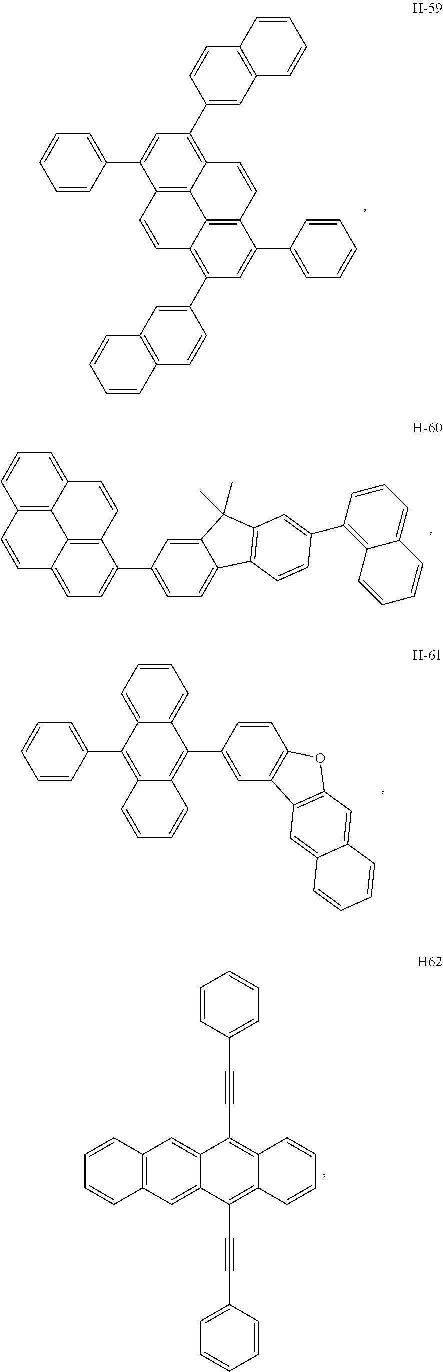

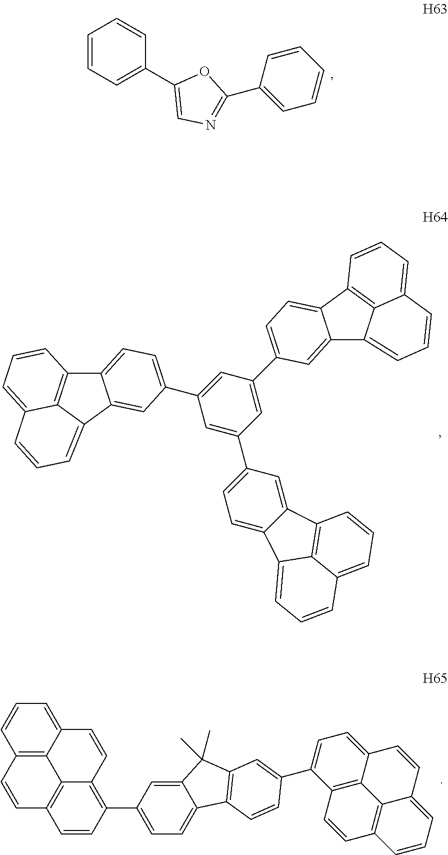

In an embodiment of the present application, the mass ratio (i.e., doping concentration) of the TADF dye in the light emitting layer is 0.1 wt % to 40 wt %. In order to further obtain a device with better roll-off and better lifetime, it is preferable to control the mass ratio of the TADF dye in the light emitting layer to be 0.1 wt %-20 wt %.

Further, for the selected TADF material to be used, the present application also defines a fluorescence quantum yield of an instantaneous component thereof.

When the TADF material emits light, a part of excitons will directly return from the singlet to the ground state to emit fluorescence, and the other part of excitons will return to the ground state after inverse intersystem crossing from the triplet to the singlet, to emit fluorescence. Where the quantum yield of the fluorescence emitted by directly returning from the singlet to the ground state is called the fluorescence quantum yield of the instantaneous component, and the quantum yield of the other part is called the quantum yield of delayed fluorescence. Different TADF materials have different fluorescence quantum yields of the instantaneous component. In the present application, TADF materials with fluorescence quantum yields of the instantaneous component of greater than 50% are selected. In order to reduce energy loss to improve the light emitting efficiency of the device and reduce roll-off, TADF materials with the fluorescence quantum yield of the instantaneous component of greater than 75% is preferable.

As mentioned above, the energy level difference between the singlet energy level and triplet energy level of the TADF material is small. In the present application, the TADF material can be further optimized on the basis of the above to make the energy level difference between the singlet energy level and the triplet energy level ≤0.3 eV, that is, further reducing the energy level difference between the singlet and triplet of the TADF dye, so that the triplet exciton is more prone to up-conversion to convert to the singlet excitons and then transition back to the ground state to emit light.

Specifically, the TADF material of the present application is preferably a compound having one of the following structures:

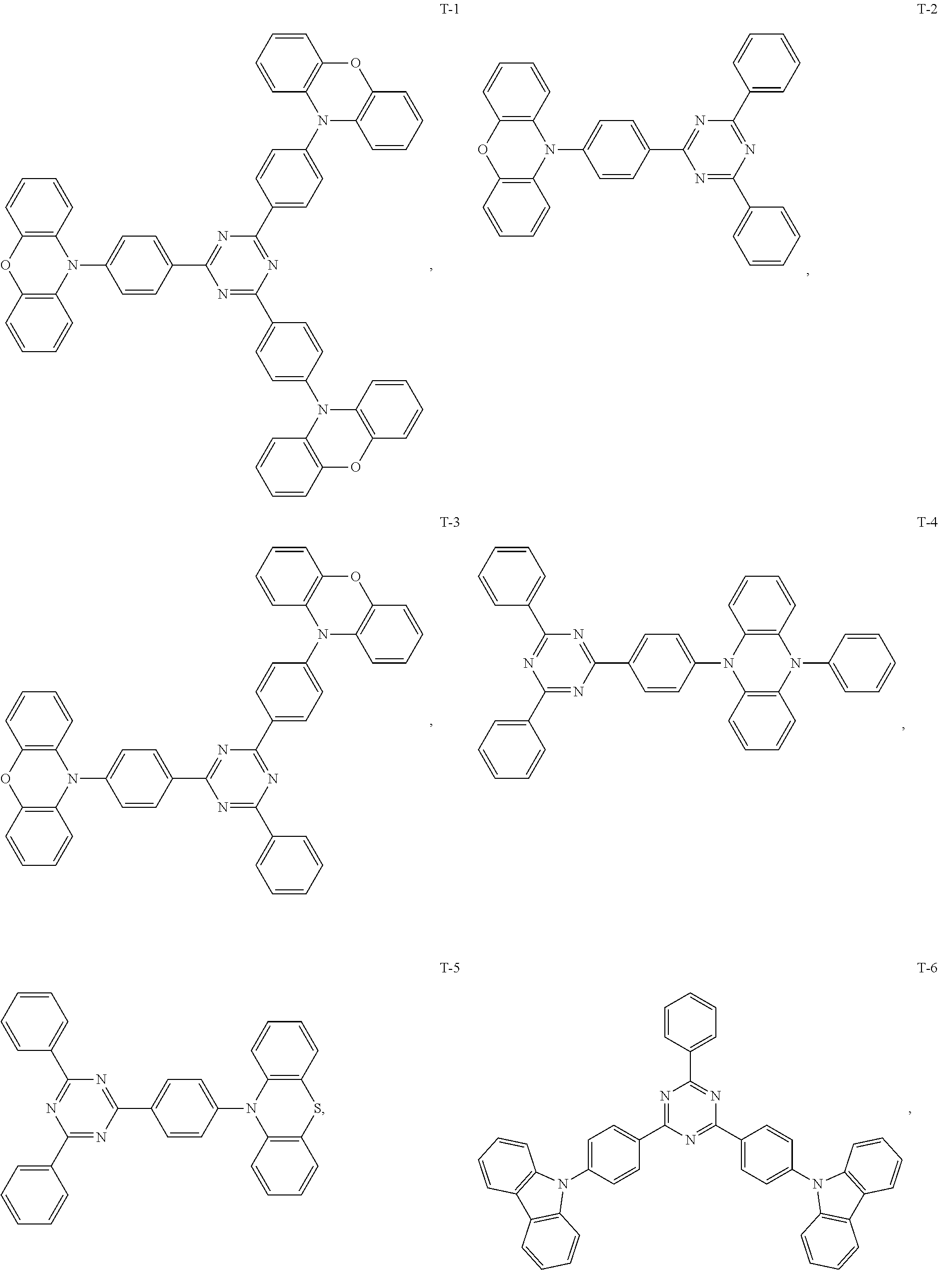 [SMILES: c1ccc2c(c1)Oc1ccccc1N2c1ccc(-c2nc(-c3ccc(N4c5ccccc5Oc5ccccc54)cc3)nc(-c3ccc(N4c5ccccc5Oc5ccccc54)cc3)n2)cc1 ; c1ccc(-c2nc(-c3ccccc3)nc(-c3ccc(N4c5ccccc5Oc5ccccc54)cc3)n2)cc1 ; c1ccc(-c2nc(-c3ccc(N4c5ccccc5Oc5ccccc54)cc3)nc(-c3ccc(N4c5ccccc5Oc5ccccc54)cc3)n2)cc1 ; c1ccc(-c2nc(-c3ccccc3)nc(-c3ccc(N4c5ccccc5N(c5ccccc5)c5ccccc54)cc3)n2)cc1 ; c1ccc(-c2nc(-c3ccccc3)nc(-c3ccc(N4c5ccccc5Sc5ccccc54)cc3)n2)cc1 ; c1ccc(-c2nc(-c3ccc(-n4c5ccccc5c5ccccc54)cc3)nc(-c3ccc(-n4c5ccccc5c5ccccc54)cc3)n2)cc1]

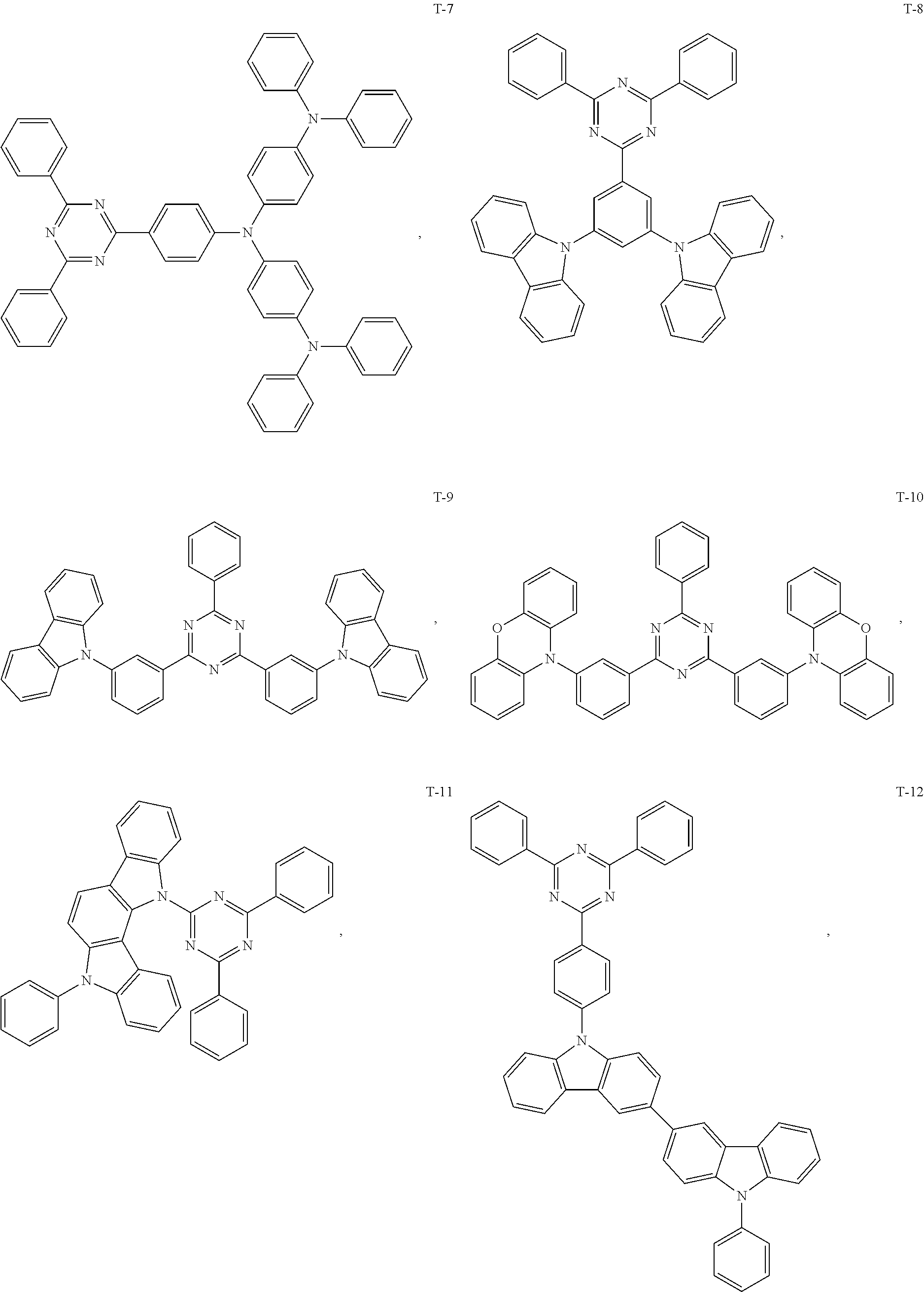

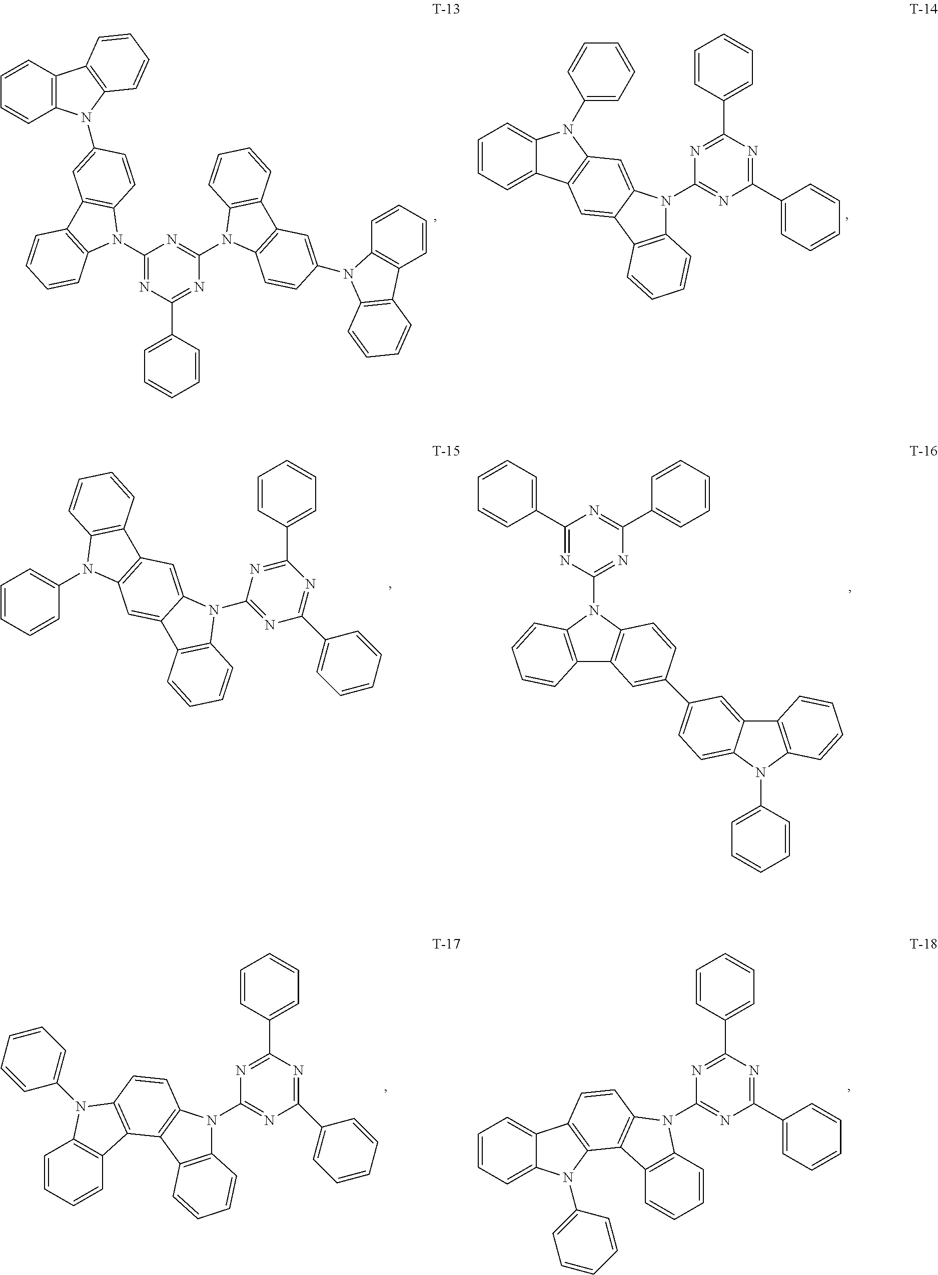

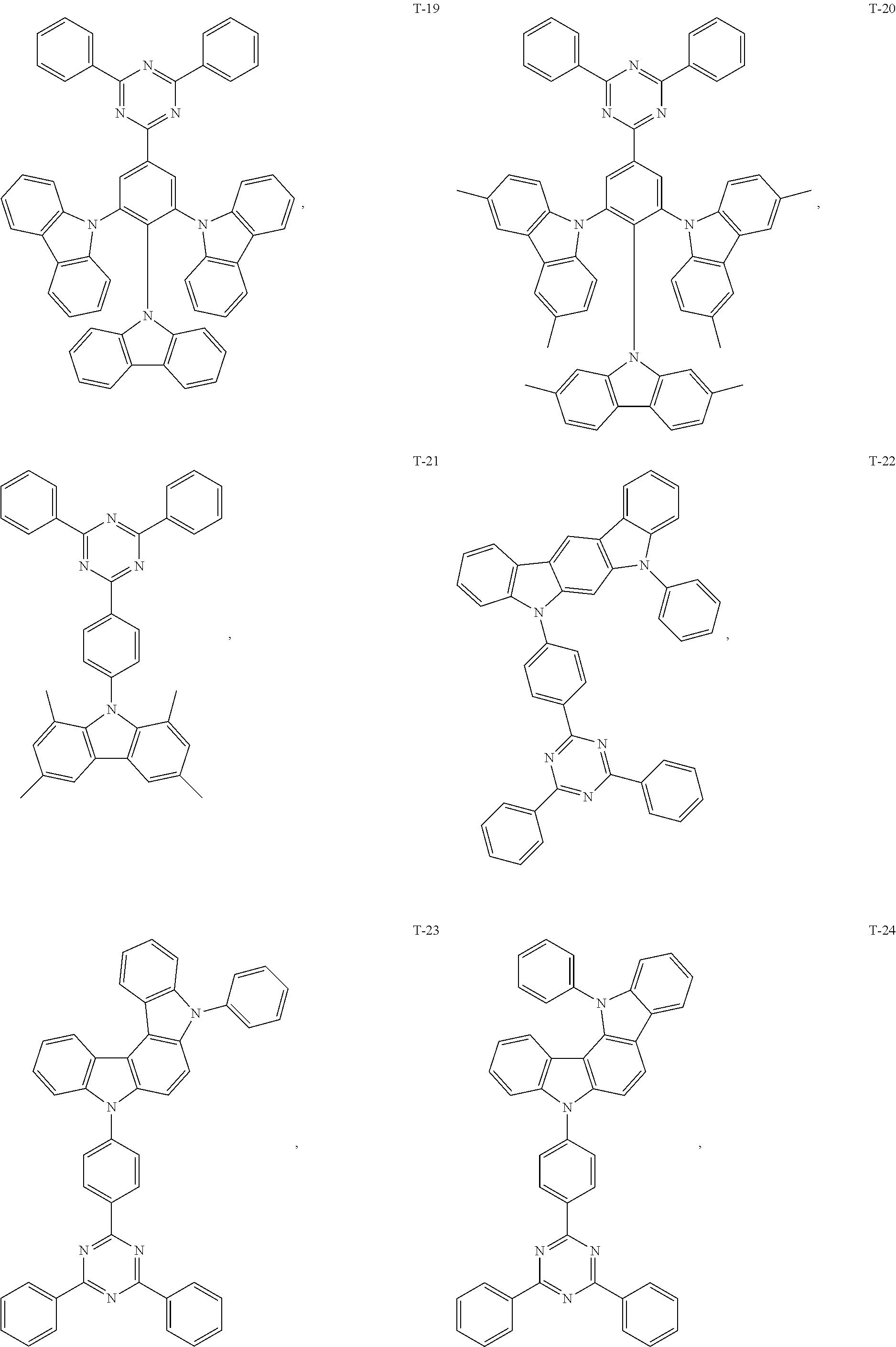

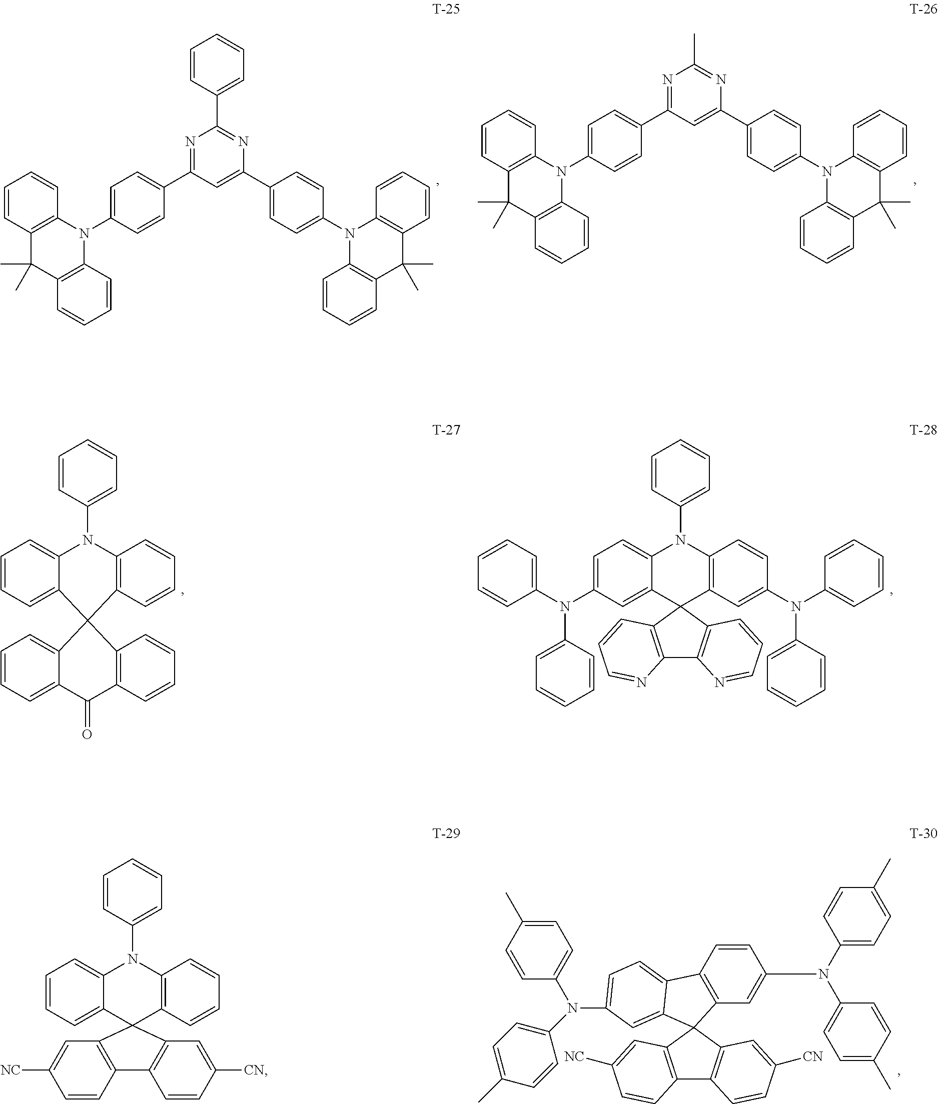

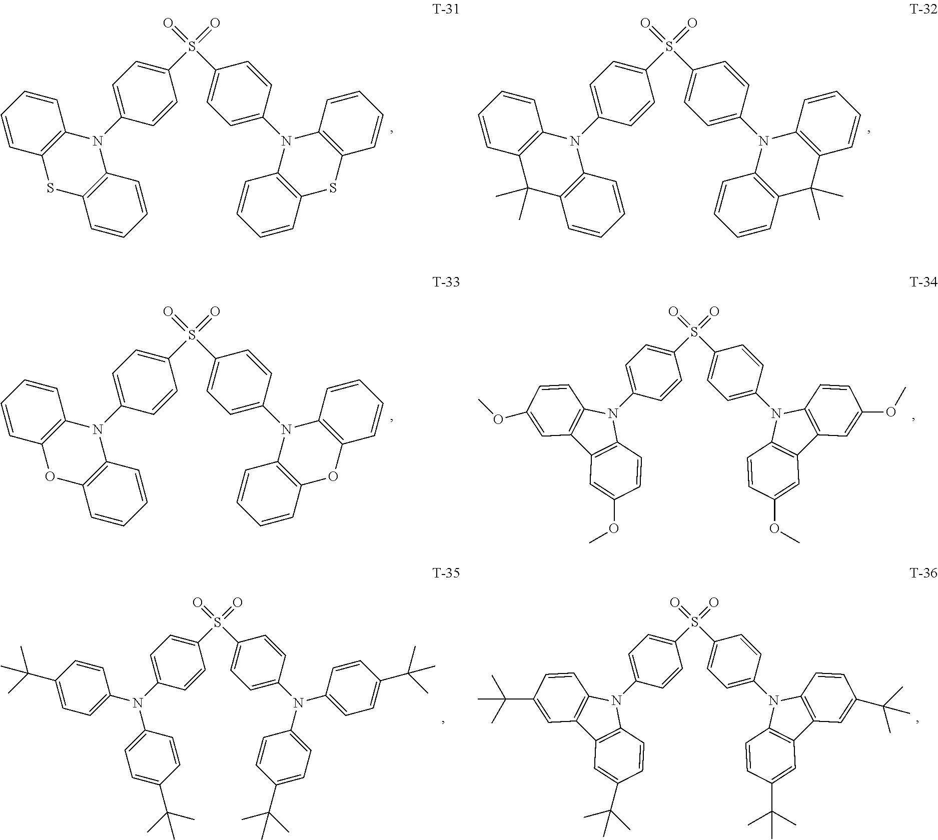

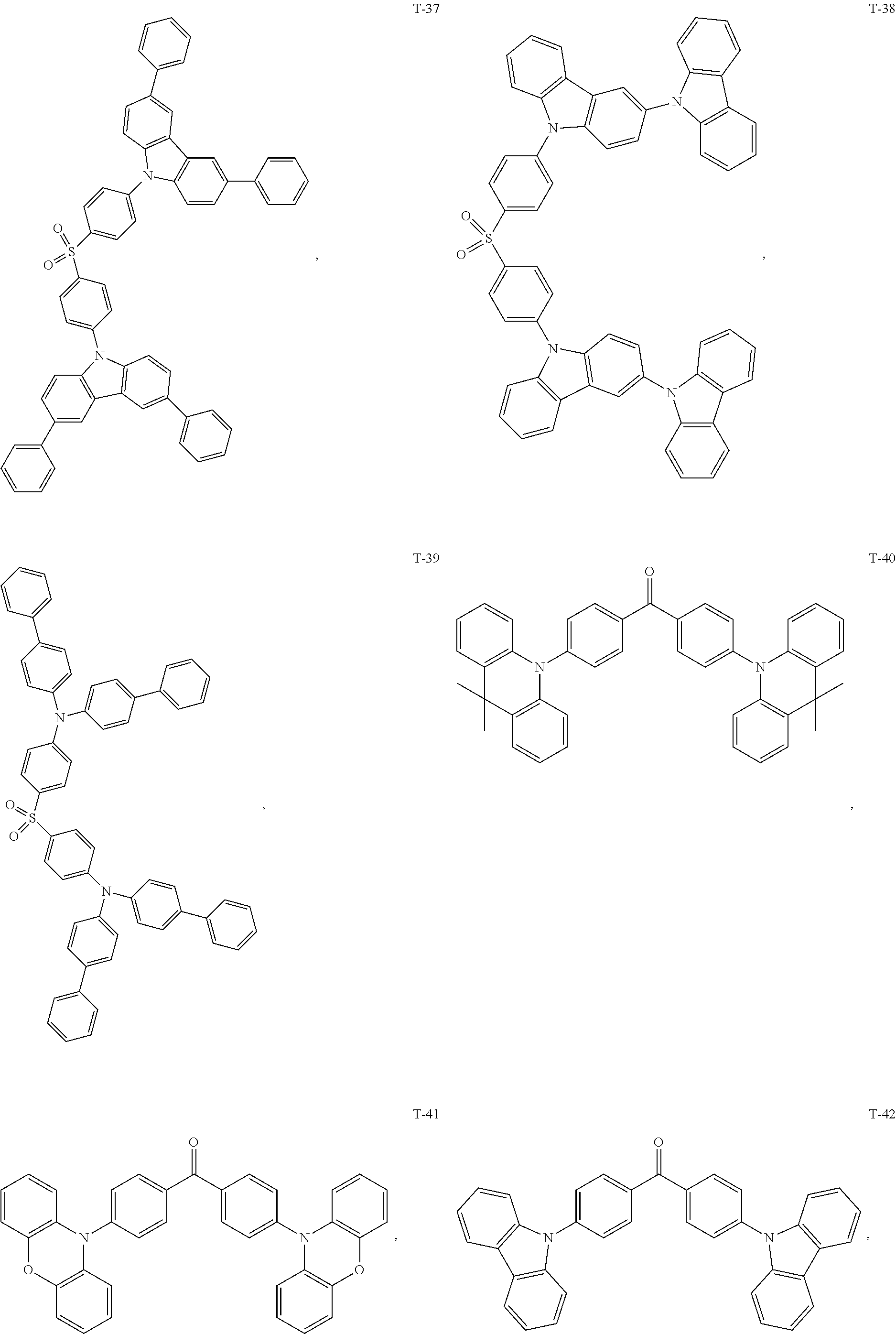

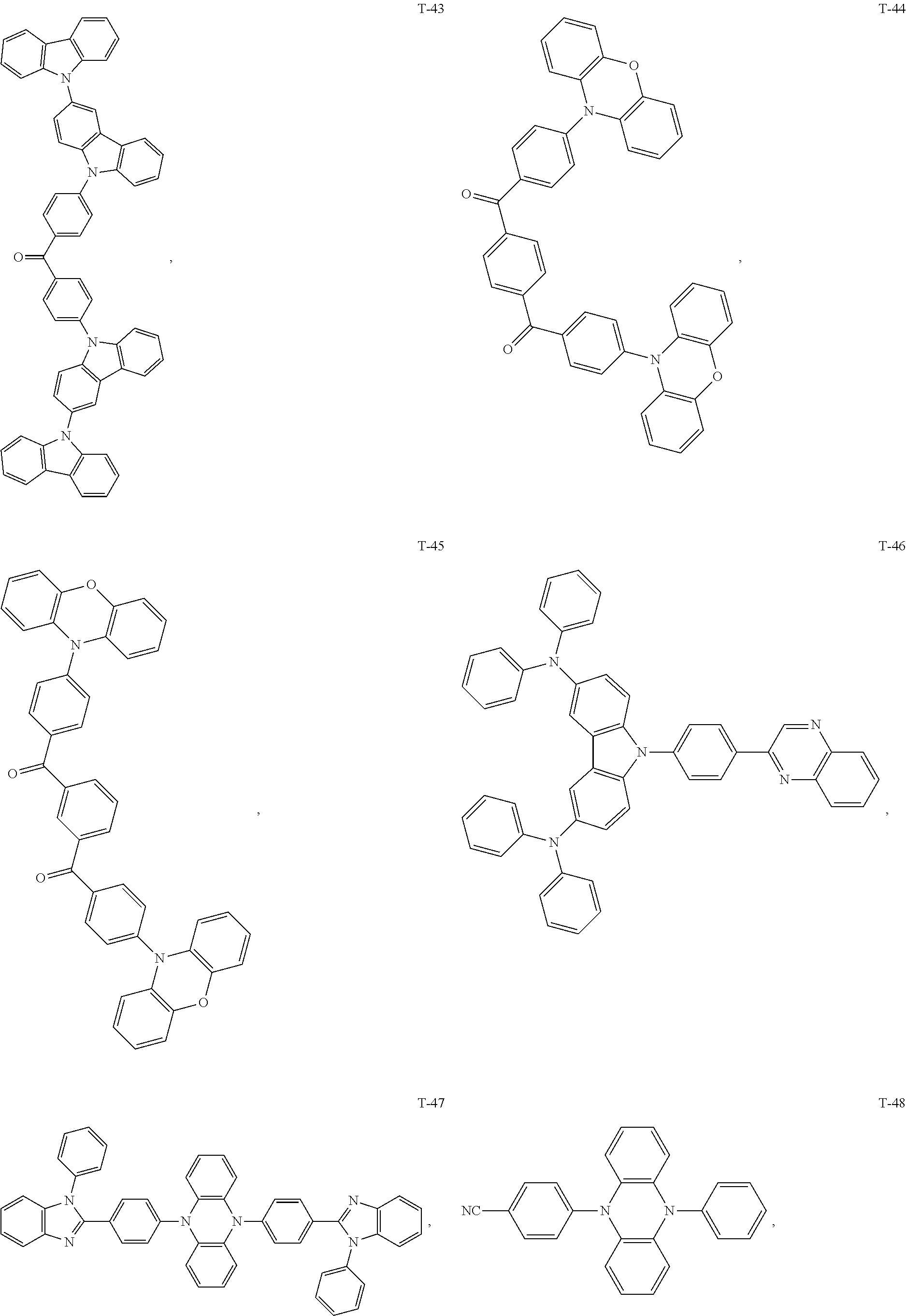

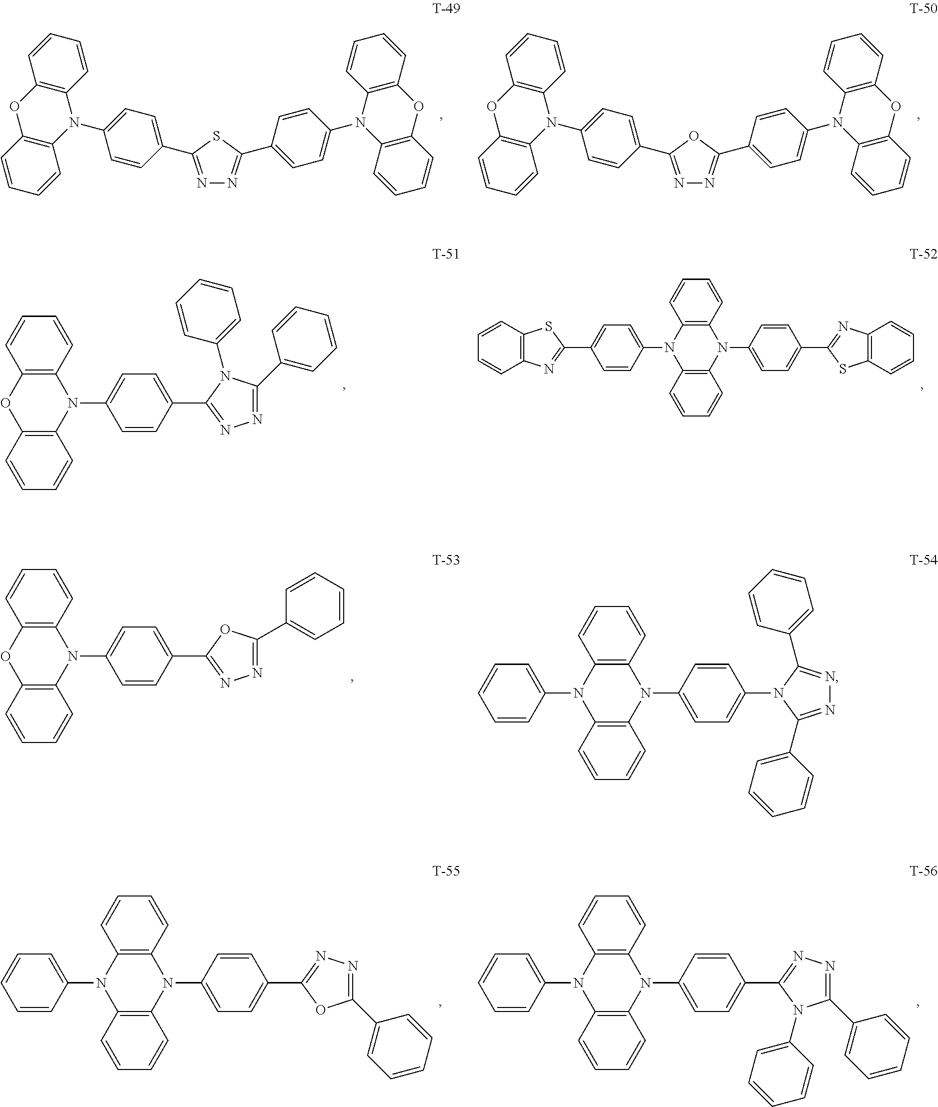

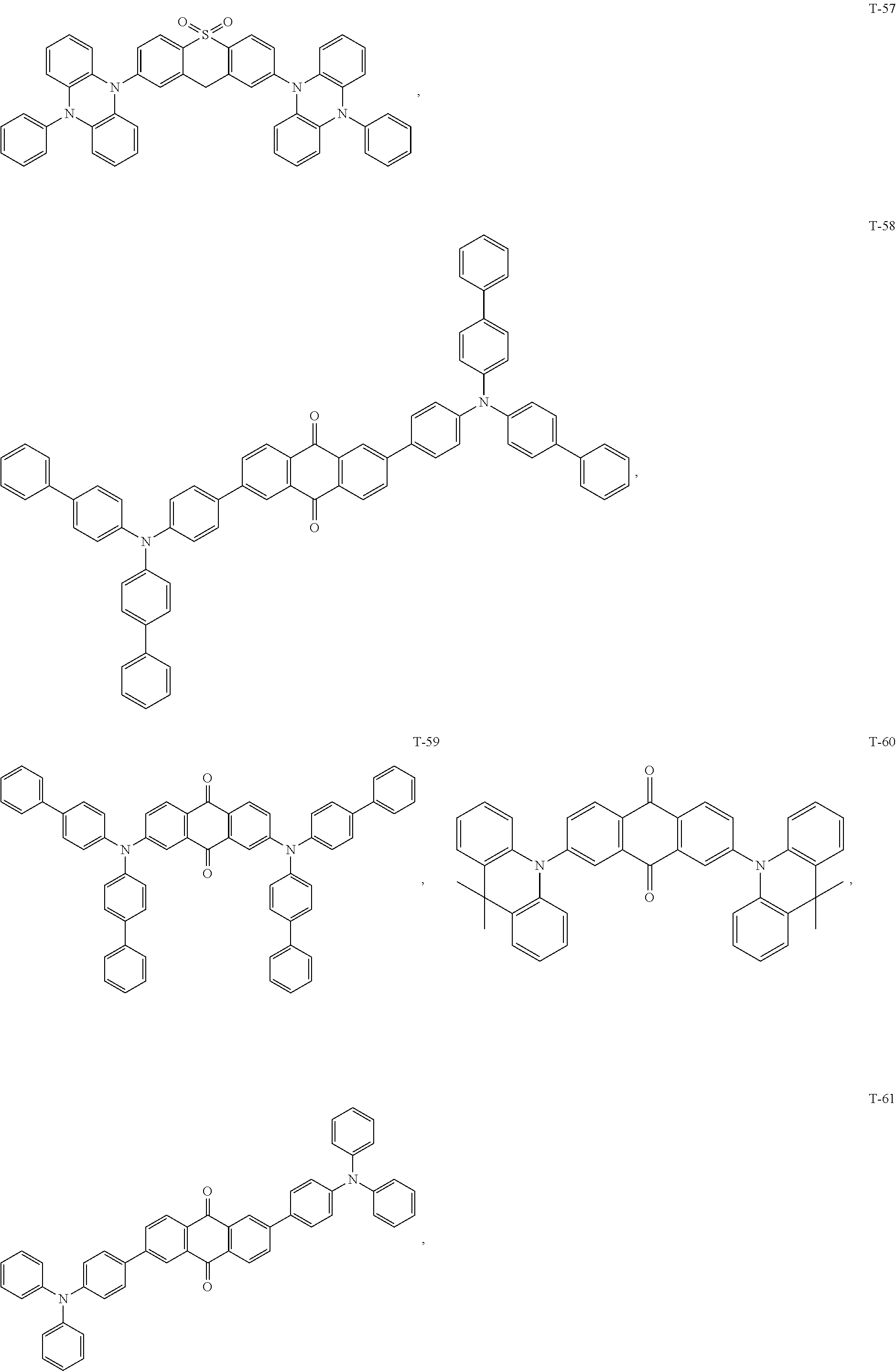

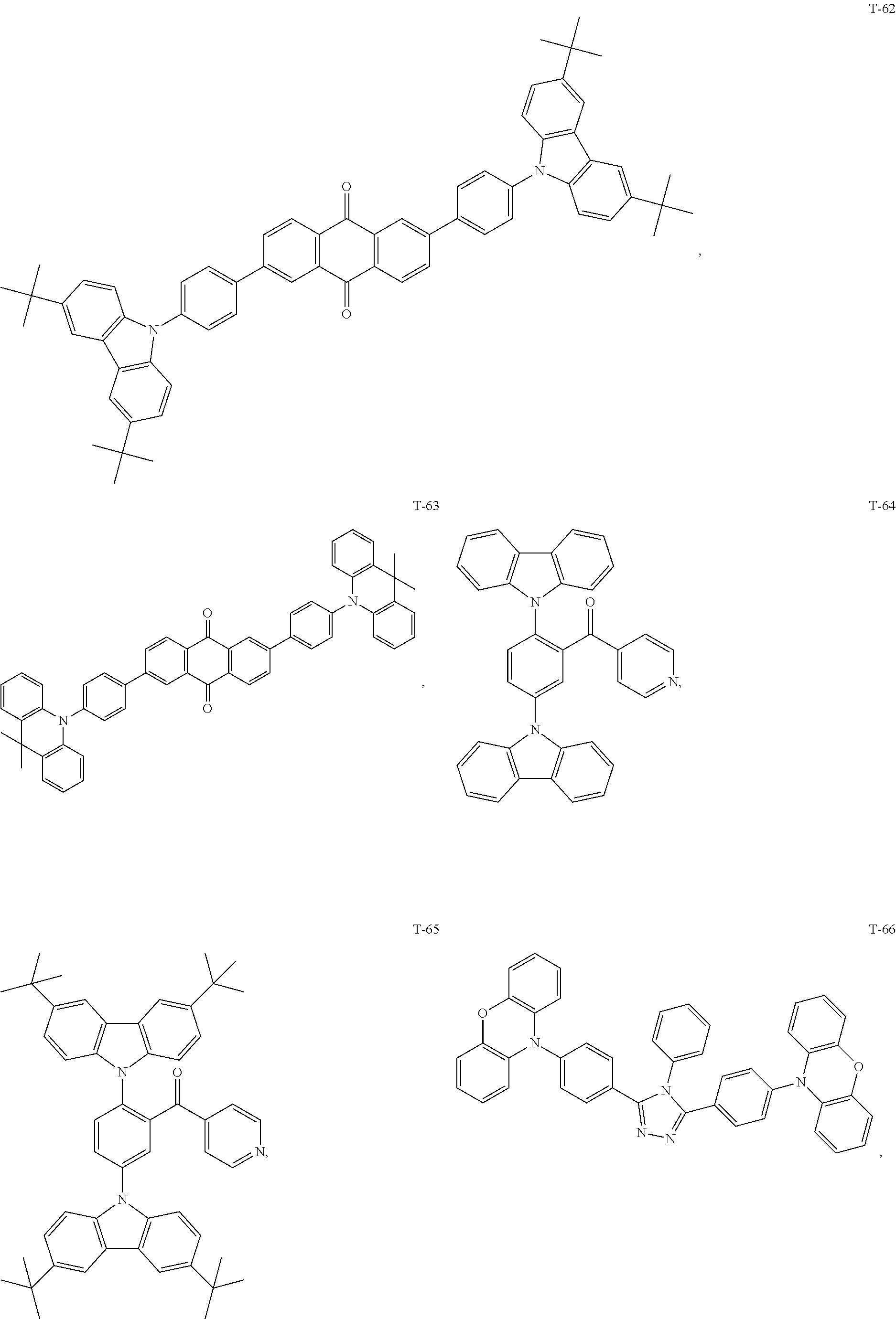

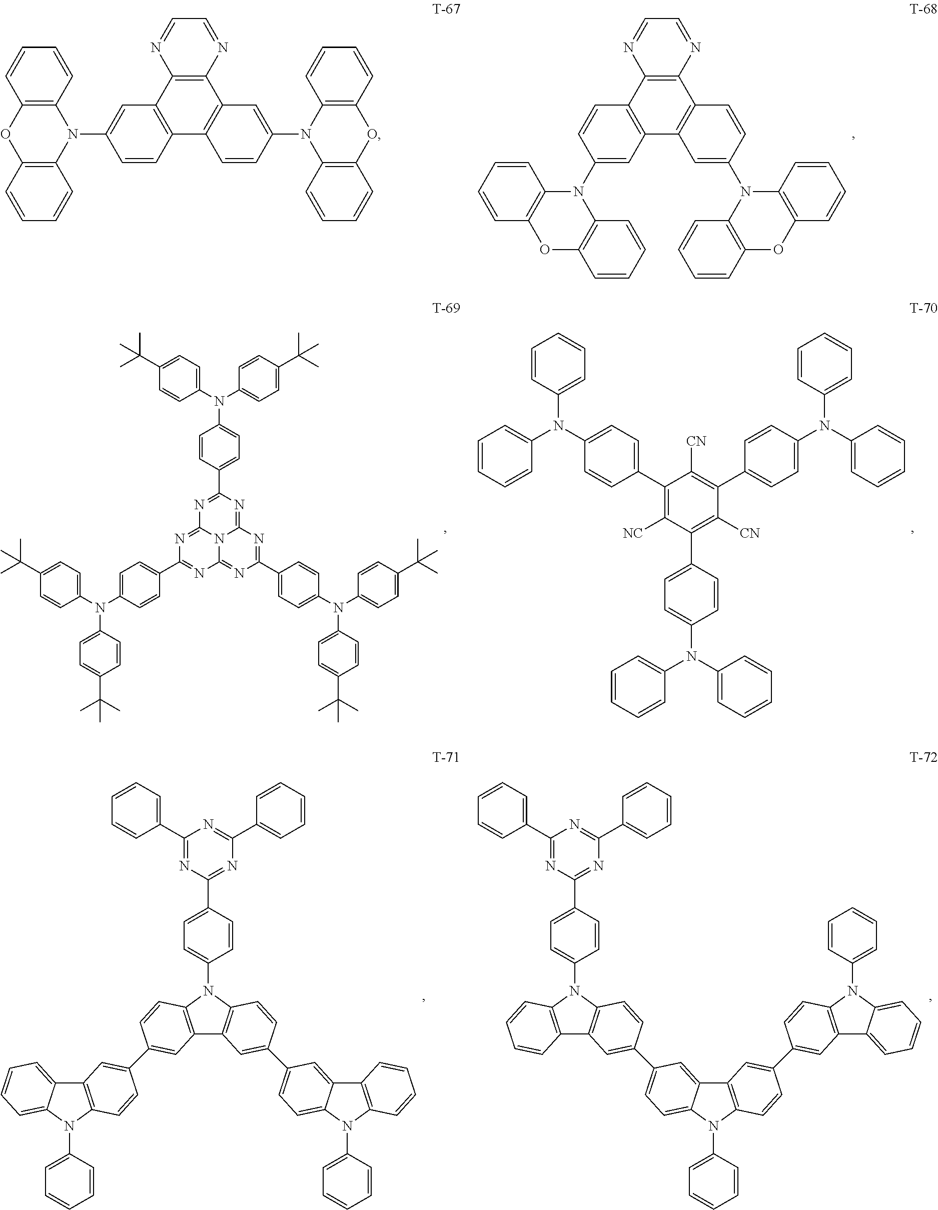

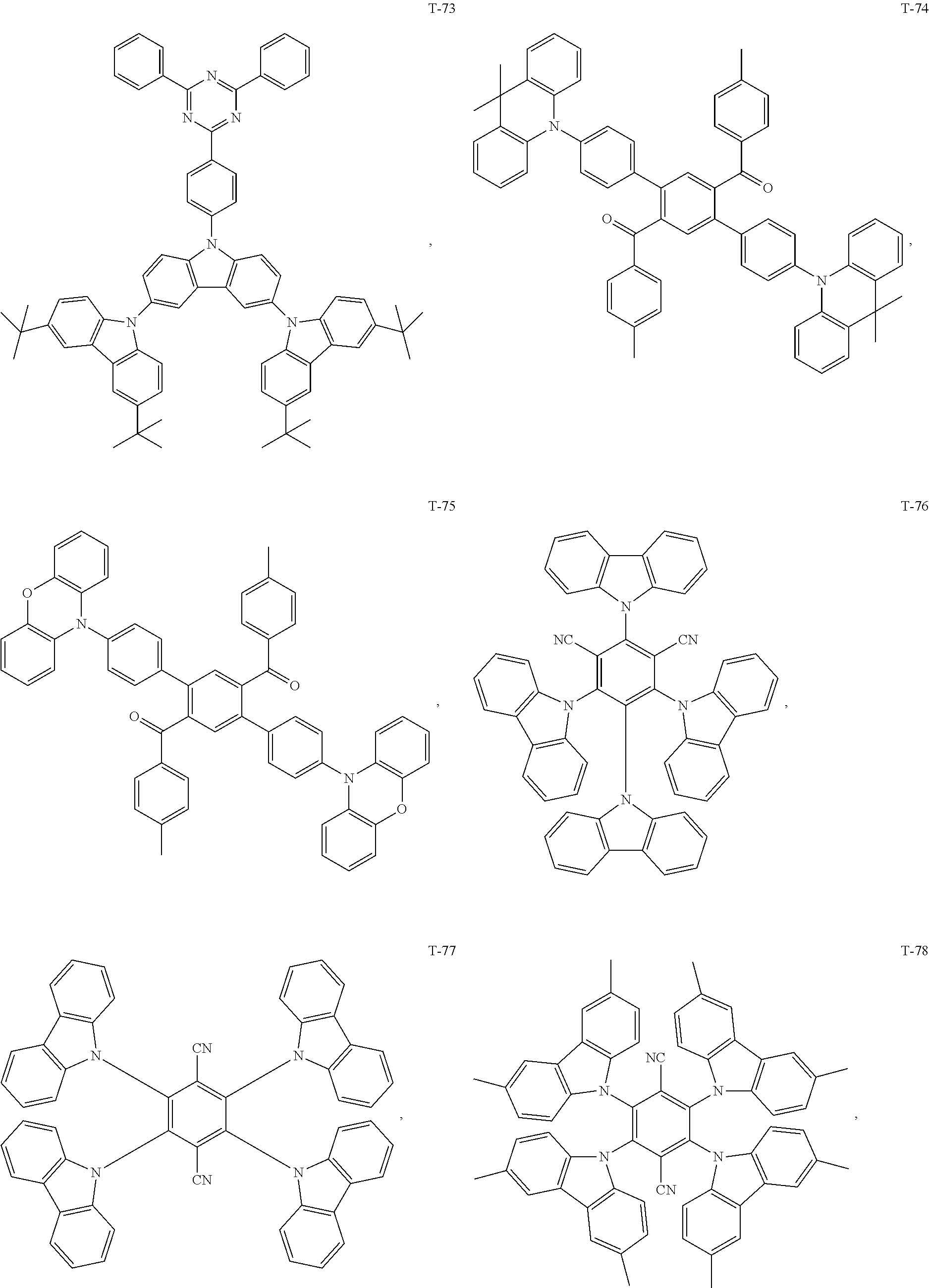

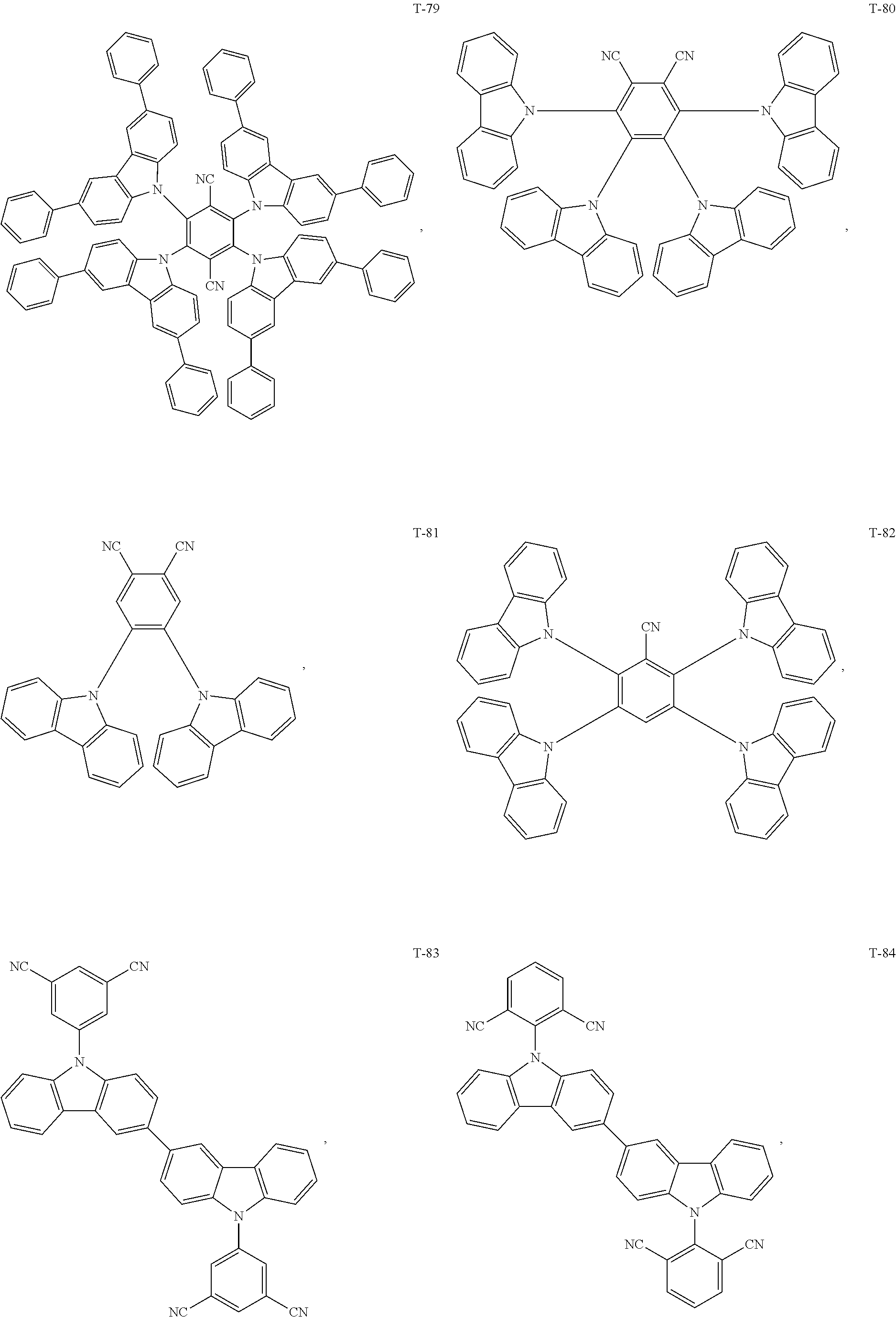

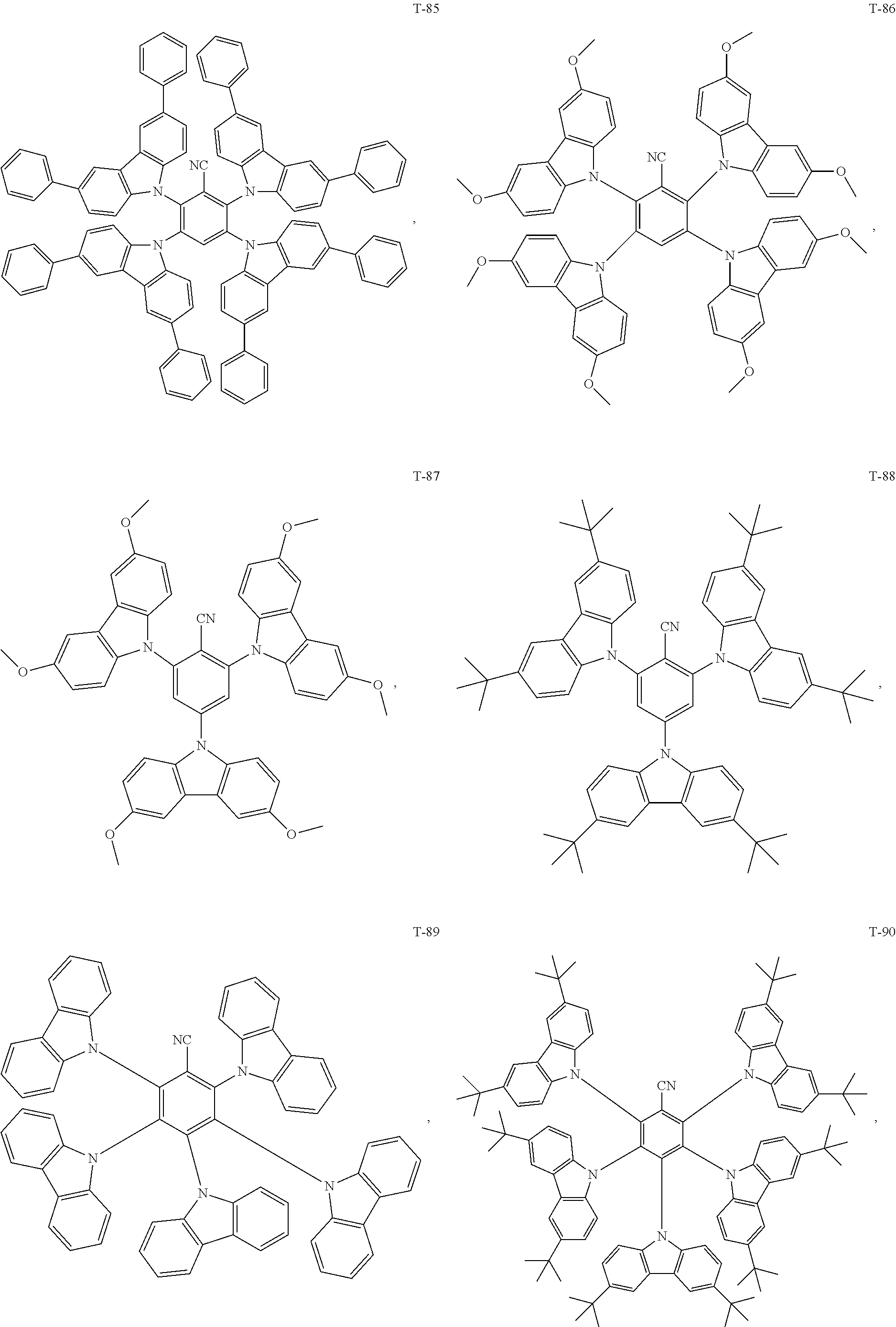

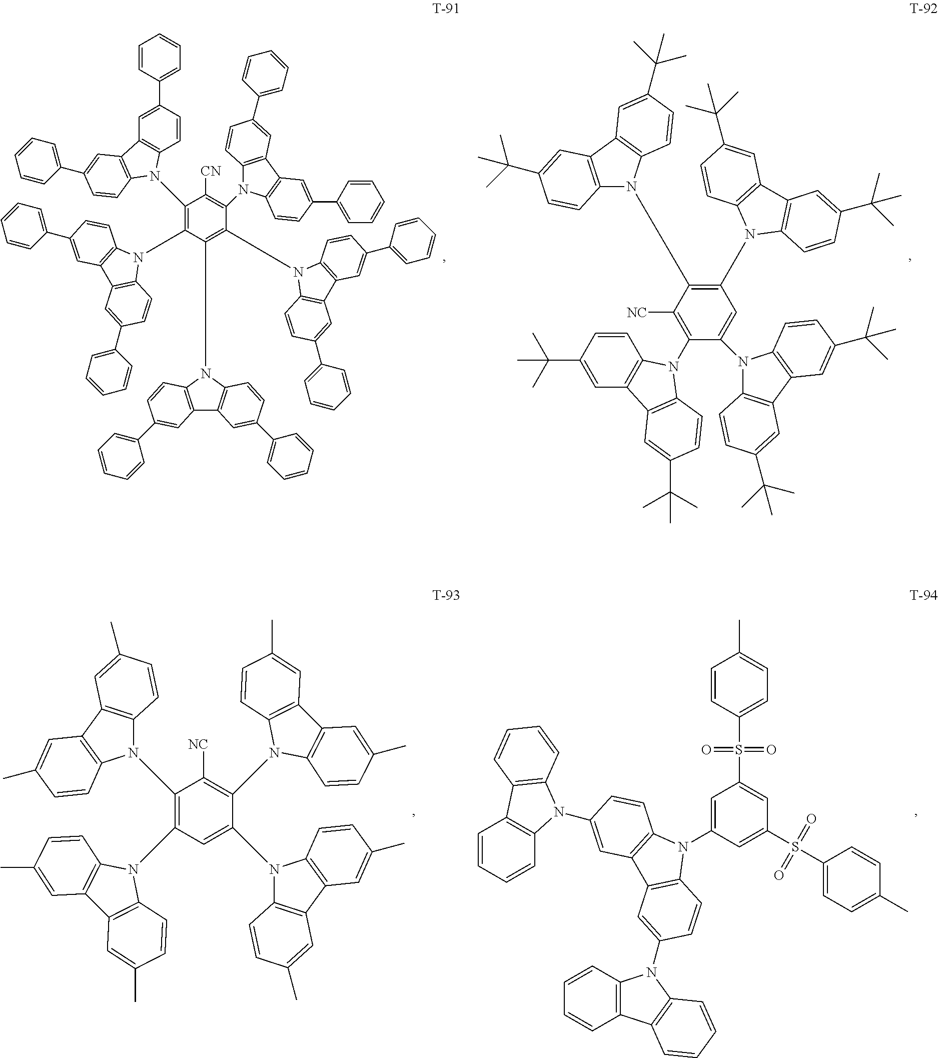

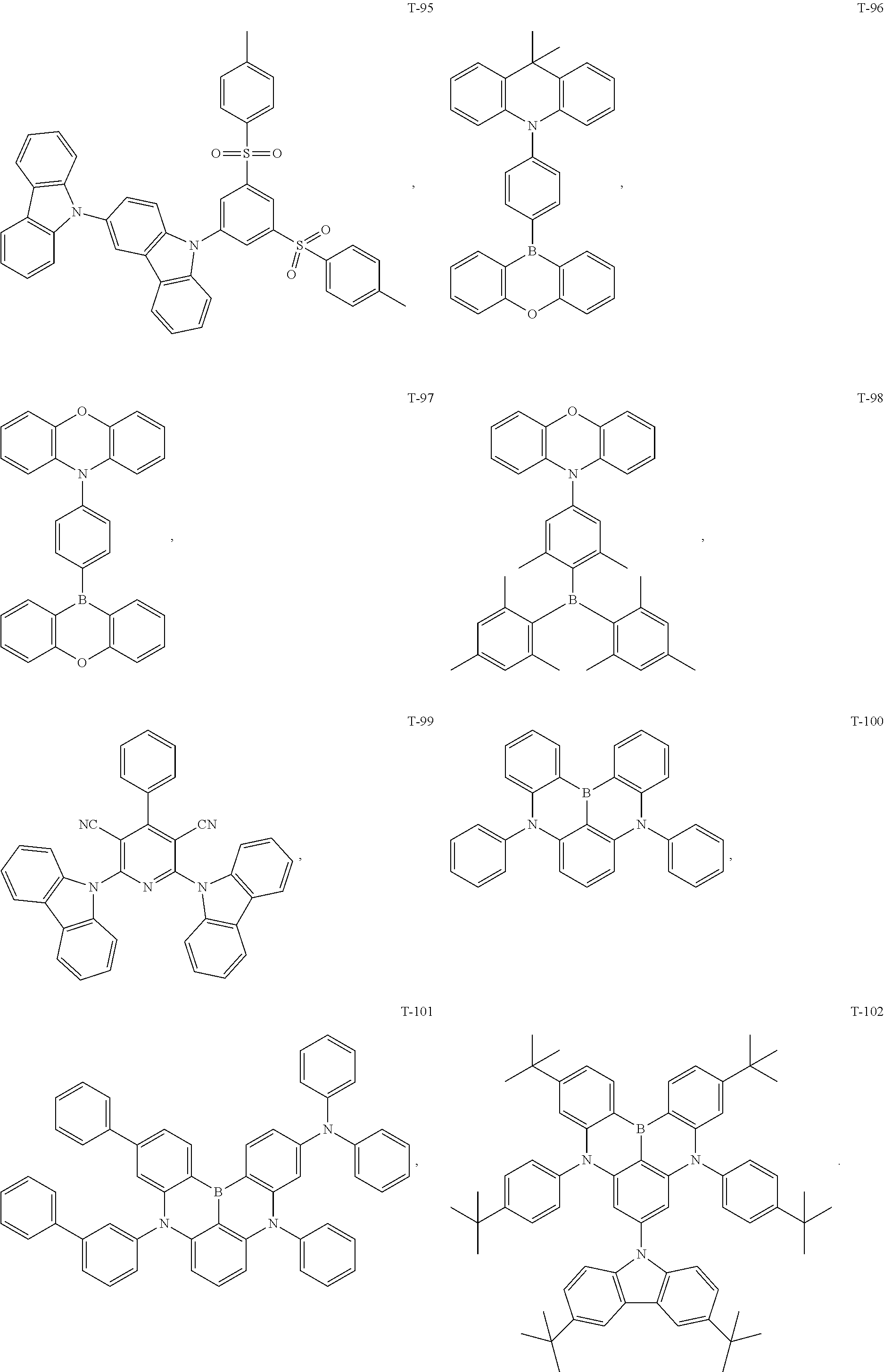

Still referring to FIG. 1, the hole transporting region 3, the electron transporting region 5, and the cathode 6 of the present application will be described. The hole transporting region 3 is located between the anode 2 and the light emitting layer 4. The hole transporting region 3 may be a single-layered hole transporting layer (HTL), including a single-layer hole transporting layer containing only one compound and a single-layer hole transporting layer containing a plurality of compounds. The hole transporting region 3 may also have a multilayer structure including at least two layers of a hole injection layer (HIL), a hole transport layer (HTL), and an electron blocking layer (EBL).

The material of the hole transporting region 3 (including HIL, HTL, and EBL) may be selected from, but not limited to, phthalocyanine derivatives such as CuPc, conductive polymers, or polymers containing conductive dopants, such as polyphenylene vinylene, polyaniline/dodecylbenzenesulfonic acid (Pani/DBSA), poly (3,4-ethylenedioxythiophene)/poly(4-styrenesulfonate) (PEDOT/PSS), polyaniline/camphorsulfonic acid (Pani/CSA), polyaniline/poly(4-styrenesulfonate) (Pani/PSS), aromatic amine derivative.

Where the aromatic amine derivative is a compound represented by the following HT-1 to HT-34. If the material of the hole transporting region 3 is an aromatic amine derivative, it may be one or more of the compounds represented by HT-1 to HT-34:

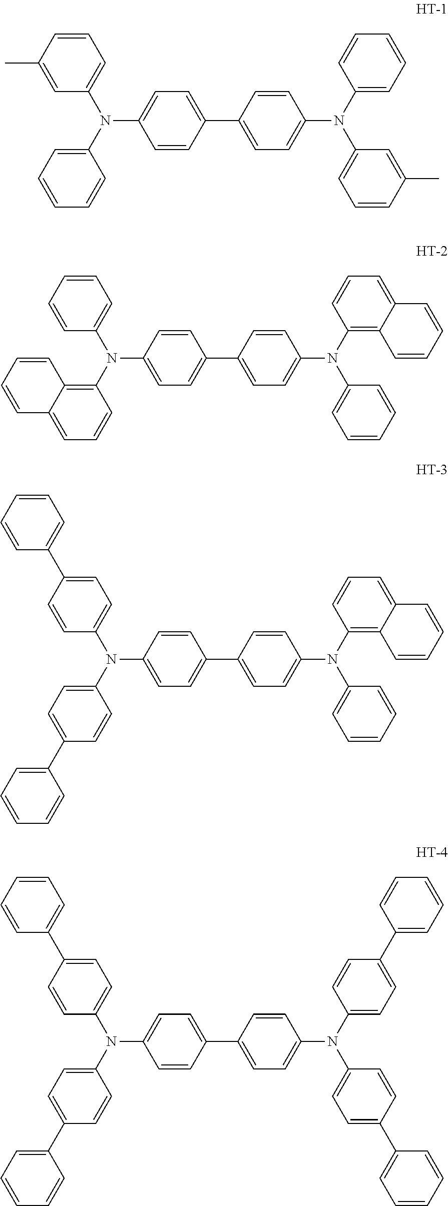

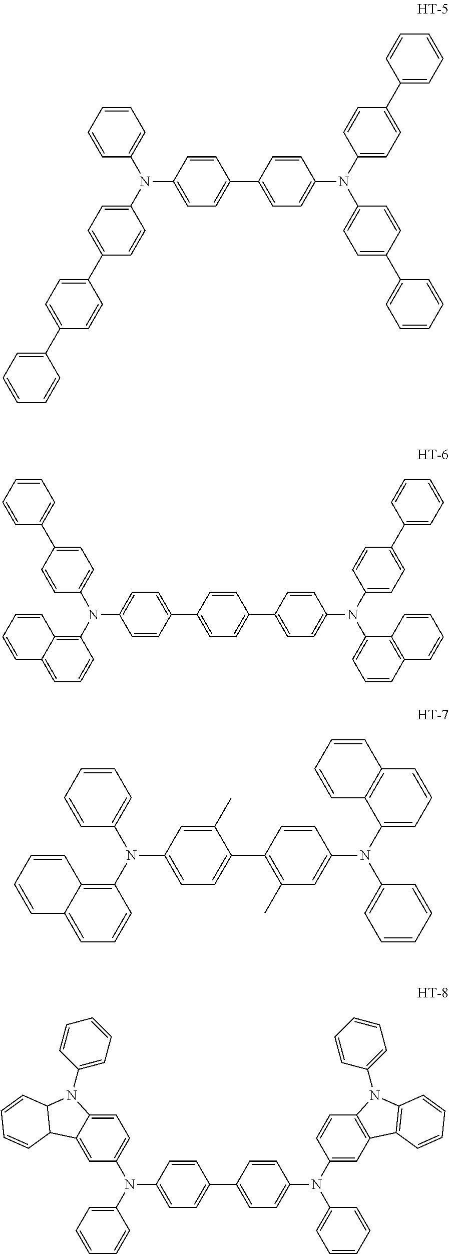 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(N(c3ccc(-c4ccc(-c5ccc(N(c6ccc(-c7ccccc7)cc6)c6cccc7ccccc67)cc5)cc4)cc3)c3cccc4ccccc34)cc2)cc1 ; Cc1cc(N(c2ccccc2)c2cccc3ccccc23)ccc1-c1ccc(N(c2ccccc2)c2cccc3ccccc23)cc1C ; C1=CC2c3cc(N(c4ccccc4)c4ccc(-c5ccc(N(c6ccccc6)c6ccc7c(c6)c6ccccc6n7-c6ccccc6)cc5)cc4)ccc3N(c3ccccc3)C2C=C1]

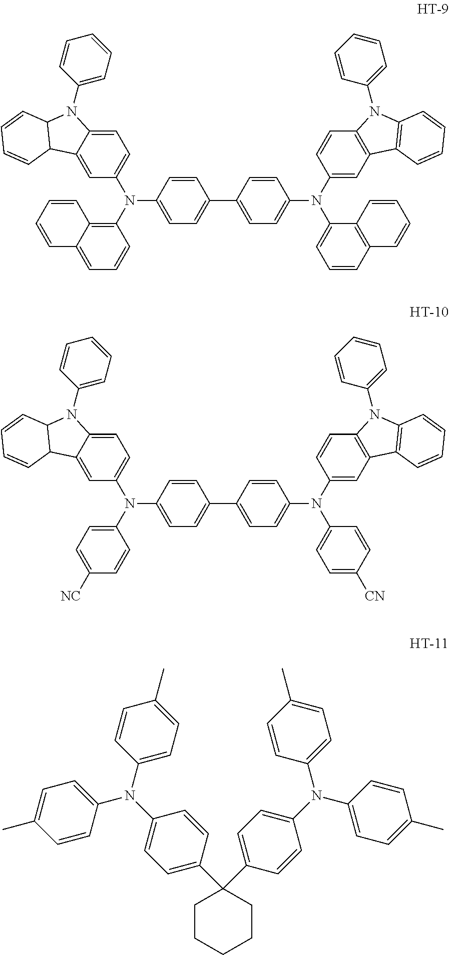

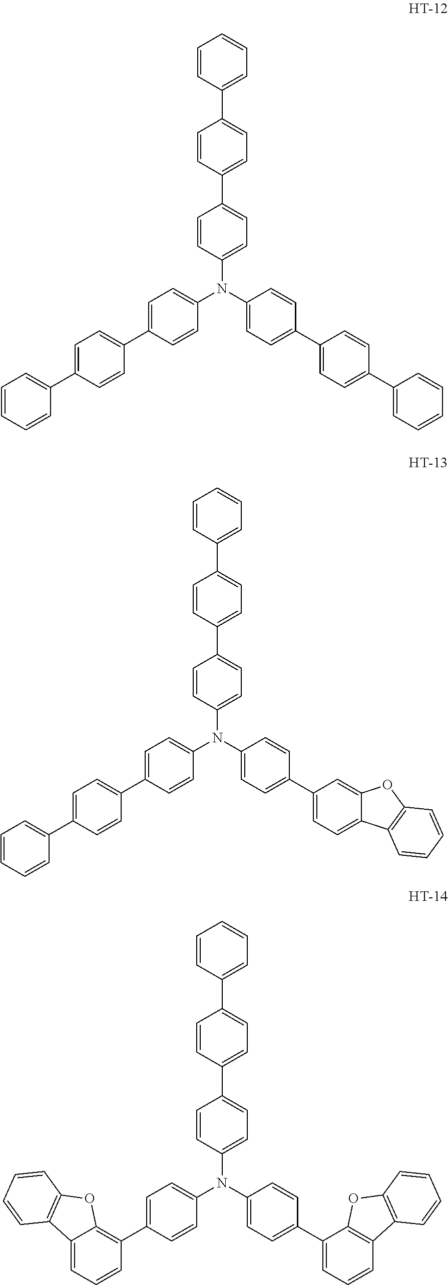 [SMILES: c1ccc(-c2ccc(-c3ccc(N(c4ccc(-c5ccc(-c6ccccc6)cc5)cc4)c4ccc(-c5ccc(-c6ccccc6)cc5)cc4)cc3)cc2)cc1 ; c1ccc(-c2ccc(-c3ccc(N(c4ccc(-c5ccc(-c6ccccc6)cc5)cc4)c4ccc(-c5ccc6c(c5)oc5ccccc56)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

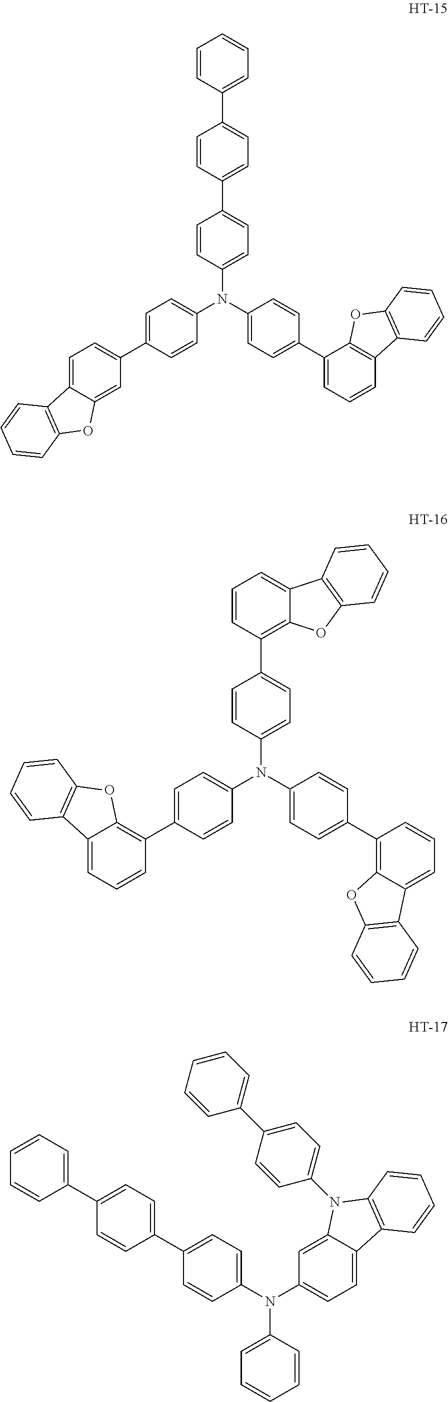 [SMILES: c1ccc(-c2ccc(-c3ccc(N(c4ccc(-c5ccc6c(c5)oc5ccccc56)cc4)c4ccc(-c5cccc6c5oc5ccccc56)cc4)cc3)cc2)cc1 ; c1ccc2c(c1)oc1c(-c3ccc(N(c4ccc(-c5cccc6c5oc5ccccc56)cc4)c4ccc(-c5cccc6c5oc5ccccc56)cc4)cc3)cccc12 ; c1ccc(-c2ccc(-c3ccc(N(c4ccccc4)c4ccc5c6ccccc6n(-c6ccc(-c7ccccc7)cc6)c5c4)cc3)cc2)cc1]

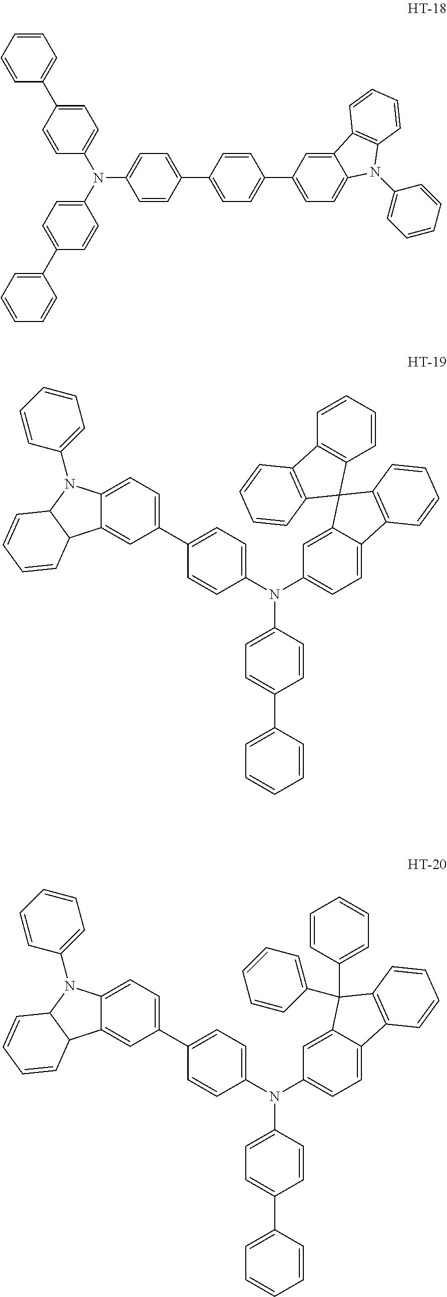 [SMILES: c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1 ; C1=CC2c3cc(-c4ccc(N(c5ccc(-c6ccccc6)cc5)c5ccc6c(c5)C5(c7ccccc7-c7ccccc75)c5ccccc5-6)cc4)ccc3N(c3ccccc3)C2C=C1 ; C1=CC2c3cc(-c4ccc(N(c5ccc(-c6ccccc6)cc5)c5ccc6c(c5)C(c5ccccc5)(c5ccccc5)c5ccccc5-6)cc4)ccc3N(c3ccccc3)C2C=C1]

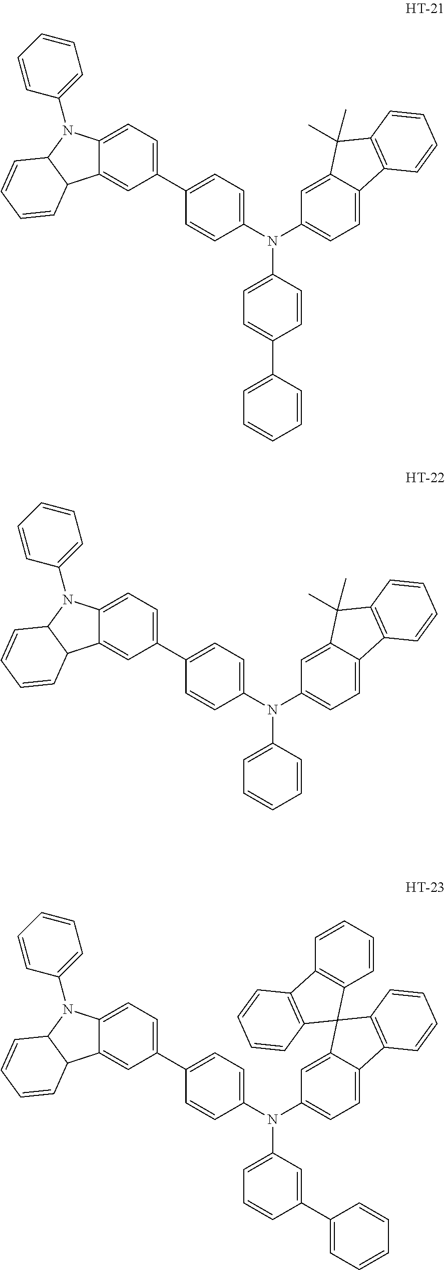 [SMILES: CC1(C)c2ccccc2-c2ccc(N(c3ccc(-c4ccccc4)cc3)c3ccc(-c4ccc5c(c4)C4C=CC=CC4N5c4ccccc4)cc3)cc21 ; CC1(C)c2ccccc2-c2ccc(N(c3ccccc3)c3ccc(-c4ccc5c(c4)C4C=CC=CC4N5c4ccccc4)cc3)cc21 ; C1=CC2c3cc(-c4ccc(N(c5cccc(-c6ccccc6)c5)c5ccc6c(c5)C5(c7ccccc7-c7ccccc75)c5ccccc5-6)cc4)ccc3N(c3ccccc3)C2C=C1]

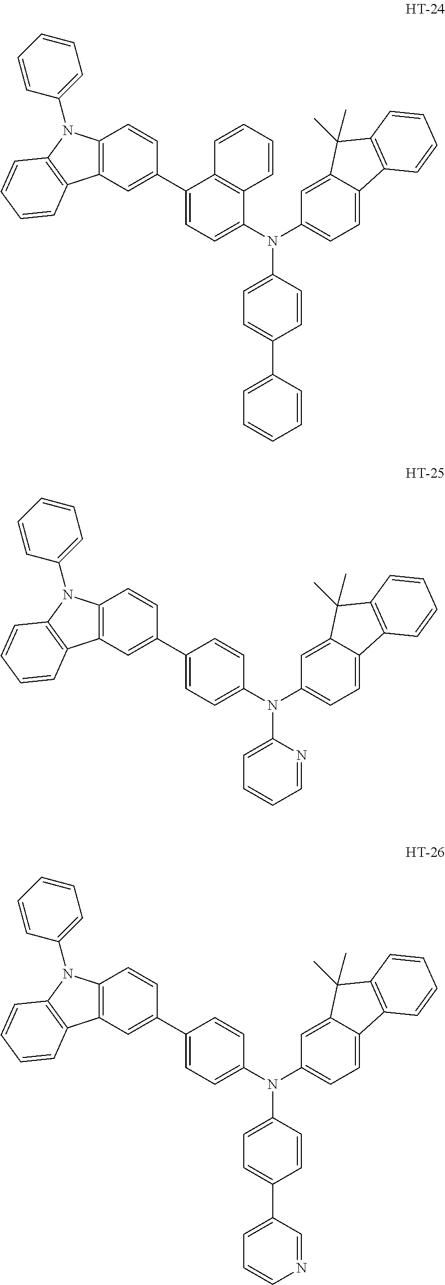 [SMILES: CC1(C)c2ccccc2-c2ccc(N(c3ccc(-c4ccccc4)cc3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccccn3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

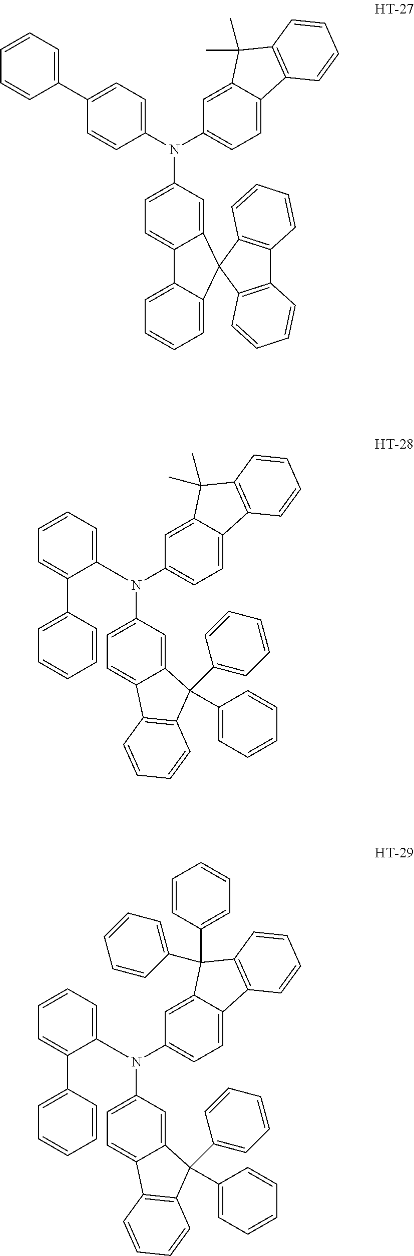 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc4c(c3)C(c3ccccc3)(c3ccccc3)c3ccccc3-4)c3ccccc3-c3ccccc3)cc21 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1]

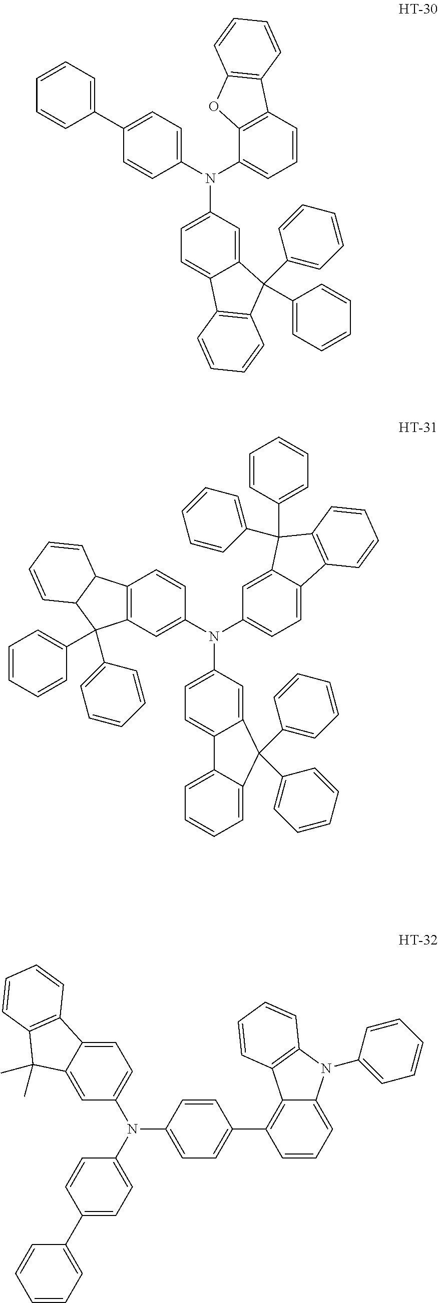 [SMILES: c1ccc(-c2ccc(N(c3ccc4c(c3)C(c3ccccc3)(c3ccccc3)c3ccccc3-4)c3cccc4c3oc3ccccc34)cc2)cc1 ; C1=CC2c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc3C(c3ccccc3)(c3ccccc3)C2C=C1 ; CC1(C)c2ccccc2-c2ccc(N(c3ccc(-c4ccccc4)cc3)c3ccc(-c4cccc5c4c4ccccc4n5-c4ccccc4)cc3)cc21]

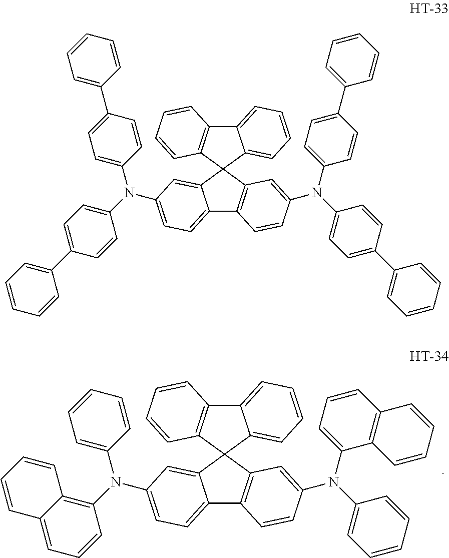 [SMILES: c1ccc(-c2ccc(N(c3ccc(-c4ccccc4)cc3)c3ccc4c(c3)C3(c5ccccc5-c5ccccc53)c3cc(N(c5ccc(-c6ccccc6)cc5)c5ccc(-c6ccccc6)cc5)ccc3-4)cc2)cc1 ; c1ccc(N(c2ccc3c(c2)C2(c4ccccc4-c4ccccc42)c2cc(N(c4ccccc4)c4cccc5ccccc45)ccc2-3)c2cccc3ccccc23)cc1]

The hole injection layer is located between the anode 2 and the hole transporting layer. The hole injection layer may be a single compound material or a combination of a plurality of compounds. For example, the hole injection layer may use one or more compounds of the aforementioned HT-1 to HT-34, or one or more compounds of the following HI1-HI3; or it may use one or more compounds of HT-1 to HT-34 doping with one or more compounds of the following HI1-HI3:

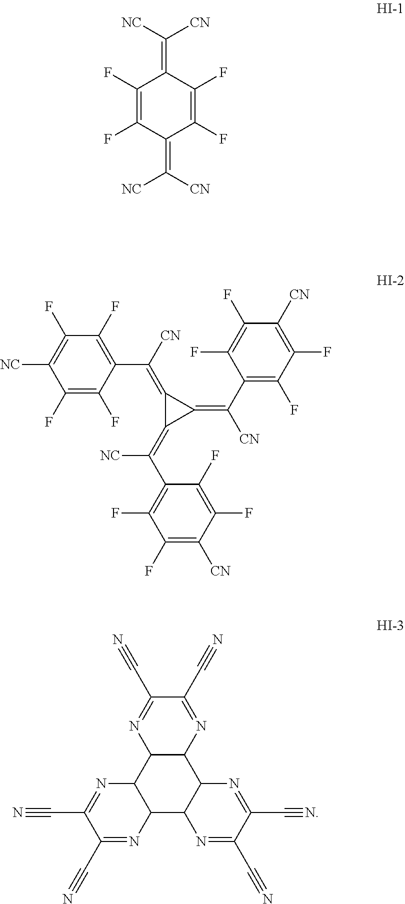 [SMILES: N#CC(C#N)=c1c(F)c(F)c(=C(C#N)C#N)c(F)c1F ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC1=NC2C3N=C(C#N)C(C#N)=NC3C3N=C(C#N)C(C#N)=NC3C2N=C1C#N]

The electron transporting region 5 may be a single-layered electron transporting layer (ETL), including a single-layer electron transporting layer containing only one compound and a single-layer electron transporting layer containing a plurality of compounds. The electron transporting region 5 may also have a multilayer structure including at least two of an electron injection layer (EIL), an electron transporting layer (ETL), and a hole blocking layer (HBL).

In one aspect of the present application, the material of the electron transporting layer may be selected from, but not limited to, one or a combination of more of ET-1 to ET-57 listed below:

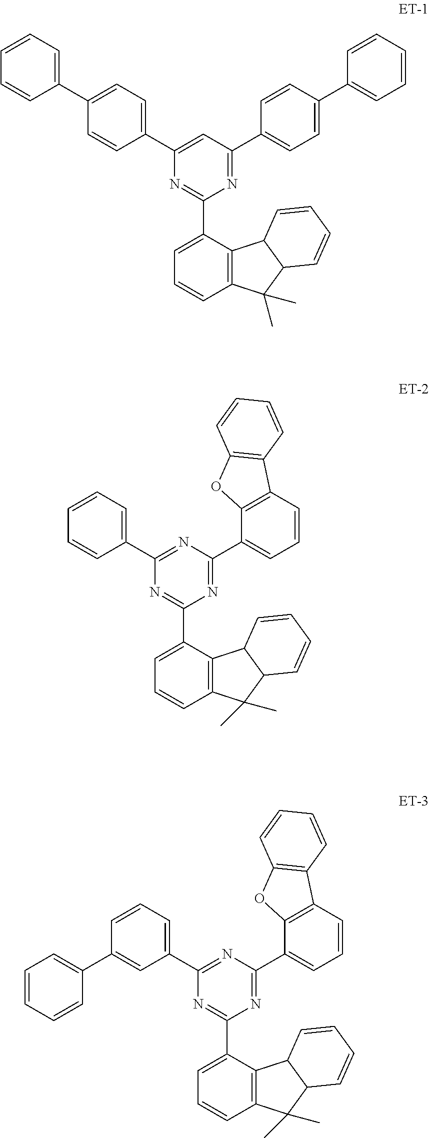 [SMILES: CC1(C)c2cccc(-c3nc(-c4ccc(-c5ccccc5)cc4)cc(-c4ccc(-c5ccccc5)cc4)n3)c2C2C=CC=CC21 ; CC1(C)c2cccc(-c3nc(-c4ccccc4)nc(-c4cccc5c4oc4ccccc45)n3)c2C2C=CC=CC21 ; CC1(C)c2cccc(-c3nc(-c4cccc(-c5ccccc5)c4)nc(-c4cccc5c4oc4ccccc45)n3)c2C2C=CC=CC21]

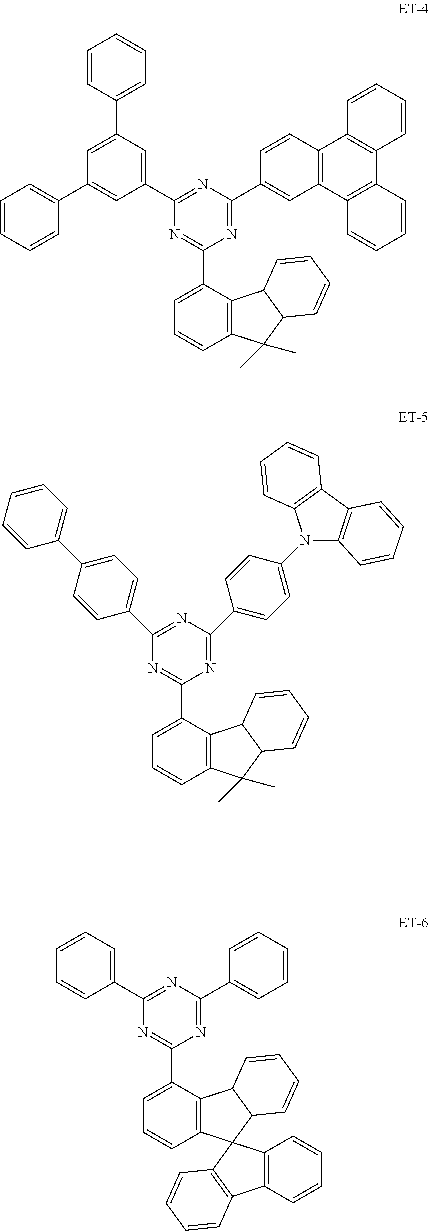 [SMILES: CC1(C)c2cccc(-c3nc(-c4cc(-c5ccccc5)cc(-c5ccccc5)c4)nc(-c4ccc5c6ccccc6c6ccccc6c5c4)n3)c2C2C=CC=CC21 ; CC1(C)c2cccc(-c3nc(-c4ccc(-c5ccccc5)cc4)nc(-c4ccc(-n5c6ccccc6c6ccccc65)cc4)n3)c2C2C=CC=CC21 ; C1=CC2c3c(-c4nc(-c5ccccc5)nc(-c5ccccc5)n4)cccc3C3(c4ccccc4-c4ccccc43)C2C=C1]

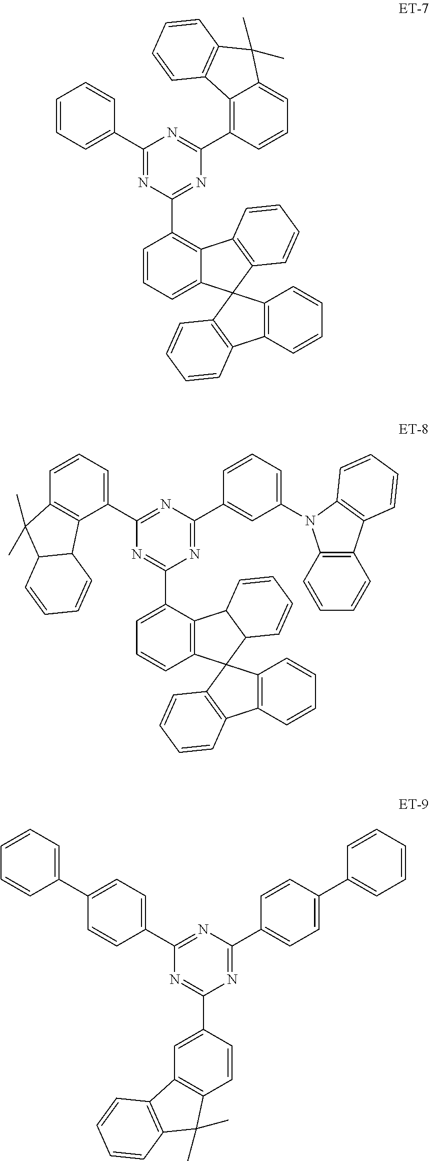 [SMILES: CC1(C)c2ccccc2-c2c(-c3nc(-c4ccccc4)nc(-c4cccc5c4-c4ccccc4C54c5ccccc5-c5ccccc54)n3)cccc21 ; CC1(C)c2cccc(-c3nc(-c4cccc(-n5c6ccccc6c6ccccc65)c4)nc(-c4cccc5c4C4C=CC=CC4C54c5ccccc5-c5ccccc54)n3)c2C2C=CC=CC21 ; CC1(C)c2ccccc2-c2cc(-c3nc(-c4ccc(-c5ccccc5)cc4)nc(-c4ccc(-c5ccccc5)cc4)n3)ccc21]

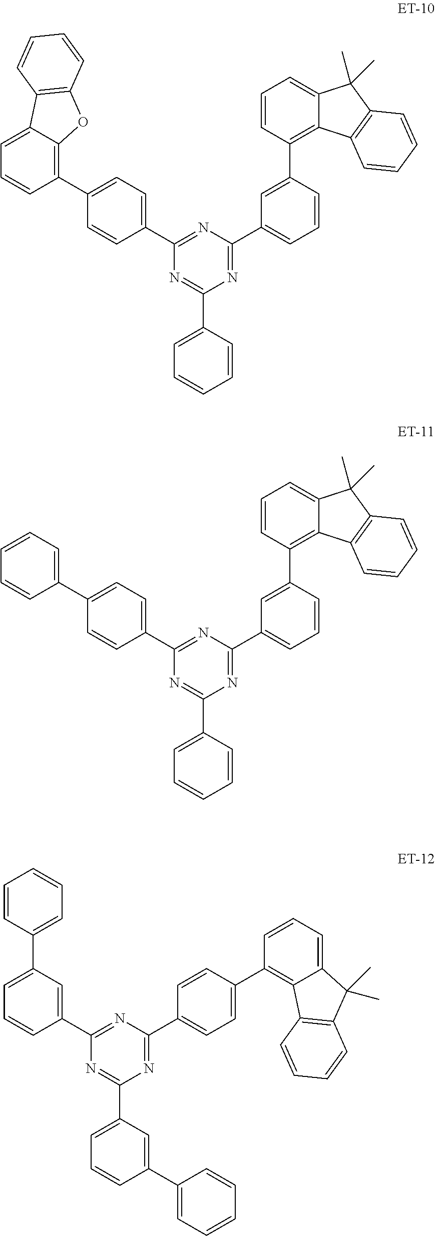 [SMILES: CC1(C)c2ccccc2-c2c(-c3cccc(-c4nc(-c5ccccc5)nc(-c5ccc(-c6cccc7c6oc6ccccc67)cc5)n4)c3)cccc21 ; CC1(C)c2ccccc2-c2c(-c3cccc(-c4nc(-c5ccccc5)nc(-c5ccc(-c6ccccc6)cc5)n4)c3)cccc21 ; CC1(C)c2ccccc2-c2c(-c3ccc(-c4nc(-c5cccc(-c6ccccc6)c5)nc(-c5cccc(-c6ccccc6)c5)n4)cc3)cccc21]

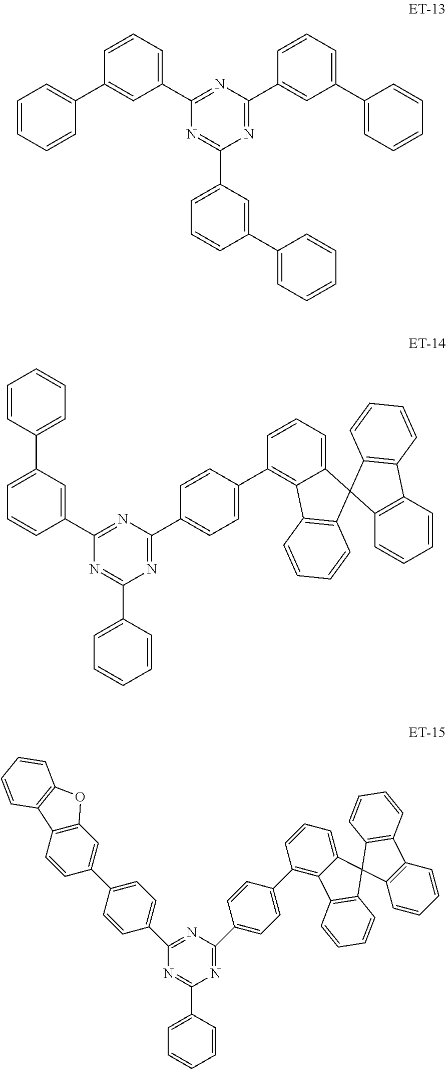 [SMILES: c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4ccccc4)nc(-c4ccc(-c5cccc6c5-c5ccccc5C65c6ccccc6-c6ccccc65)cc4)n3)c2)cc1 ; c1ccc(-c2nc(-c3ccc(-c4ccc5c(c4)oc4ccccc45)cc3)nc(-c3ccc(-c4cccc5c4-c4ccccc4C54c5ccccc5-c5ccccc54)cc3)n2)cc1]

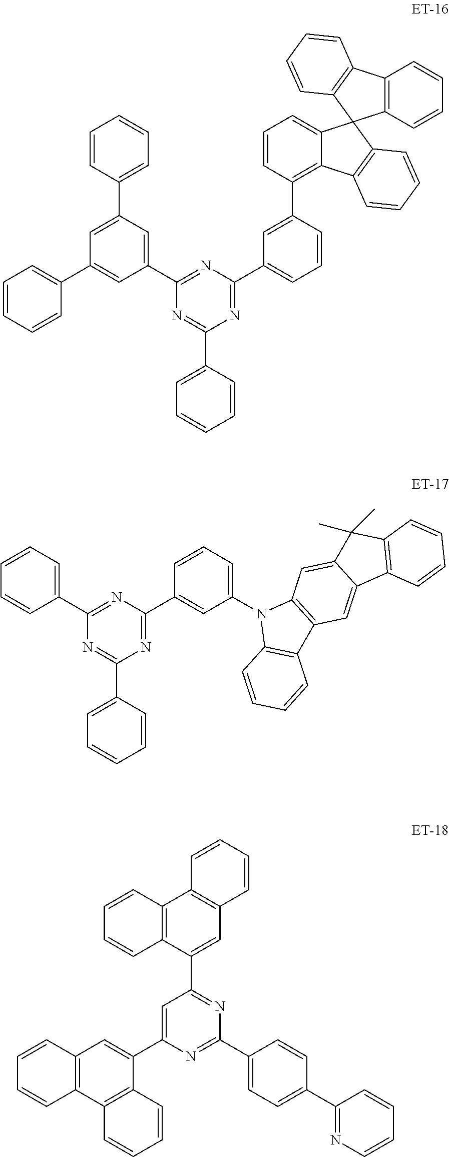 [SMILES: c1ccc(-c2cc(-c3ccccc3)cc(-c3nc(-c4ccccc4)nc(-c4cccc(-c5cccc6c5-c5ccccc5C65c6ccccc6-c6ccccc65)c4)n3)c2)cc1 ; CC1(C)c2ccccc2-c2cc3c4ccccc4n(-c4cccc(-c5nc(-c6ccccc6)nc(-c6ccccc6)n5)c4)c3cc21 ; c1ccc(-c2ccc(-c3nc(-c4cc5ccccc5c5ccccc45)cc(-c4cc5ccccc5c5ccccc45)n3)cc2)nc1]

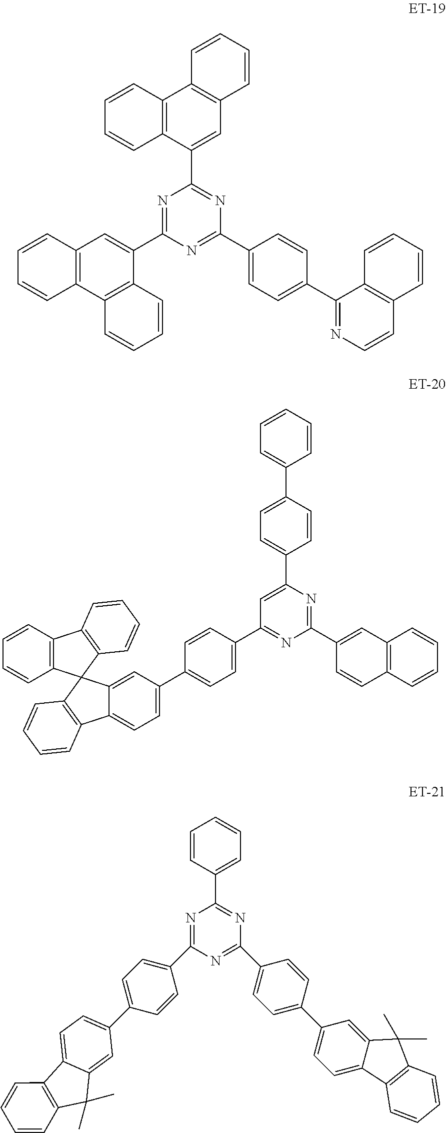 [SMILES: c1ccc2c(-c3ccc(-c4nc(-c5cc6ccccc6c6ccccc56)nc(-c5cc6ccccc6c6ccccc56)n4)cc3)nccc2c1 ; c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

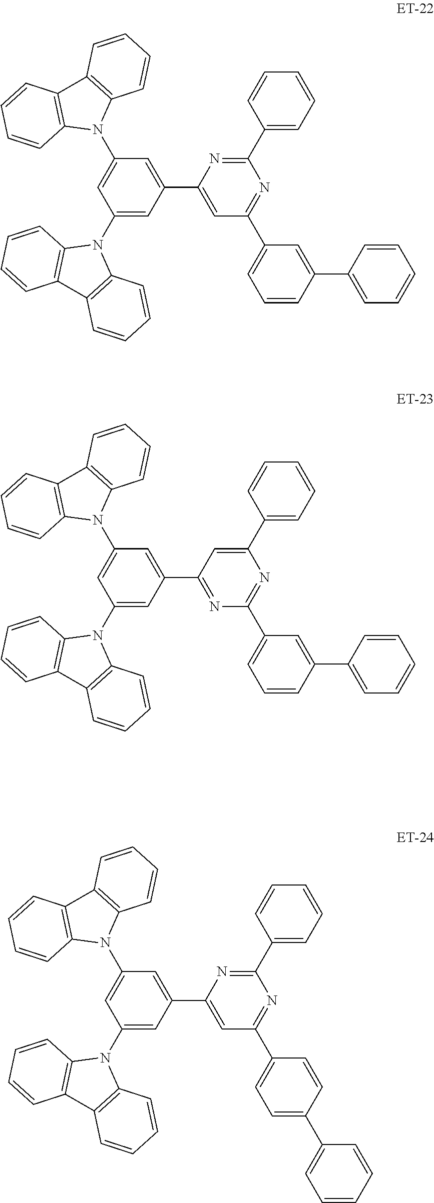 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2cccc(-c3nc(-c4ccccc4)cc(-c4cc(-n5c6ccccc6c6ccccc65)cc(-n5c6ccccc6c6ccccc65)c4)n3)c2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

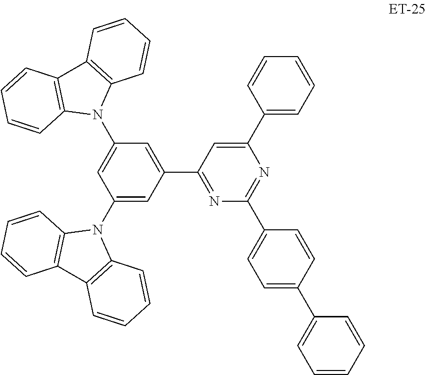 [SMILES: c1ccc(-c2ccc(-c3nc(-c4ccccc4)cc(-c4cc(-n5c6ccccc6c6ccccc65)cc(-n5c6ccccc6c6ccccc65)c4)n3)cc2)cc1]

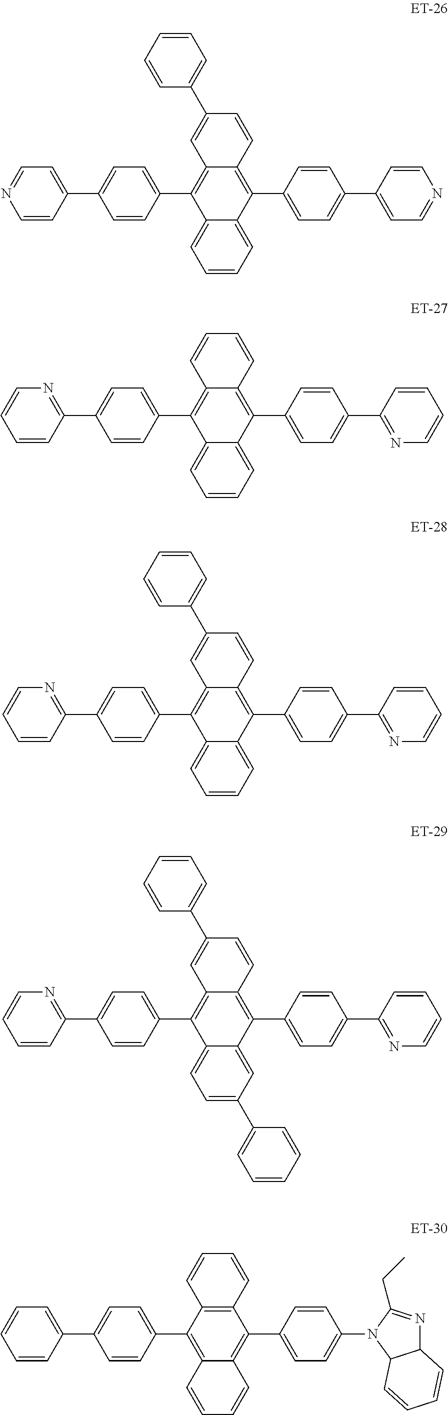 [SMILES: c1ccc(-c2ccc3c(-c4ccc(-c5ccncc5)cc4)c4ccccc4c(-c4ccc(-c5ccncc5)cc4)c3c2)cc1 ; c1ccc(-c2ccc(-c3c4ccccc4c(-c4ccc(-c5ccccn5)cc4)c4ccccc34)cc2)nc1 ; c1ccc(-c2ccc3c(-c4ccc(-c5ccccn5)cc4)c4ccccc4c(-c4ccc(-c5ccccn5)cc4)c3c2)cc1 ; c1ccc(-c2ccc3c(-c4ccc(-c5ccccn5)cc4)c4cc(-c5ccccc5)ccc4c(-c4ccc(-c5ccccn5)cc4)c3c2)cc1 ; CCC1=NC2C=CC=CC2N1c1ccc(-c2c3ccccc3c(-c3ccc(-c4ccccc4)cc3)c3ccccc23)cc1]

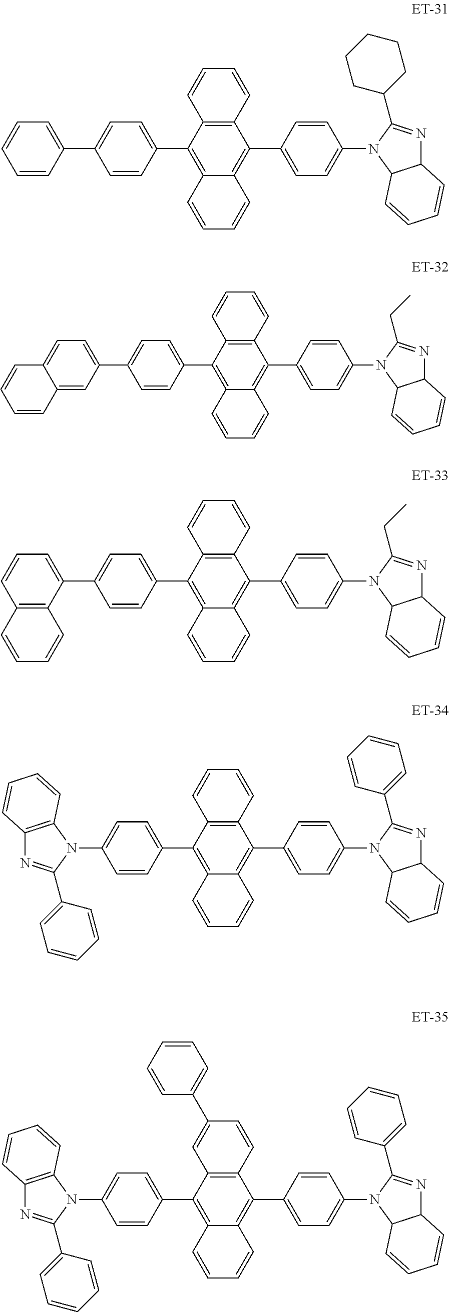 [SMILES: C1=CC2N=C(C3CCCCC3)N(c3ccc(-c4c5ccccc5c(-c5ccc(-c6ccccc6)cc5)c5ccccc45)cc3)C2C=C1 ; CCC1=NC2C=CC=CC2N1c1ccc(-c2c3ccccc3c(-c3ccc(-c4ccc5ccccc5c4)cc3)c3ccccc23)cc1 ; CCC1=NC2C=CC=CC2N1c1ccc(-c2c3ccccc3c(-c3ccc(-c4cccc5ccccc45)cc3)c3ccccc23)cc1 ; C1=CC2N=C(c3ccccc3)N(c3ccc(-c4c5ccccc5c(-c5ccc(-n6c(-c7ccccc7)nc7ccccc76)cc5)c5ccccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccccc6)ccc45)cc3)C2C=C1]

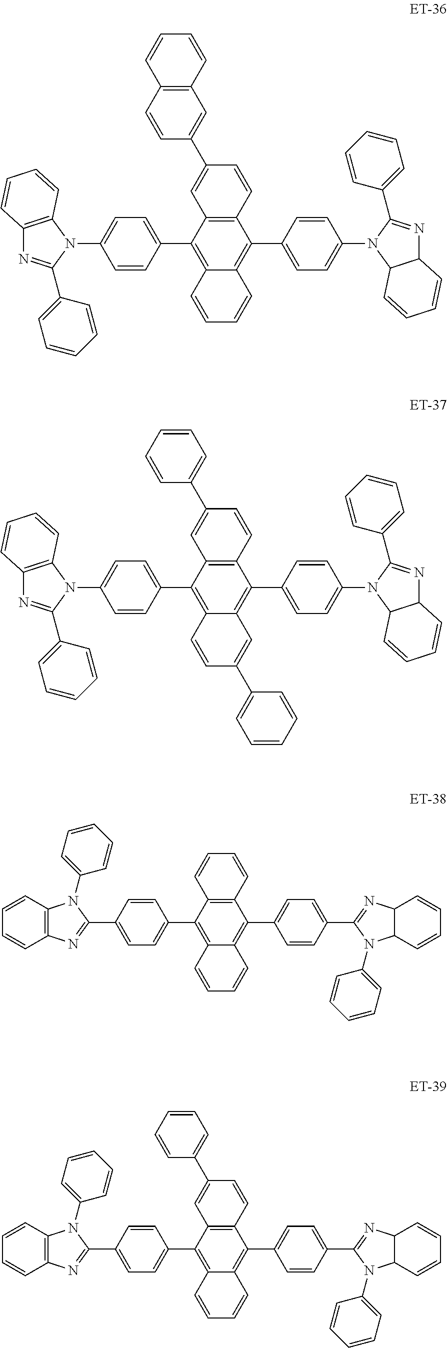 [SMILES: C1=CC2N=C(c3ccccc3)N(c3ccc(-c4c5ccccc5c(-c5ccc(-n6c(-c7ccccc7)nc7ccccc76)cc5)c5cc(-c6ccc7ccccc7c6)ccc45)cc3)C2C=C1 ; C1=CC2N=C(c3ccccc3)N(c3ccc(-c4c5ccc(-c6ccccc6)cc5c(-c5ccc(-n6c(-c7ccccc7)nc7ccccc76)cc5)c5ccc(-c6ccccc6)cc45)cc3)C2C=C1 ; C1=CC2N=C(c3ccc(-c4c5ccccc5c(-c5ccc(-c6nc7ccccc7n6-c6ccccc6)cc5)c5ccccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccccc6)ccc45)cc3)N(c3ccccc3)C2C=C1]

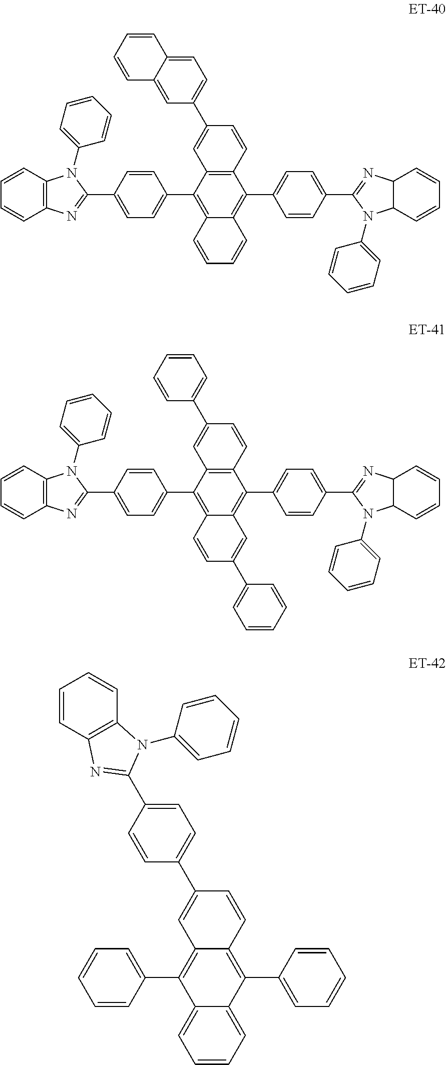 [SMILES: C1=CC2N=C(c3ccc(-c4c5ccccc5c(-c5ccc(-c6nc7ccccc7n6-c6ccccc6)cc5)c5cc(-c6ccc7ccccc7c6)ccc45)cc3)N(c3ccccc3)C2C=C1 ; C1=CC2N=C(c3ccc(-c4c5ccc(-c6ccccc6)cc5c(-c5ccc(-c6nc7ccccc7n6-c6ccccc6)cc5)c5ccc(-c6ccccc6)cc45)cc3)N(c3ccccc3)C2C=C1 ; c1ccc(-c2c3ccccc3c(-c3ccccc3)c3cc(-c4ccc(-c5nc6ccccc6n5-c5ccccc5)cc4)ccc23)cc1]

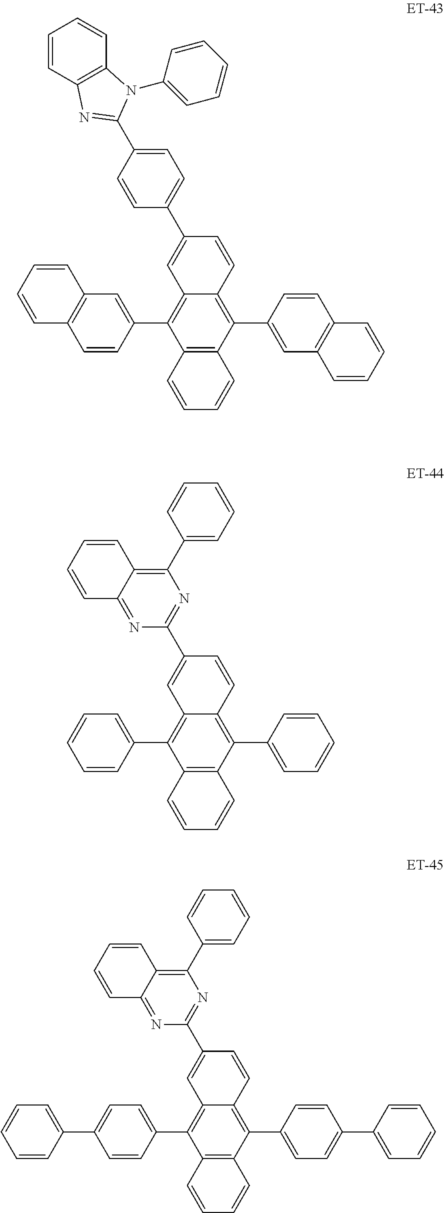 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2nc(-c3ccc4c(-c5ccccc5)c5ccccc5c(-c5ccccc5)c4c3)nc3ccccc23)cc1 ; c1ccc(-c2ccc(-c3c4ccccc4c(-c4ccc(-c5ccccc5)cc4)c4cc(-c5nc(-c6ccccc6)c6ccccc6n5)ccc34)cc2)cc1]

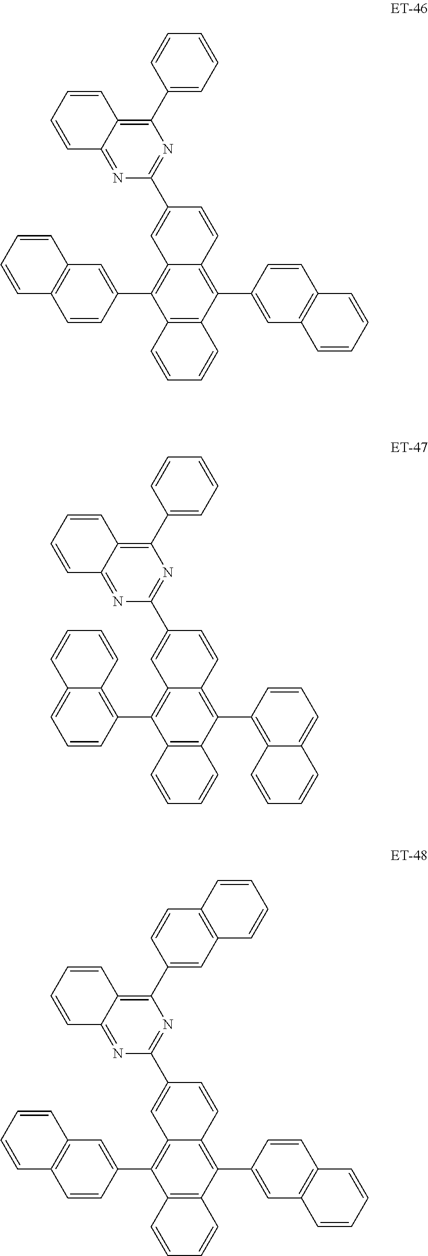 [SMILES: c1ccc(-c2nc(-c3ccc4c(-c5ccc6ccccc6c5)c5ccccc5c(-c5ccc6ccccc6c5)c4c3)nc3ccccc23)cc1 ; c1ccc(-c2nc(-c3ccc4c(-c5cccc6ccccc56)c5ccccc5c(-c5cccc6ccccc56)c4c3)nc3ccccc23)cc1 ; c1ccc2cc(-c3nc(-c4ccc5c(-c6ccc7ccccc7c6)c6ccccc6c(-c6ccc7ccccc7c6)c5c4)nc4ccccc34)ccc2c1]

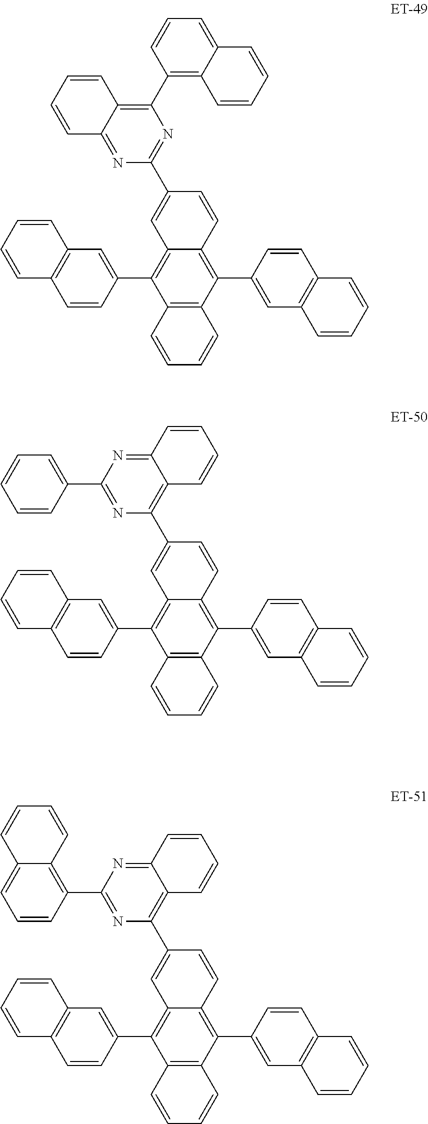 [SMILES: c1ccc2cc(-c3c4ccccc4c(-c4ccc5ccccc5c4)c4cc(-c5nc(-c6cccc7ccccc67)c6ccccc6n5)ccc34)ccc2c1 ; c1ccc(-c2nc(-c3ccc4c(-c5ccc6ccccc6c5)c5ccccc5c(-c5ccc6ccccc6c5)c4c3)c3ccccc3n2)cc1 ; c1ccc2cc(-c3c4ccccc4c(-c4ccc5ccccc5c4)c4cc(-c5nc(-c6cccc7ccccc67)nc6ccccc56)ccc34)ccc2c1]

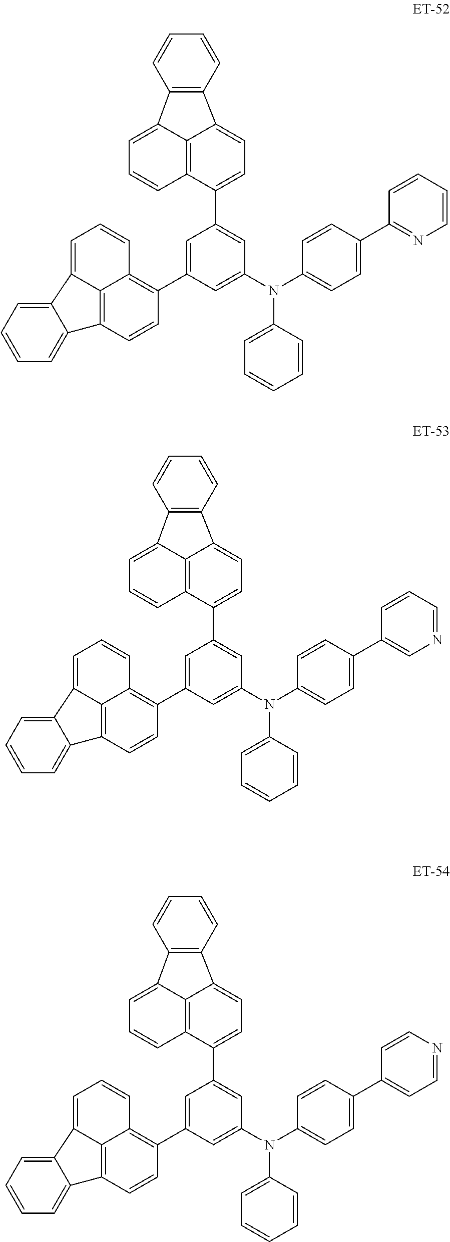 [SMILES: c1ccc(N(c2ccc(-c3ccccn3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3cccnc3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3ccncc3)cc2)c2cc(-c3ccc4c5c(cccc35)-c3ccccc3-4)cc(-c3ccc4c5c(cccc35)-c3ccccc3-4)c2)cc1]

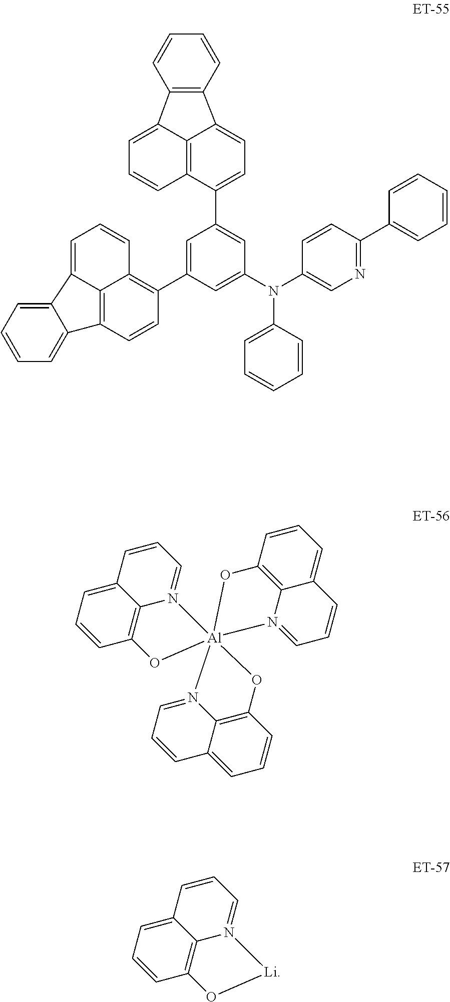

The structure of the light emitting device may further include an electron injection layer located between the electron transporting layer and the cathode 6, and the material of the electron injection layer includes, but is not limited to, one or a combinations of more of the listed below:

LiQ, LiF, NaCl, CsF, Li₂O, Cs₂CO₃, BaO, Na, Li, and Ca.

The thicknesses of the above-mentioned layers can adopt the conventional thicknesses of these layers in the art.

The present application also provides a preparation method of the organic electroluminescent device. Taking FIG. 1 as an example, it includes sequentially depositing an anode 2, a hole transporting region 3, an light emitting layer 4, an electron transporting region 5, and a cathode 6 on a substrate 1, then encapsulating them. Where when preparing the light emitting layer 4, the light emitting layer 4 is formed by a method of co-evaporation of a triplet-triplet annihilation material source and a thermally activated delayed fluorescence material source.

Specifically, the preparation method of the organic electroluminescent device of the present application includes the following steps:

1. sonicating the glass plate coated with an anode material in a commercial cleaning agent, rinsing in a deionized water, ultrasonically degreasing in a mixed solvent of acetone: ethanol, and baking in a clean environment to completely remove water, cleaning with UV light and ozone and performing a surface bombardment with a low-energy cation beam;

2. placing the above glass plate with an anode in a vacuum chamber, and evacuating to 1×10⁻⁵˜9×10⁻³ Pa, and vacuum-evaporating a hole injection layer on this anode layer film with an evaporation rate of 0.1-0.5 nm/s;

3. vacuum-evaporating a hole transporting layer on the hole injection layer with an evaporation rate of 0.1-0.5 nm/s;

4. vacuum-evaporating a light emitting layer of the device on the hole transporting layer, the light emitting layer including a host material and a TADF dye, and using a multi-source co-evaporation method to adjust an evaporation rate of the host material and an evaporation rate of the dye so that the dye reaches a preset doping ratio;

5. vacuum-evaporating an electron transporting layer material of the device on the light emitting layer with an evaporation rate of 0.1-0.5 nm/s;

6. vacuum-evaporating LiF as an electron injection layer on the electron transporting layer at an evaporation rate of 0.1-0.5 nm/s, and vacuum-evaporating an Al layer as a cathode of the device at an evaporation rate of 0.5-1 nm/s.

An embodiment of the present application further provides a display apparatus, including the organic electroluminescent device provided as described above. The display apparatus may specifically be a display device such as an OLED display, and any product or component including the display device and having a display function, such as a television, a digital camera, a mobile phone, a tablet computer, etc. This display apparatus has the same advantages as the above-mentioned organic electroluminescent device over the prior art, and is not repeated here.

The organic electroluminescent device of the present application is further described below through specific embodiments.

### Embodiments 1-21

Embodiments 1-21 respectively provide an organic electroluminescent device, the structure of which includes an ITO anode, a hole injection layer (HIL), a hole transporting layer (HTL), a light emitting layer (EML), and an electron transporting layer (ETL), an electron injection layer (EIL), and a cathode.

Where the material of the hole injection layer is HI-2, and the total thickness is generally 5-30 nm, and specifically is 10 nm in the present embodiment. The material of the hole transporting layer is HT-28, and the total thickness is generally 5-50 nm, and specifically is 50 nm in the embodiments. The host material of the light emitting layer is a TTA material, the dye is a TADF material, the doping concentration of the dye is 0.1 wt %-40 wt %, the thickness of the light emitting layer is generally 1-60 nm, and specifically is 30 nm in the embodiments. The material of the electron transporting layer is ET-53, and the thickness is generally 5-30 nm, and specifically is 30 nm in the embodiments. The materials of the electron injection layer and cathode are selected from LiF (0.5 nm) and metal aluminum (150 nm).

In the organic electroluminescent device provided in Embodiments 1-21, specific selections and doping concentrations of the host material and the dye are shown in Table 1.

### Comparative Examples 1-5

Comparative Examples 1-5 provide an organic electroluminescent device, the structure of which is substantially the same as those of Embodiments 1-21, and the parameters of the corresponding functional layers are basically the same as those of Embodiments 1-21, except that the materials used in the host material and the dye of the light emitting layer are inconsistent or doping concentrations are inconsistent. The selections of specific materials are shown in Table 1.

Where DPEPO in Comparative Example 1, mCBP in Comparative Example 2 and DPAC-TRZ in Comparative Example 4 are shown below:

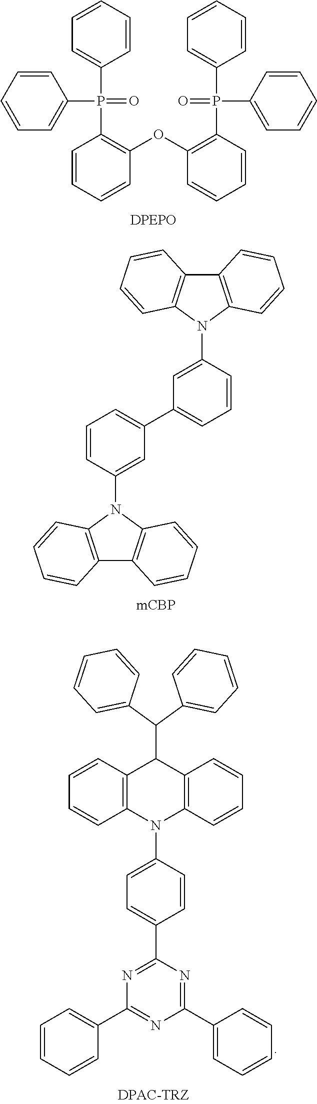 [SMILES: O=P(c1ccccc1)(c1ccccc1)c1ccccc1Oc1ccccc1P(=O)(c1ccccc1)c1ccccc1 ; c1cc(-c2cccc(-n3c4ccccc4c4ccccc43)c2)cc(-n2c3ccccc3c3ccccc32)c1 ; c1ccc(-c2nc(-c3ccccc3)nc(-c3ccc(N4c5ccccc5C(C(c5ccccc5)c5ccccc5)c5ccccc54)cc3)n2)cc1]

The following performance measurements were performed on the organic electroluminescent devices (Embodiments 1-21, Comparative Examples 1-5) prepared by the above processes: current, voltage, brightness, luminescence spectrum, current efficiency, and external quantum efficiency and other characteristics of the devices are tested synchronously with a PR 655 spectral scanning luminance meter and a Keithley K 2400 digital source meter system, and the lifetime is tested by MC-6000.

1. Turn-on voltage: increasing the voltage at a rate of 0.1V per second, and measuring a voltage when the brightness of the organic electroluminescent device reaches 1 cd/m², as the turn-on voltage;

2. The lifetime test of LT90 is as follows: by setting different test brightness, a brightness and lifetime decay curve of the organic electroluminescent device is obtained, so as to obtain a lifetime value of the device under the required decay brightness. That is, set the test brightness to 5000 cd/m², maintain a constant current, and measure the time for the brightness of the organic electroluminescent device to decrease to 4500 cd/m², in hours.

3. fluorescence quantum yield of the instantaneous component: doping the TADF material into the host DPEPO to prepare a 20 wt % doped film with a thickness of 60 nm. The steady-state-transient fluorescence spectrometer (Edinburgh-FLS900) was used together with an integrating sphere to measure the total fluorescence quantum yield of the doped film (the sum of instantaneous and delayed fluorescence) and ratios of the instantaneous and delayed fluorescence. Estimating the fluorescence quantum yield of the instantaneous component according to the ratio of the instantaneous fluorescence. Reference: J. Mater. Chem. C, 2018, 6, 7728-7733.

The above specific test results are shown in Table 1.

TABLE 1

| | | | Fluorescence | | External | | |
|---|---|---|---|---|---|---|---|
| | | | quantum | Maximum | quantum | | |
| | | | yield of | external | efficiency | | |
| | Host | Dye and doping | instantaneous | quantum | at 5000 | Efficiency | |
| | material | concentration | component | efficiency/100% | cd/m²/100% | roll-off | LT90/h |
| Embodiment 1 | H4 | 0.1% T-12 | 73% | 10.2 | 9.4 | 8.2% | 80 |
| Embodiment 2 | H4 | 10% T-12 | 73% | 13.5 | 12.4 | 8.4% | 77 |
| Embodiment 3 | H4 | 20% T-12 | 73% | 15.2 | 13.9 | 8.7% | 75 |
| Embodiment 4 | H4 | 30% T-12 | 73% | 13.7 | 12.0 | 12.1% | 40 |
| Embodiment 5 | H4 | 40% T-12 | 73% | 13.1 | 11.1 | 15.1% | 35 |
| Embodiment 6 | H12 | 15% T-12 | 73% | 14.8 | 13.6 | 8.1% | 65 |
| Embodiment 7 | H12 | 15% T-24 | 78% | 15.2 | 14.0 | 7.7% | 72 |
| Embodiment 8 | H12 | 15% T-73 | 54% | 12.9 | 11.3 | 12.3% | 45 |
| Embodiment 9 | H52 | 25% T-23 | 59% | 13.1 | 11.0 | 15.7% | 44 |
| Embodiment 10 | H55 | 12% T-71 | 81% | 15.2 | 14.1 | 7.2% | 82 |
| Embodiment 11 | H58 | 5% T-72 | 80% | 15.0 | 13.7 | 8.9% | 68 |
| Embodiment 12 | H60 | 10% T-19 | 76% | 14.1 | 12.8 | 9.1% | 72 |
| Embodiment 13 | H65 | 15% T-22 | 75% | 14.2 | 12.9 | 9.2% | 64 |
| Embodiment 14 | H50 | 13% T-20 | 64% | 13.1 | 11.7 | 10.5% | 61 |
| Embodiment 15 | H55 | 10% T-23 | 59% | 12.9 | 11.4 | 11.3% | 56 |
| Embodiment 16 | H52 | 11% T-71 | 81% | 14.7 | 13.3 | 9.5% | 79 |
| Embodiment 17 | H4 | 16% T-72 | 80% | 14.5 | 13.0 | 10.0% | 88 |
| Embodiment 18 | H65 | 30% T-19 | 76% | 13.5 | 11.2 | 16.7% | 48 |
| Embodiment 19 | H65 | 7% T-22 | 75% | 14.6 | 13.2 | 9.9% | 81 |
| Embodiment 20 | H58 | 10% T-19 | 76% | 13.8 | 12.4 | 9.8% | 65 |
| Embodiment 21 | H12 | 13% T-22 | 75% | 13.2 | 11.9 | 9.7% | 76 |
| Comparative | H4 | 50% T-12 | 73% | 12.8 | 10.5 | 18.1% | 28 |
| Example 1 | | | | | | | |
| Comparative | DPEPO | 15% T-24 | 78% | 20.2 | 14.1 | 30.2% | 0.01 |
| Example 2 | | | | | | | |
| Comparative | mCBP | 15% T-24 | 78% | 18.9 | 14.3 | 24.3% | 0.8 |
| Example 3 | | | | | | | |
| Comparative | T-65 | 15% T-24 | 78% | 21.2 | 16.4 | 22.6% | 1.2 |
| Example 4 | | | | | | | |
| Comparative | H12 | 15% DPAC-TRZ | 36% | 10.8 | 8.4 | 23.7% | 6.5 |
| Example 5 | | | | | | | |

According to Table 1:

1. Compared with Comparative Examples 2-5, the structure of the organic electroluminescent device of the present application, that is, the organic layer being a combination of the TTA material and the TADF material, can effectively reduce the efficiency roll-off of the device and increase the lifetime of the device;

2. The structure of the organic electroluminescent device of the present application has a maximum external fluorescence quantum yield of more than 10%, which breaks through an external quantum efficiency of the conventional fluorescence of 5%;

3. According to Embodiments 1-5 and Comparative Example 1, it can be found that in the organic electroluminescent device of the present application, when the doping concentration of the dye is 0.1-40%, the device has good performances in external quantum efficiency, efficiency roll-off, and lifetime, and further, when the doping concentration of the dye is 0.1-20%, its external quantum efficiency, efficiency roll-off and lifetime are obviously better;

4. According to Embodiments 6-8 and Comparative Example 5, it can be found that in the organic electroluminescent device of the present application, when a TADF dye having a fluorescence quantum yield of an instantaneous component of greater than 50% is selected, the device has relatively good performances in external quantum efficiency, efficiency roll-off and lifetime, and further, when a TADF dye having a fluorescence quantum yield of an instantaneous component of greater than 75% is selected, the device has significantly better performances in external quantum efficiency, efficiency roll-off, and lifetime.

Finally, it should be noted that the above embodiments are only used to describe technical solutions of the present application, rather than limiting them. Although the present application has been described in detail with reference to the foregoing embodiments, those skilled in the art should understand that: the technical solutions described in the foregoing embodiments may still be modified, or some or all of the technical features therein may be equivalently replaced; and these modifications or replacements do not deviate the essence of the corresponding technical solutions from the scope of the technical solutions of the embodiments of the present application.

What is claimed is:

1. An organic electroluminescent device, comprising: a light emitting layer, wherein
the light emitting layer comprises a host material and a dye, the host material is a triplet-triplet annihilation material, and the dye comprises a thermally activated delayed fluorescence material; and
a singlet energy level of the triplet-triplet annihilation material is greater than a singlet energy level of the thermally activated delayed fluorescence material; and a triplet energy level of the triplet-triplet annihilation material is smaller than a triplet energy level of the thermally activated delayed fluorescence material.

2. The organic electroluminescent device according to claim 1, wherein an energy level difference between the singlet energy level and the triplet energy level of the triplet-triplet annihilation material is >0.5 eV.

3. The organic electroluminescent device according to claim 2, wherein twice of the triplet energy level of the triplet-triplet annihilation material is higher than the singlet energy level of the triplet-triplet annihilation material.

4. The organic electroluminescent device according to claim 1, wherein an energy level difference between the singlet energy level and the triplet energy level of the thermally activated delayed fluorescence material is ≤0.3 eV.

5. The organic electroluminescent device according to claim 1, wherein a mass ratio of the thermally activated delayed fluorescence material in the light emitting layer is 0.1 wt %-40 wt %.

6. The organic electroluminescent device according to claim 5, wherein the mass ratio of the thermally activated delayed fluorescence material in the light emitting layer is 0.1 wt %-20 wt %.

7. The organic electroluminescent device according to claim 6, wherein the mass ratio of the thermally activated delayed fluorescence material in the light emitting layer is 0.1 wt %-10 wt %.

8. The organic electroluminescent device according to claim 1, wherein a fluorescence quantum yield of an instantaneous component of the thermally activated delayed fluorescence material is greater than 50%.

9. The organic electroluminescent device according to claim 8, wherein the fluorescence quantum yield of the instantaneous component of the thermally activated delayed fluorescence material is greater than 75%.

10. The organic electroluminescent device according to claim 1, wherein the triplet-triplet annihilation material is a compound containing one or more of naphthyl, anthryl, perylenyl, pyrenyl, phenanthryl, fluoranthenyl, triphenylenyl, tetracenyl, pentacenyl, and oxazolyl.

11. The organic electroluminescent device according to claim 10, wherein the triplet-triplet annihilation material is a compound having one of the following structures:

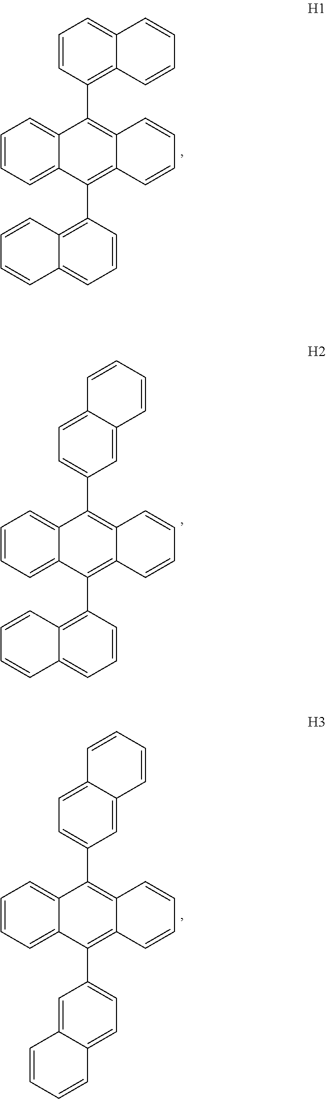

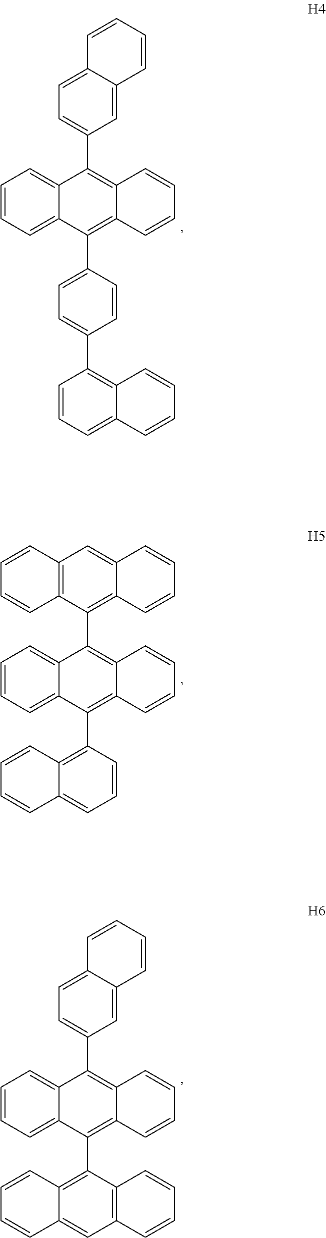

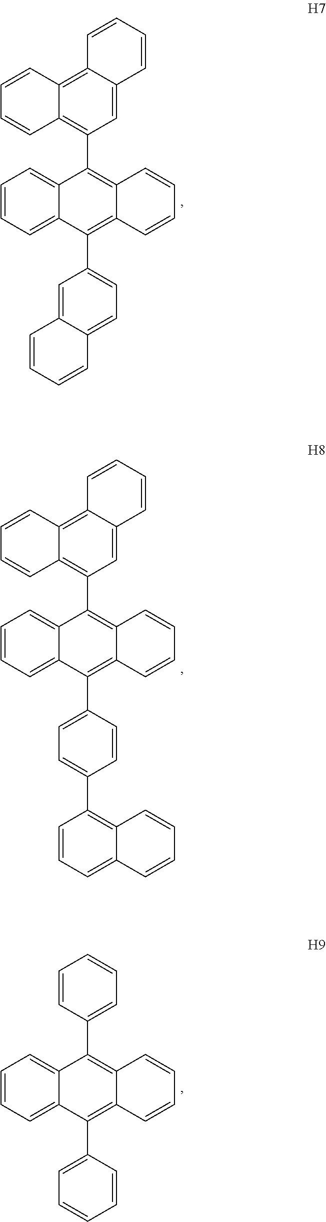

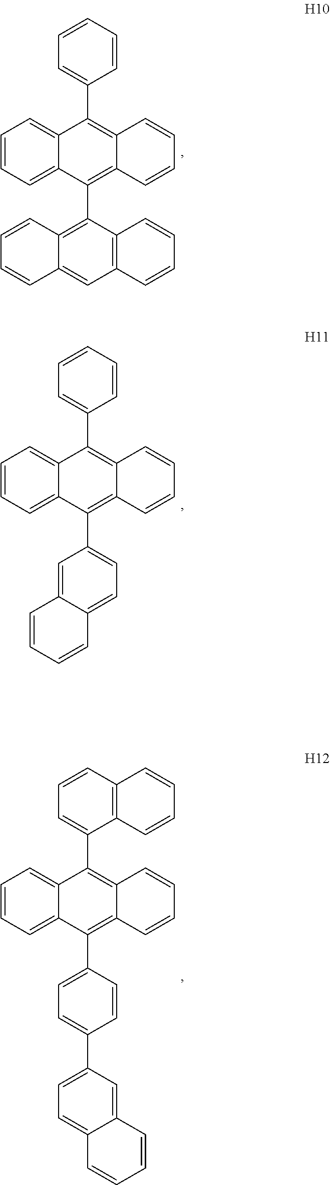

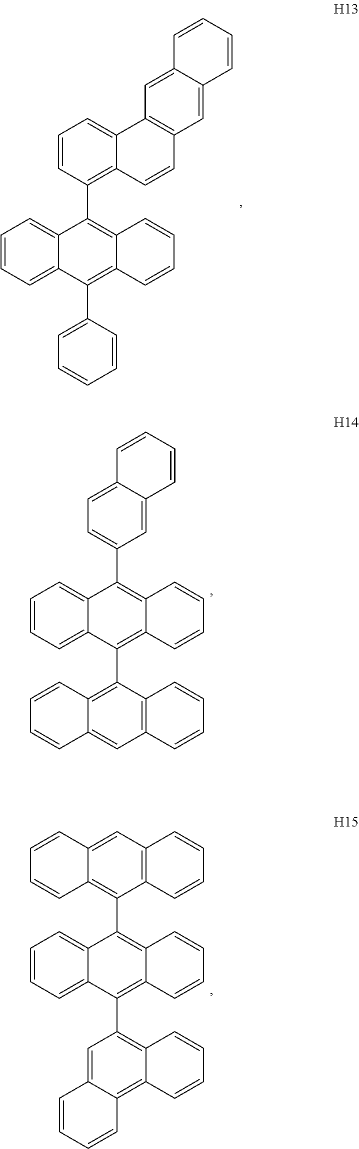

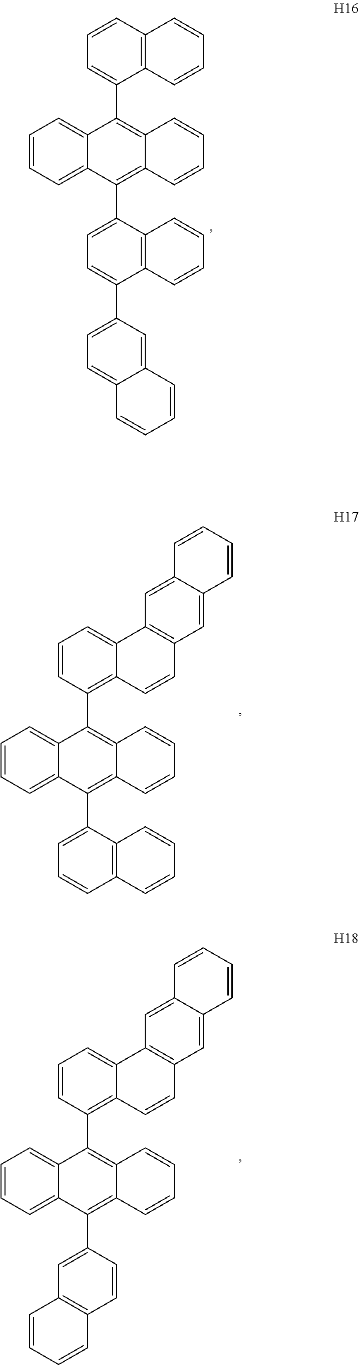

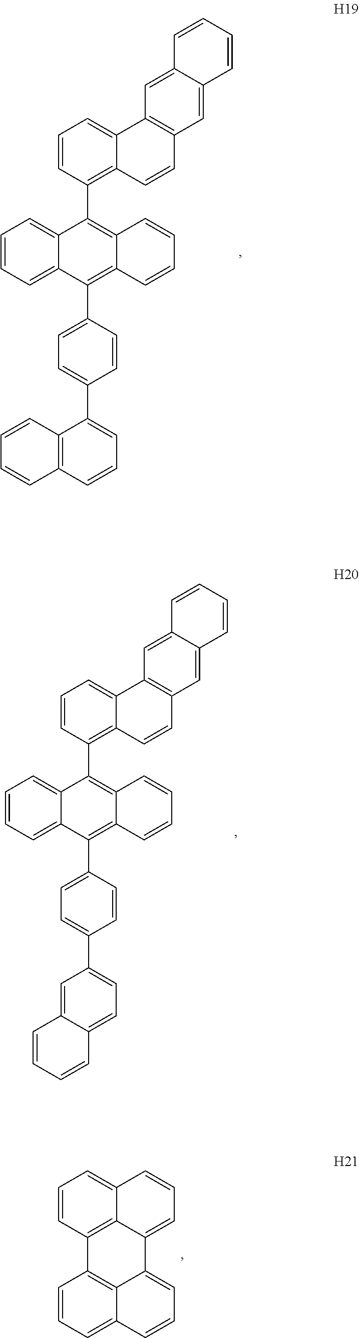

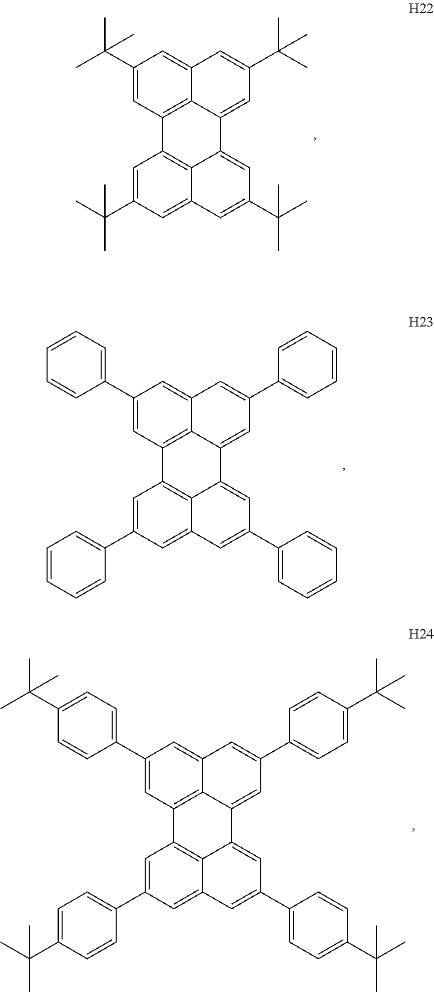

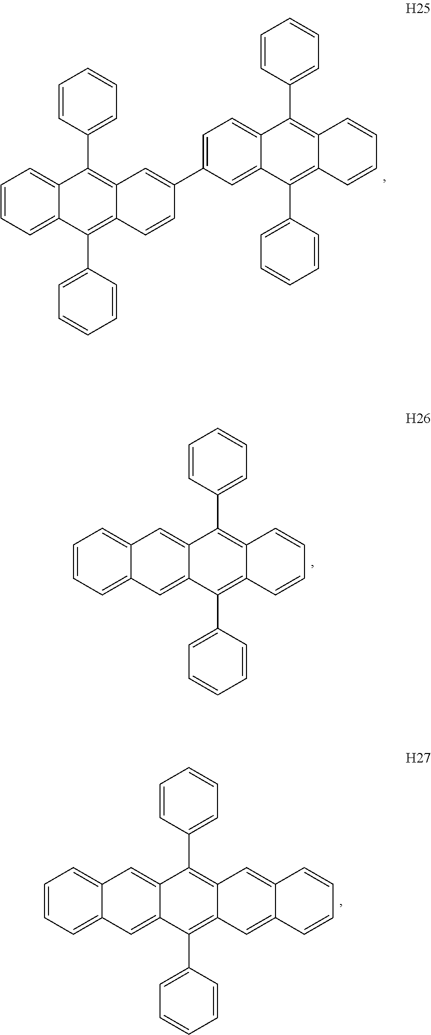

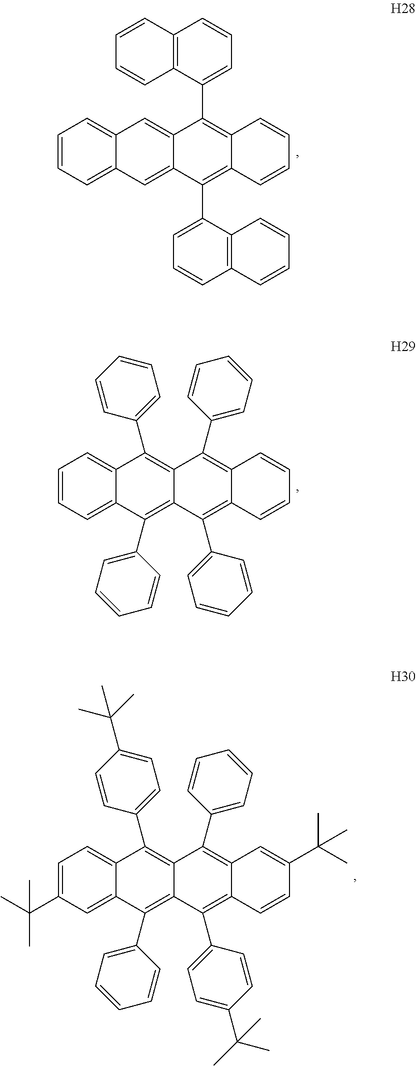

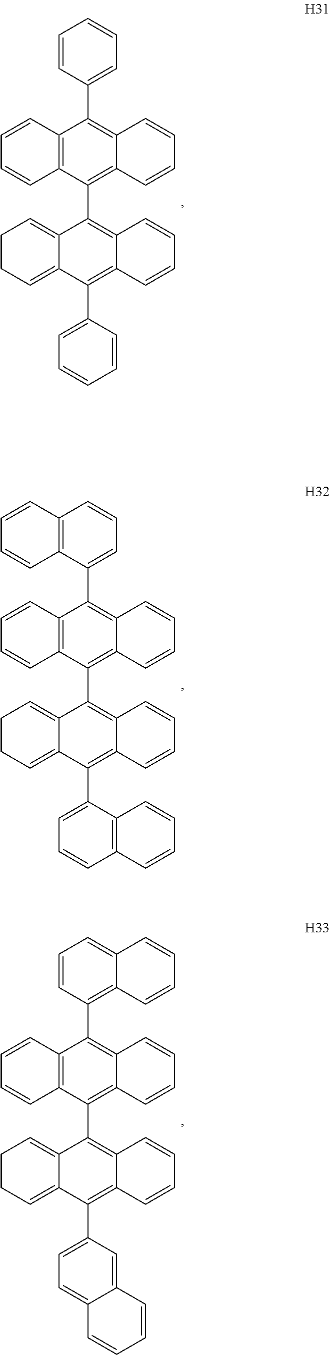

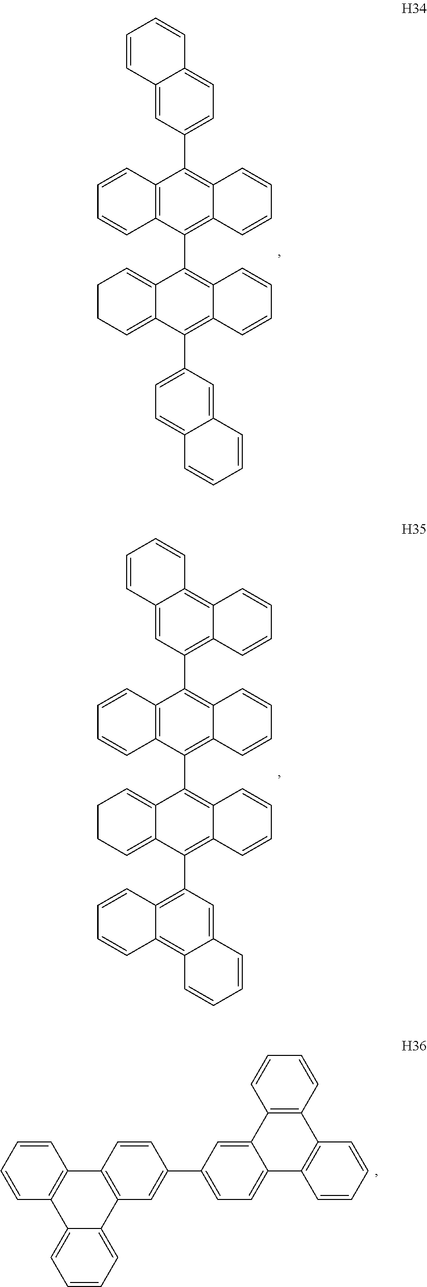

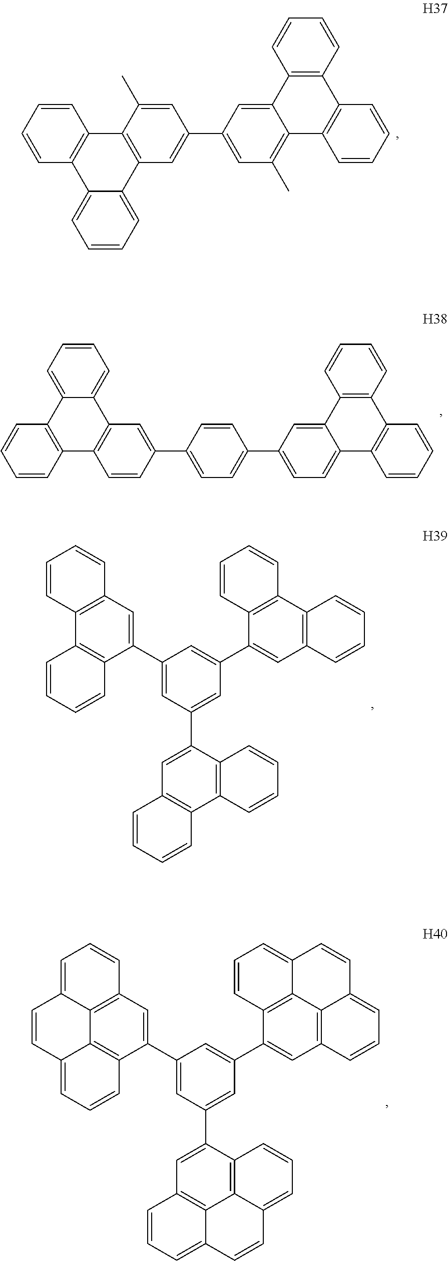

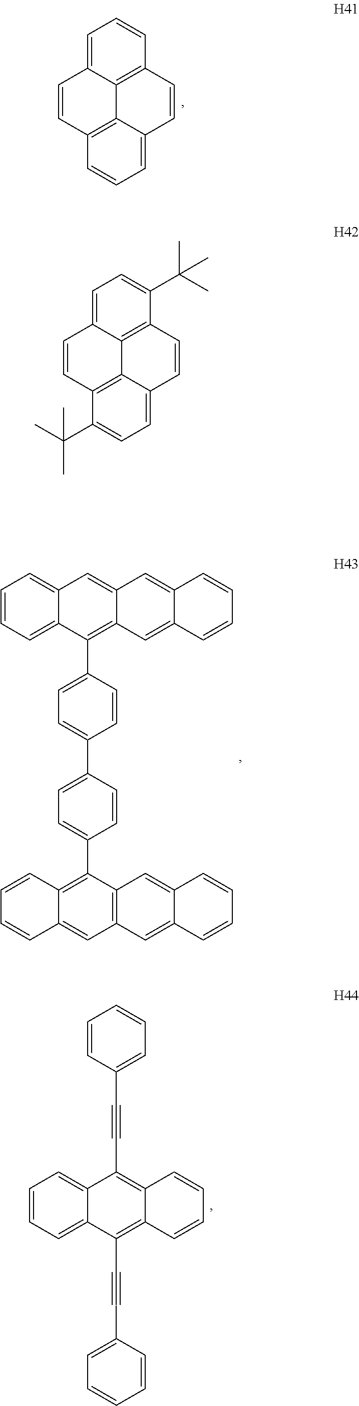

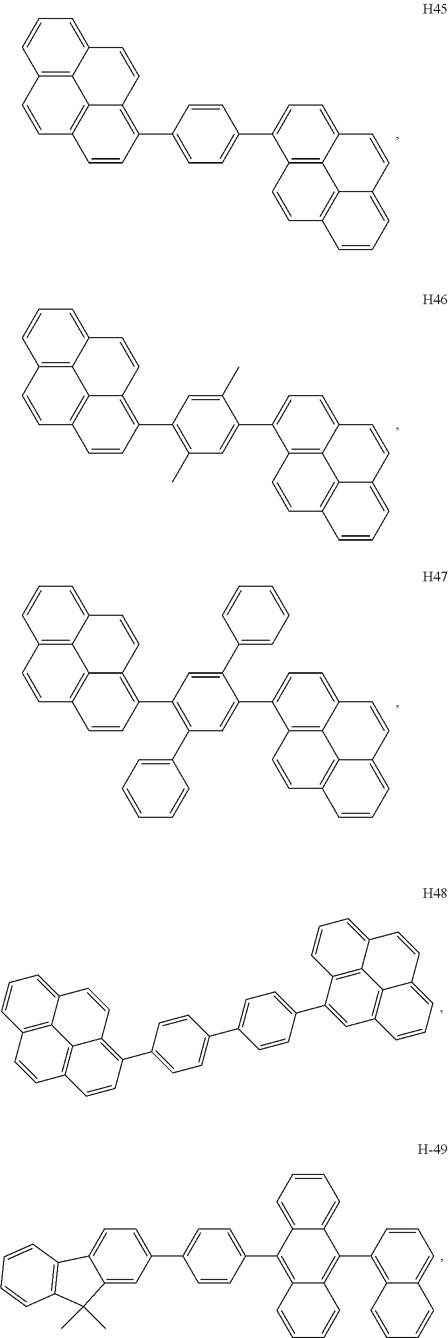

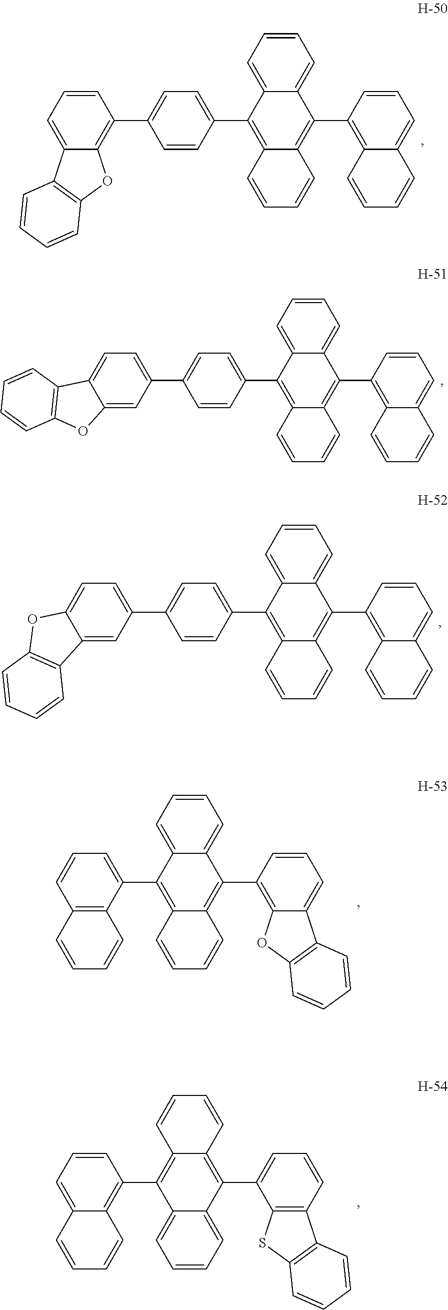 [SMILES: c1ccc2c(-c3c4ccccc4c(-c4ccc(-c5cccc6c5oc5ccccc56)cc4)c4ccccc34)cccc2c1 ; c1ccc2c(-c3c4ccccc4c(-c4ccc(-c5ccc6c(c5)oc5ccccc56)cc4)c4ccccc34)cccc2c1 ; c1ccc2c(-c3c4ccccc4c(-c4ccc(-c5ccc6oc7ccccc7c6c5)cc4)c4ccccc34)cccc2c1 ; c1ccc2c(-c3c4ccccc4c(-c4cccc5c4oc4ccccc45)c4ccccc34)cccc2c1 ; c1ccc2c(-c3c4ccccc4c(-c4cccc5c4sc4ccccc45)c4ccccc34)cccc2c1]

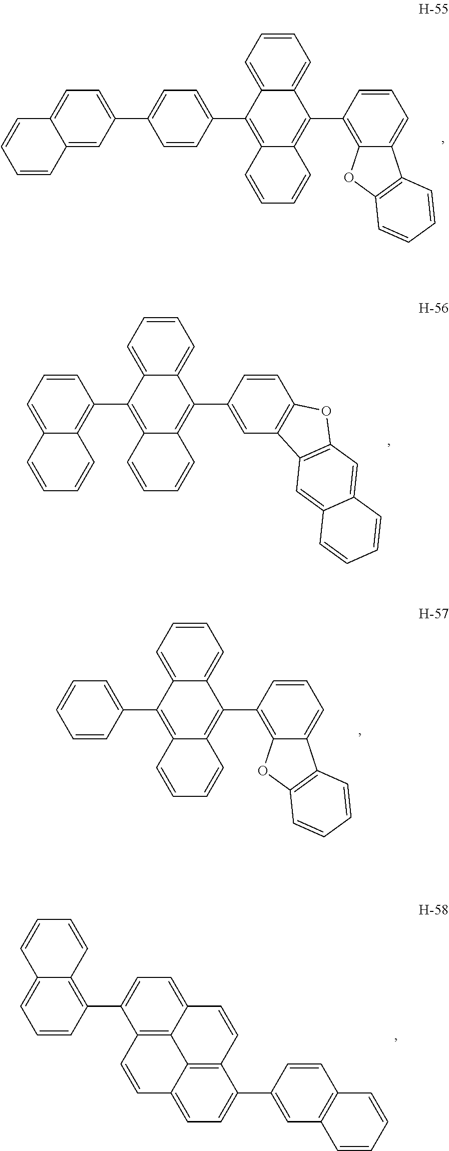

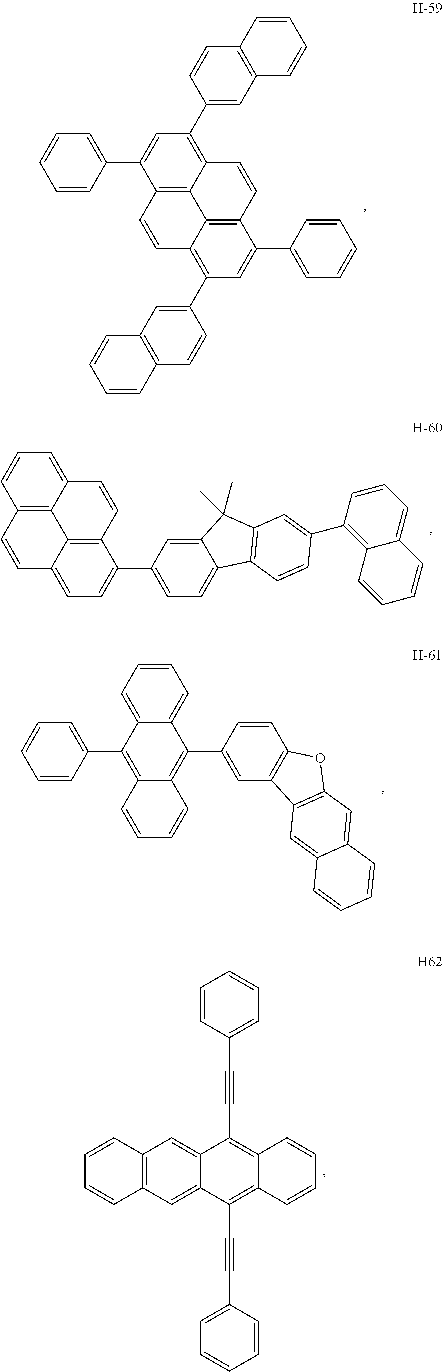

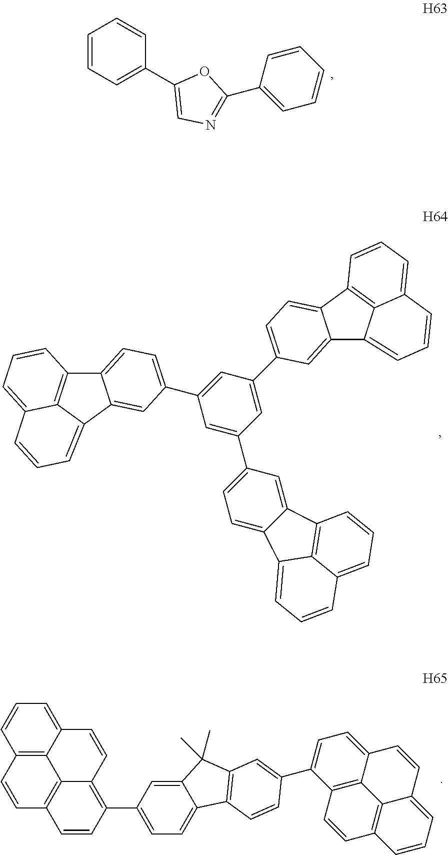

12. The organic electroluminescent device according to claim 1, wherein the thermally activated delayed fluorescence material is a compound having one of the following structures:

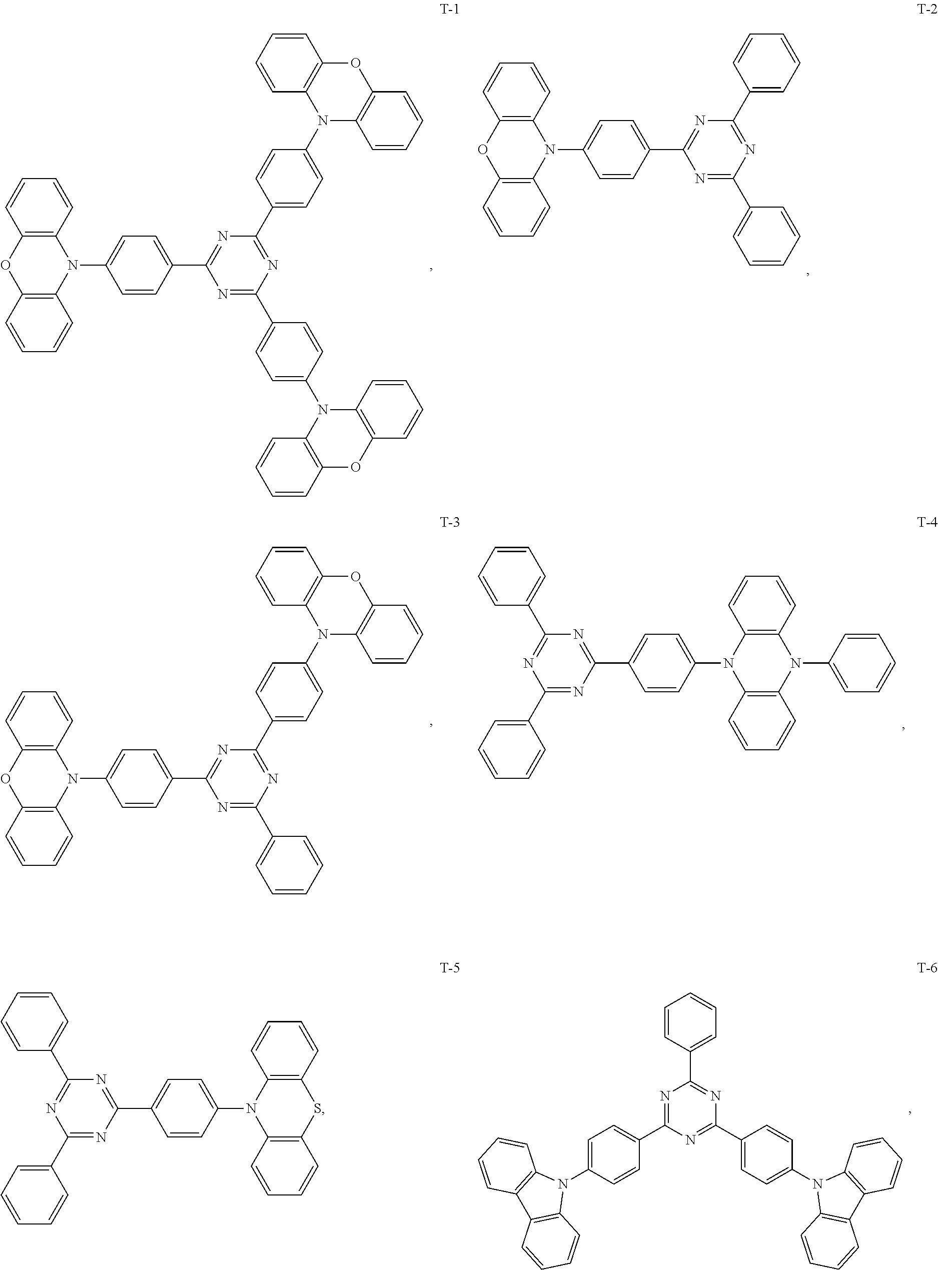 [SMILES: c1ccc2c(c1)Oc1ccccc1N2c1ccc(-c2nc(-c3ccc(N4c5ccccc5Oc5ccccc54)cc3)nc(-c3ccc(N4c5ccccc5Oc5ccccc54)cc3)n2)cc1 ; c1ccc(-c2nc(-c3ccccc3)nc(-c3ccc(N4c5ccccc5Oc5ccccc54)cc3)n2)cc1 ; c1ccc(-c2nc(-c3ccc(N4c5ccccc5Oc5ccccc54)cc3)nc(-c3ccc(N4c5ccccc5Oc5ccccc54)cc3)n2)cc1 ; c1ccc(-c2nc(-c3ccccc3)nc(-c3ccc(N4c5ccccc5N(c5ccccc5)c5ccccc54)cc3)n2)cc1 ; c1ccc(-c2nc(-c3ccccc3)nc(-c3ccc(N4c5ccccc5Sc5ccccc54)cc3)n2)cc1 ; c1ccc(-c2nc(-c3ccc(-n4c5ccccc5c5ccccc54)cc3)nc(-c3ccc(-n4c5ccccc5c5ccccc54)cc3)n2)cc1]

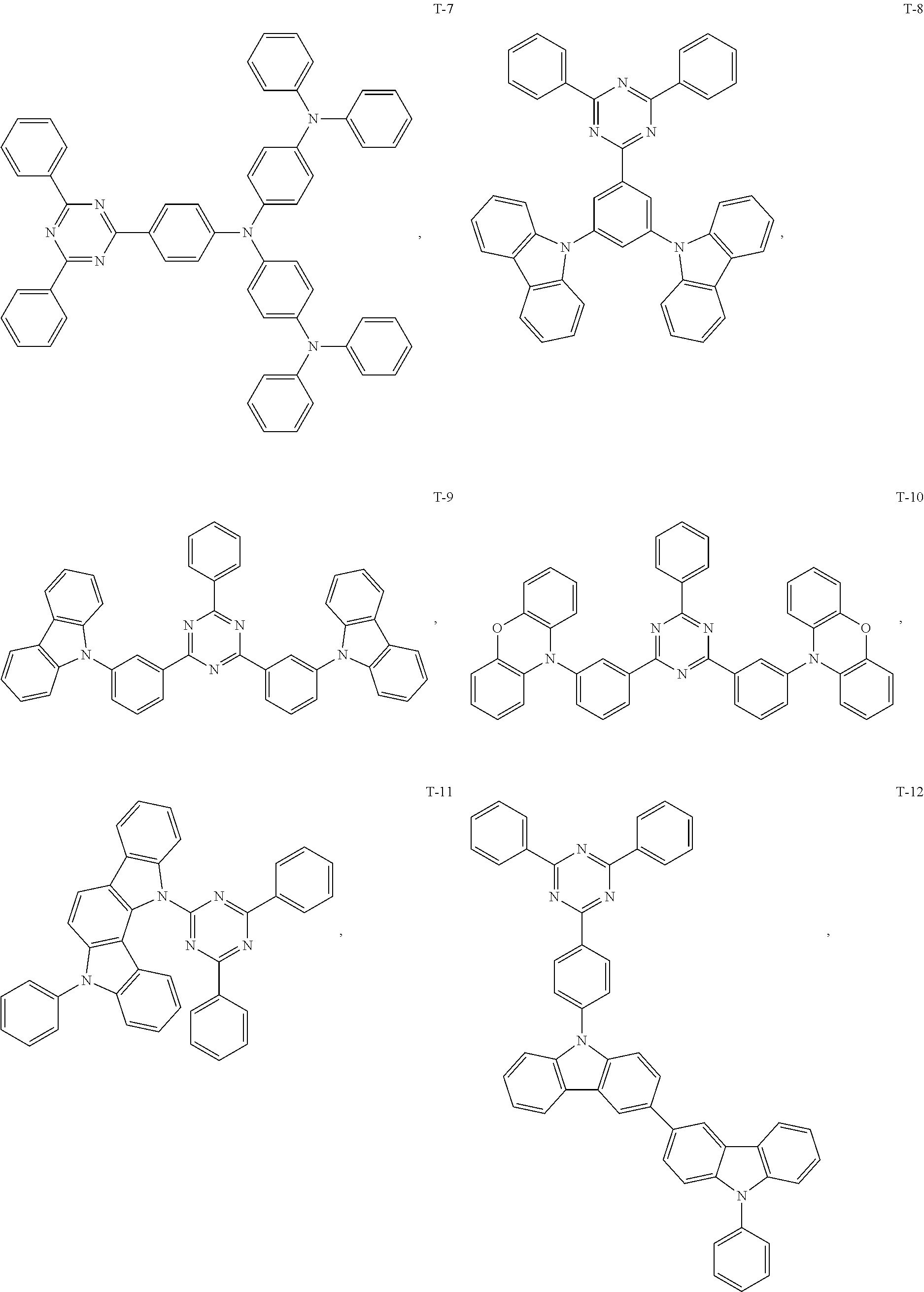

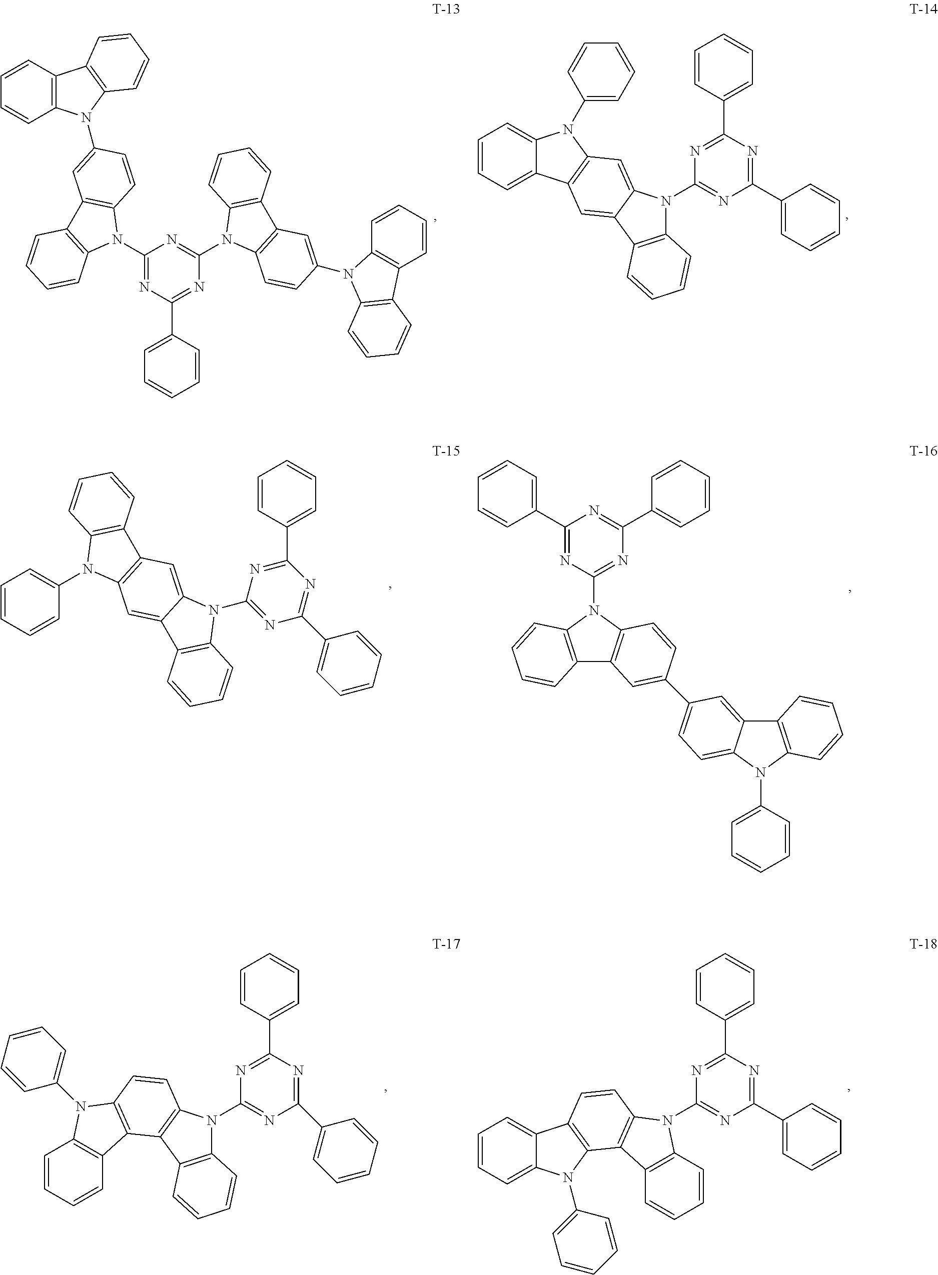

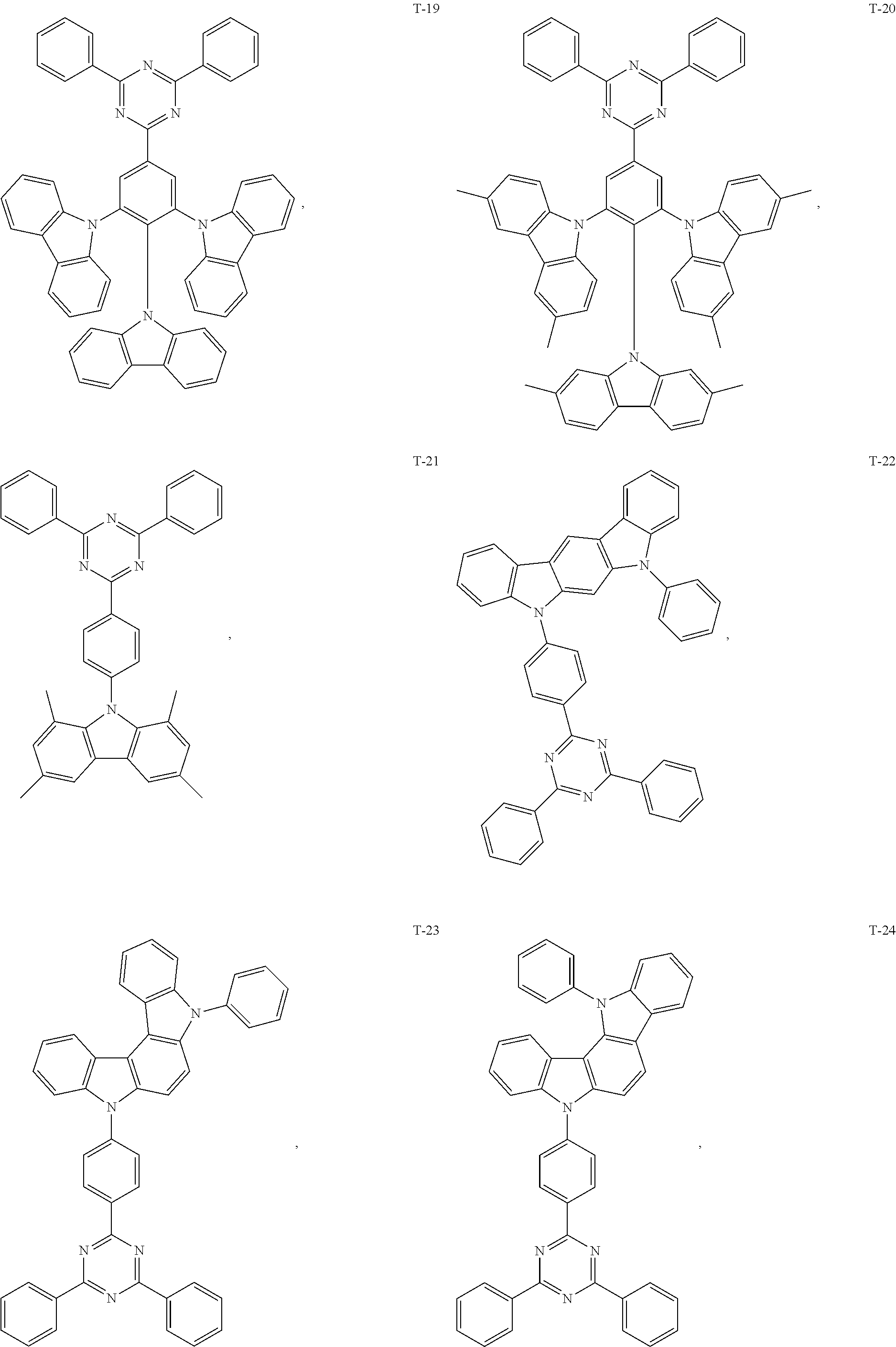

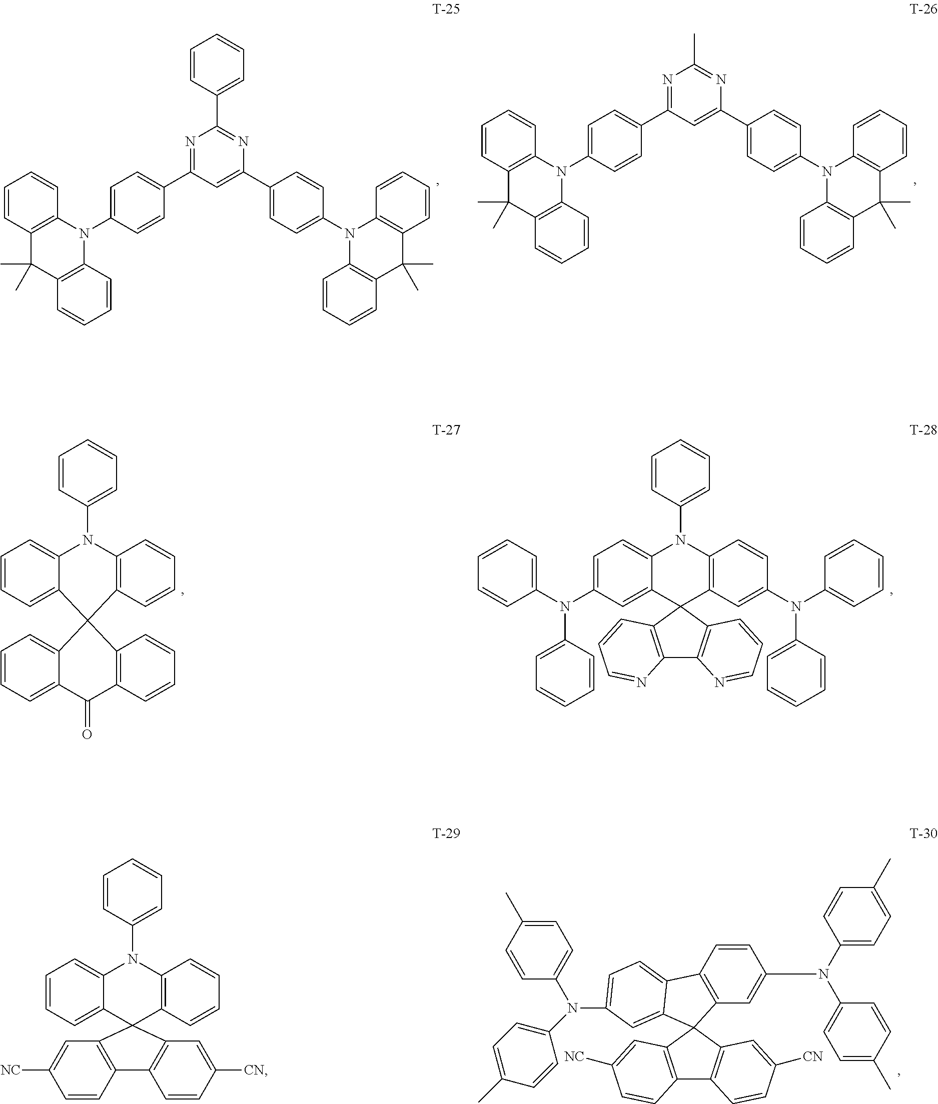

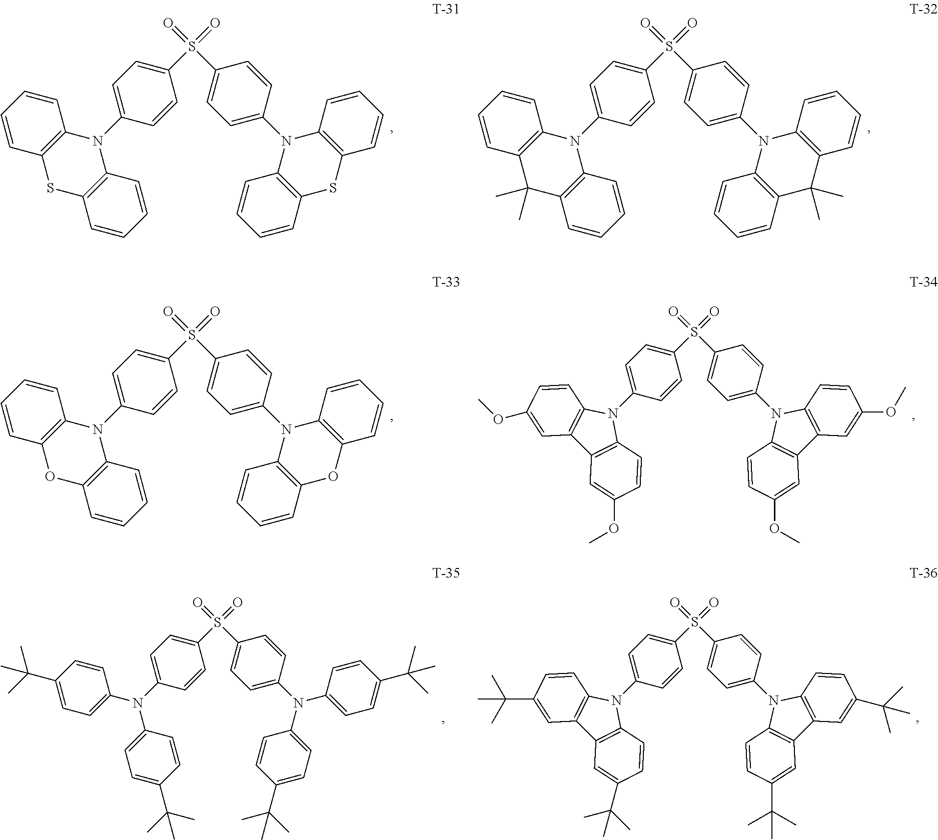

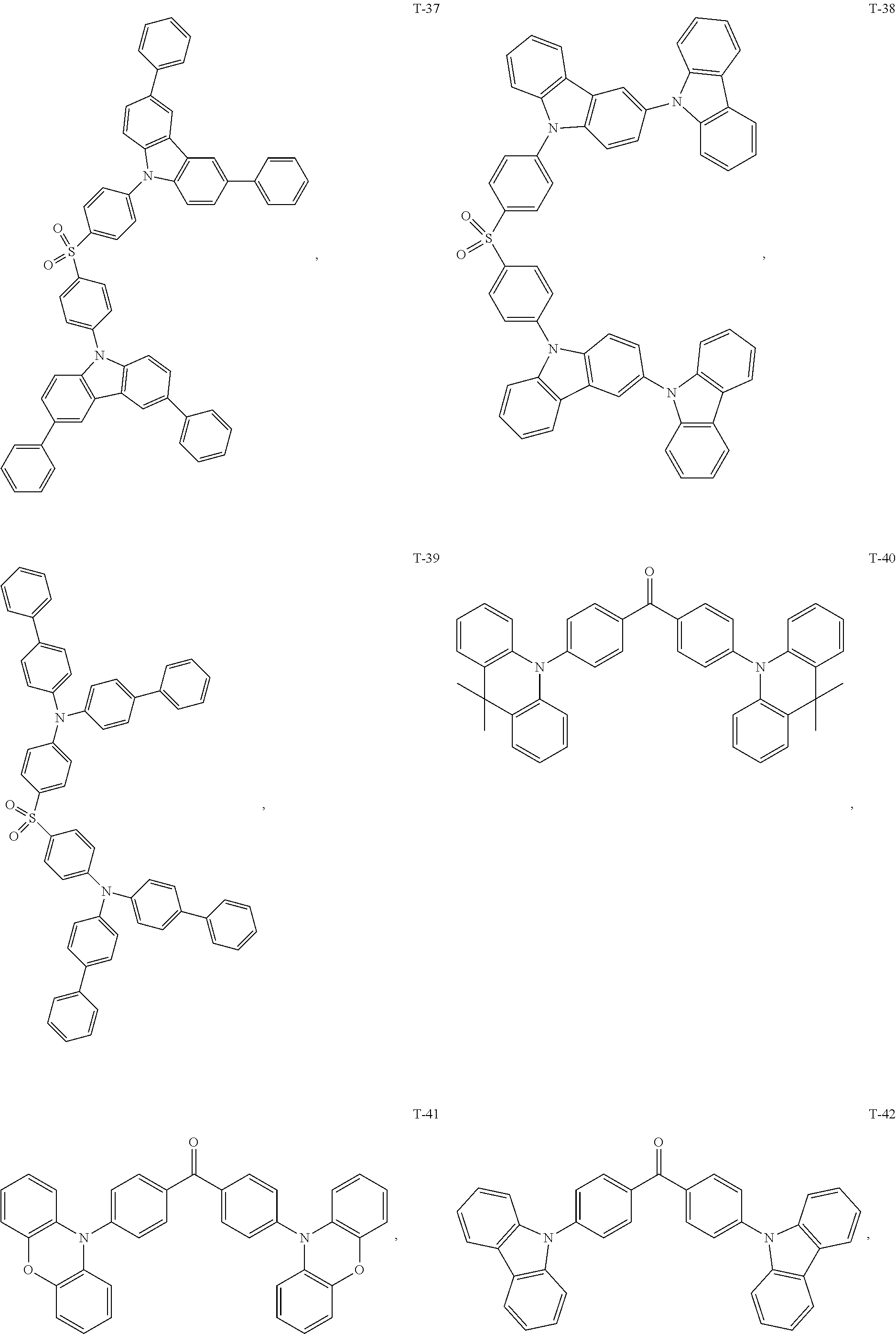

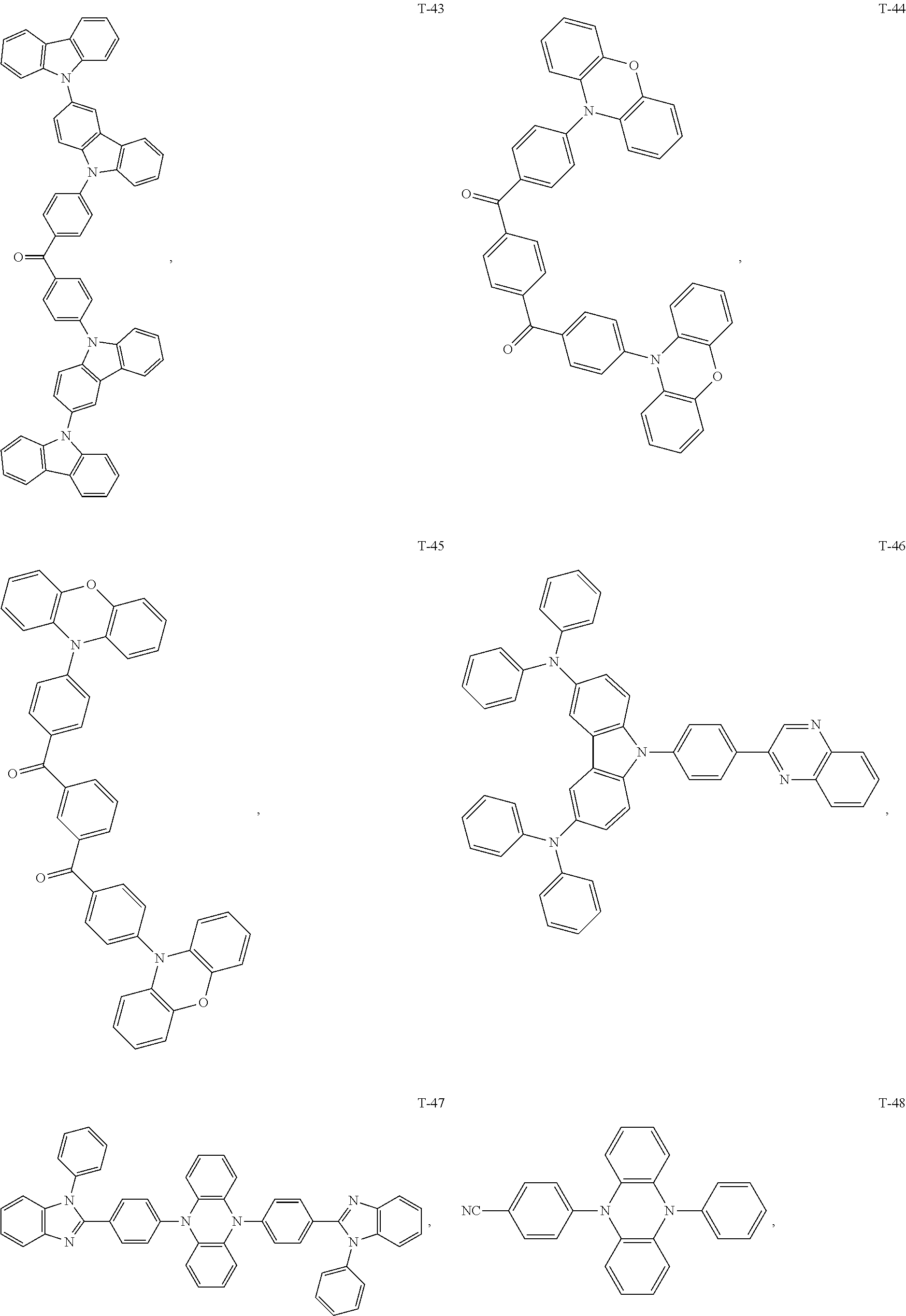

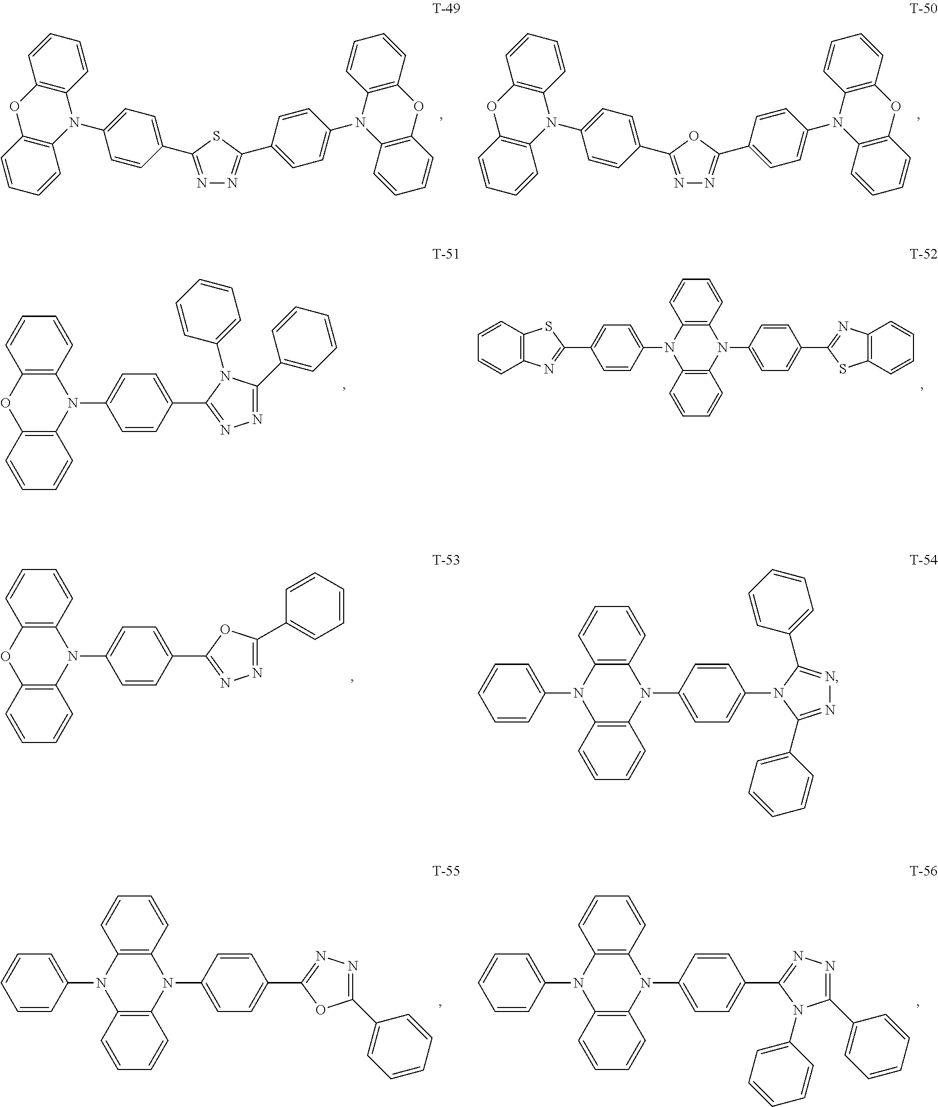

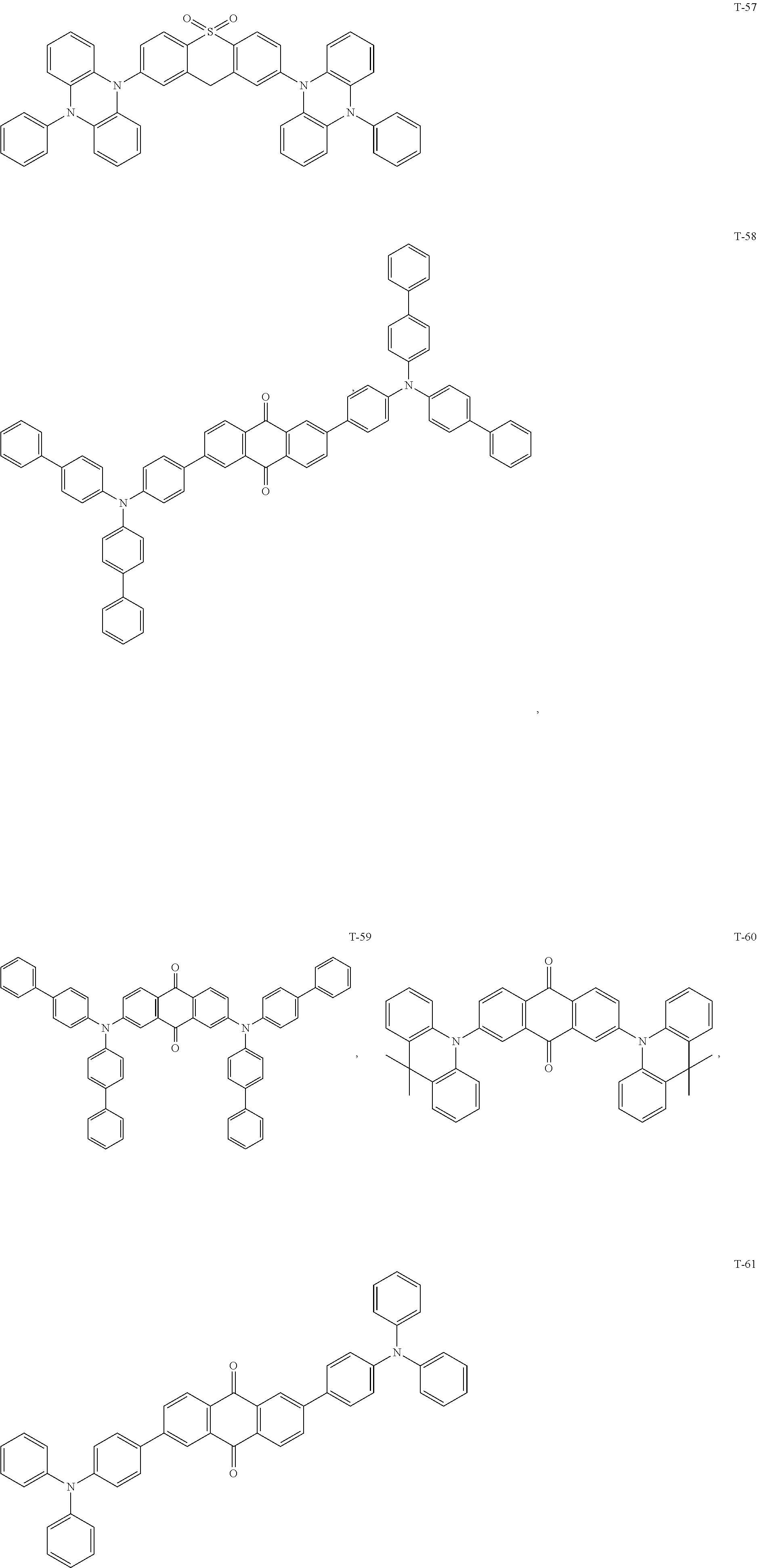

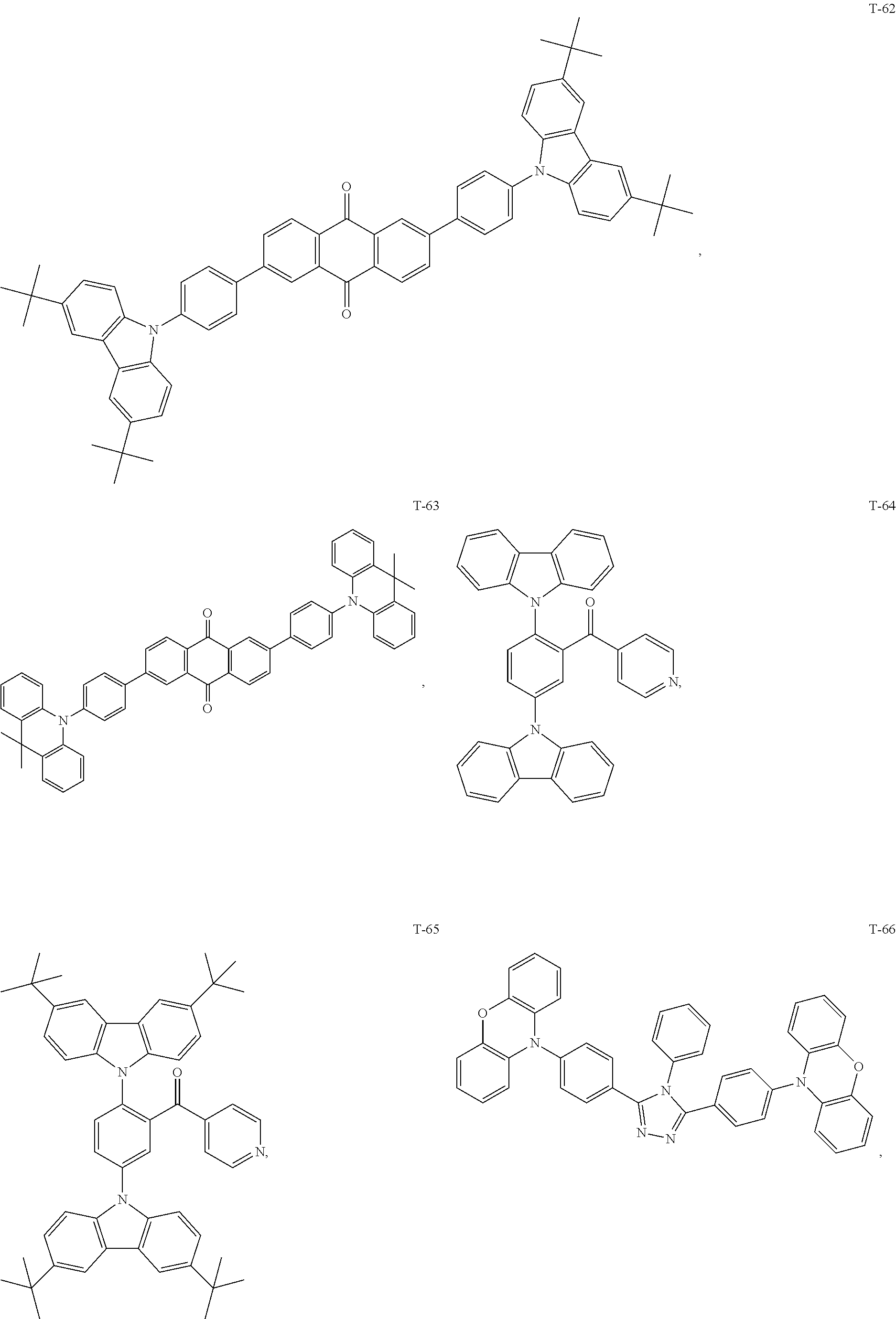

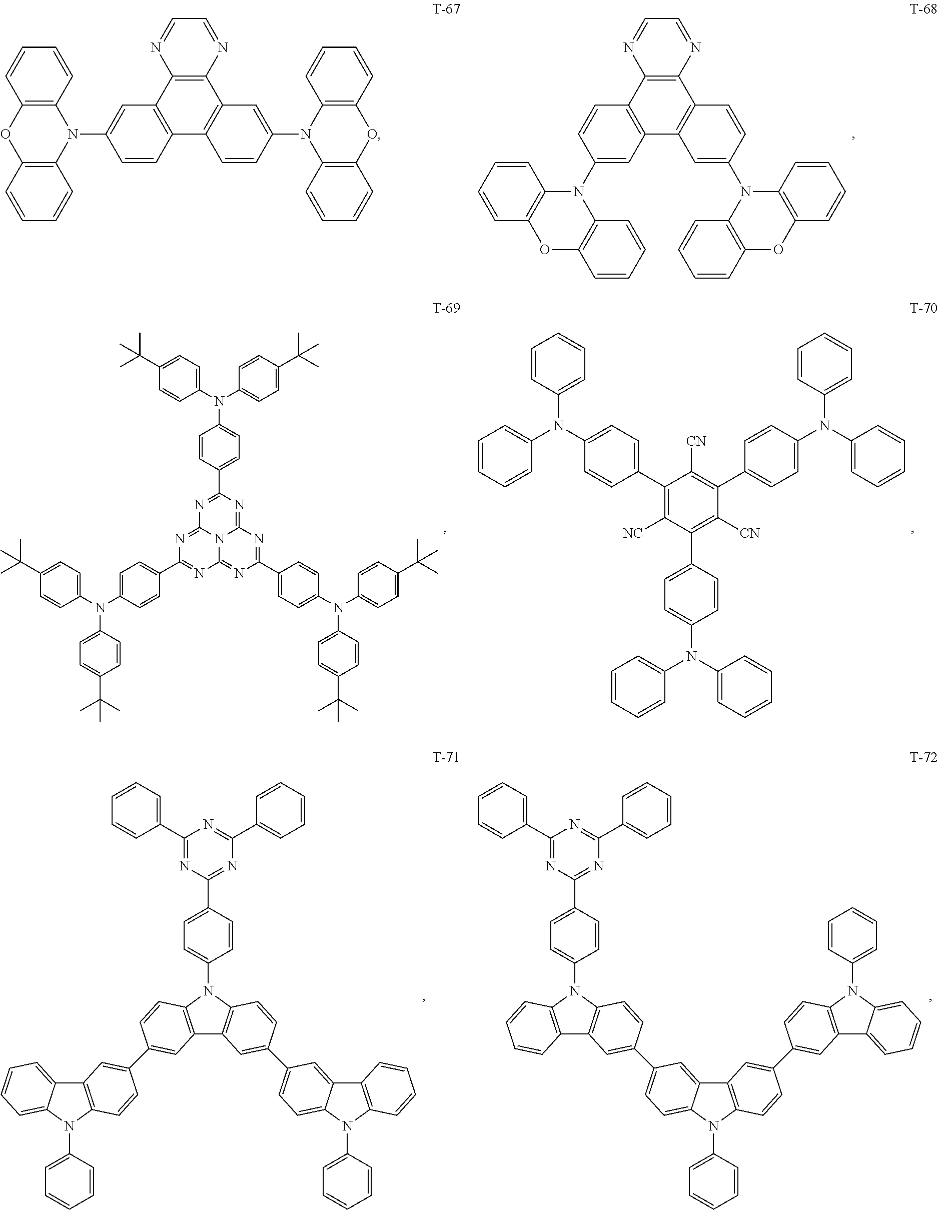

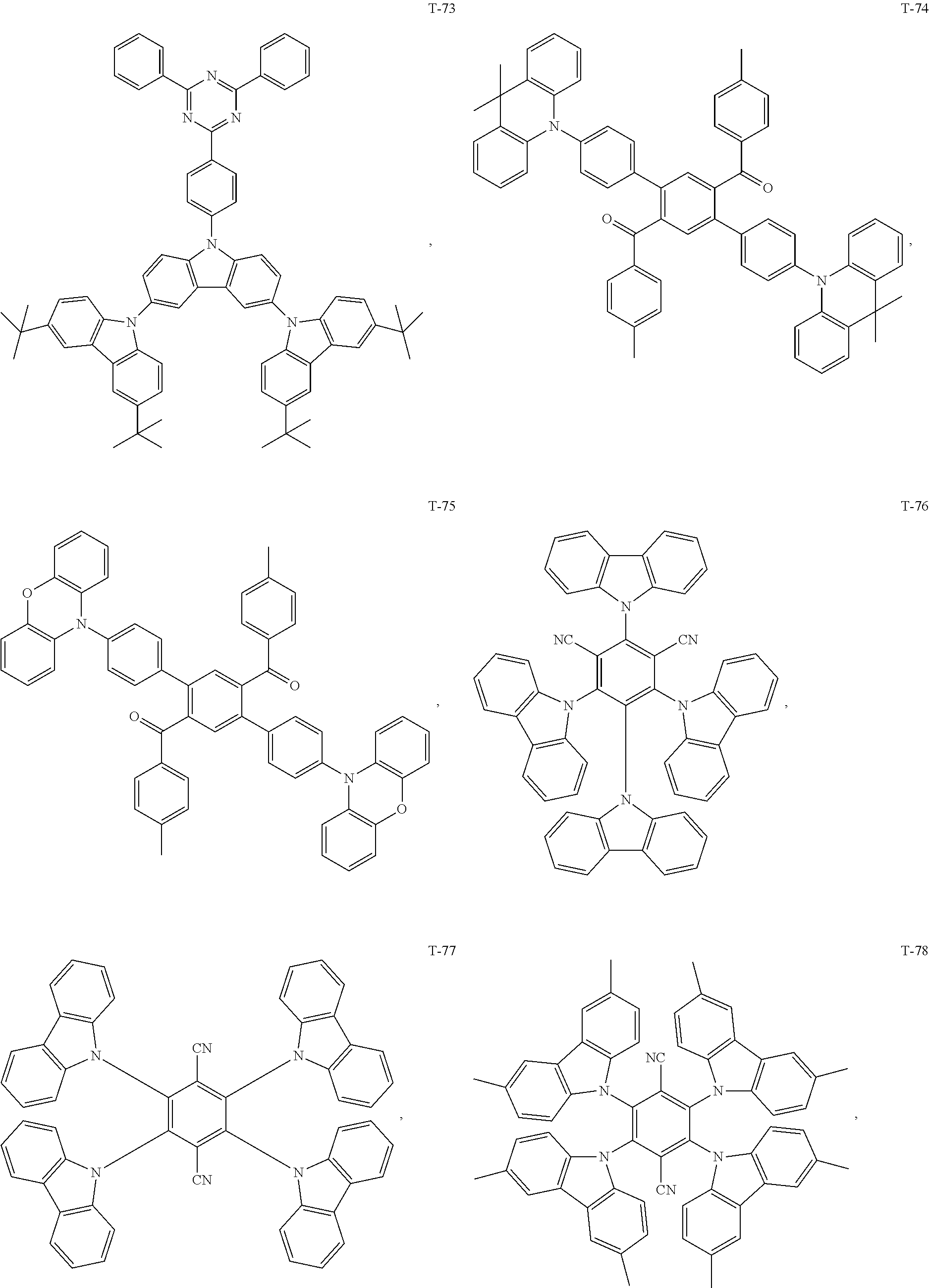

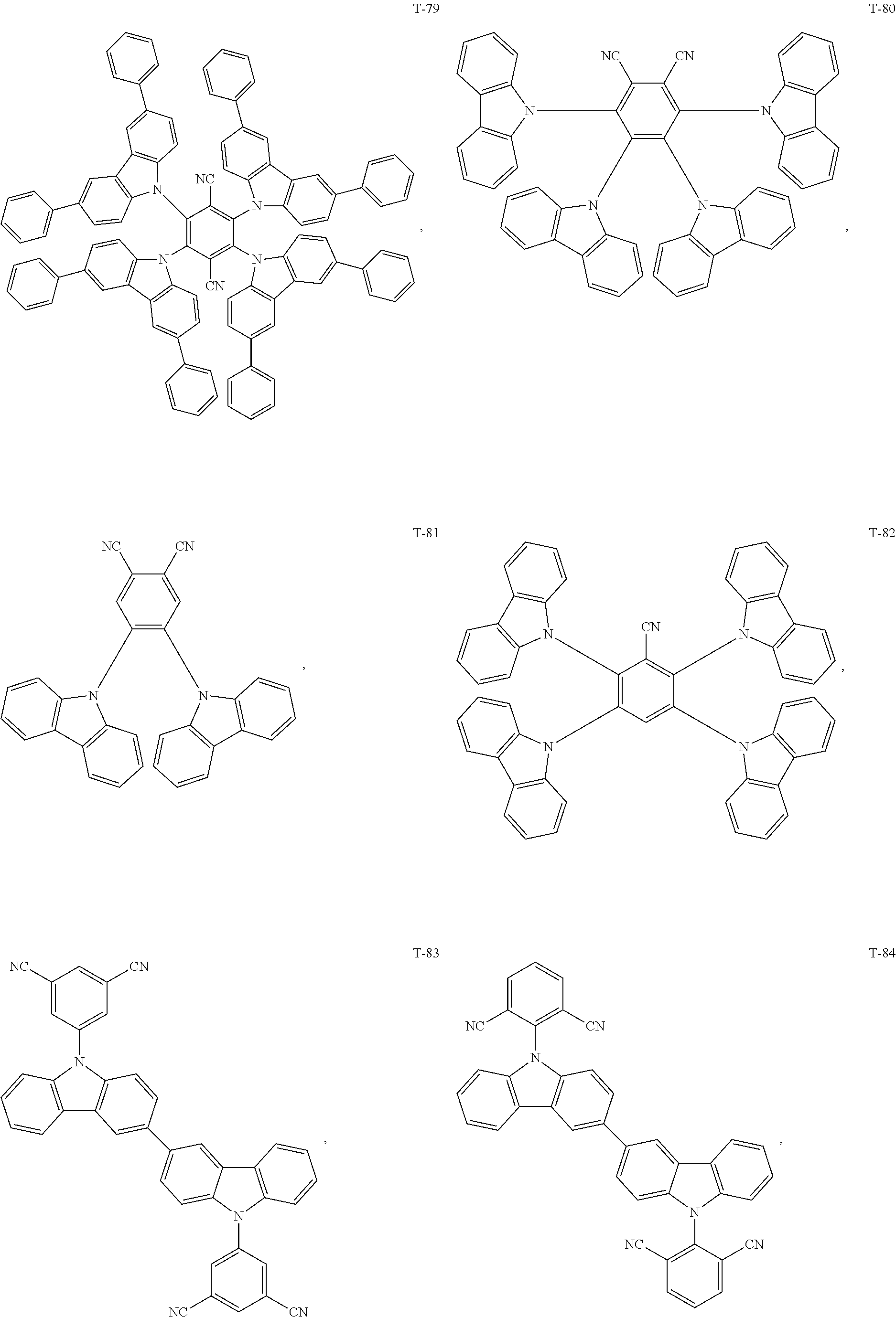

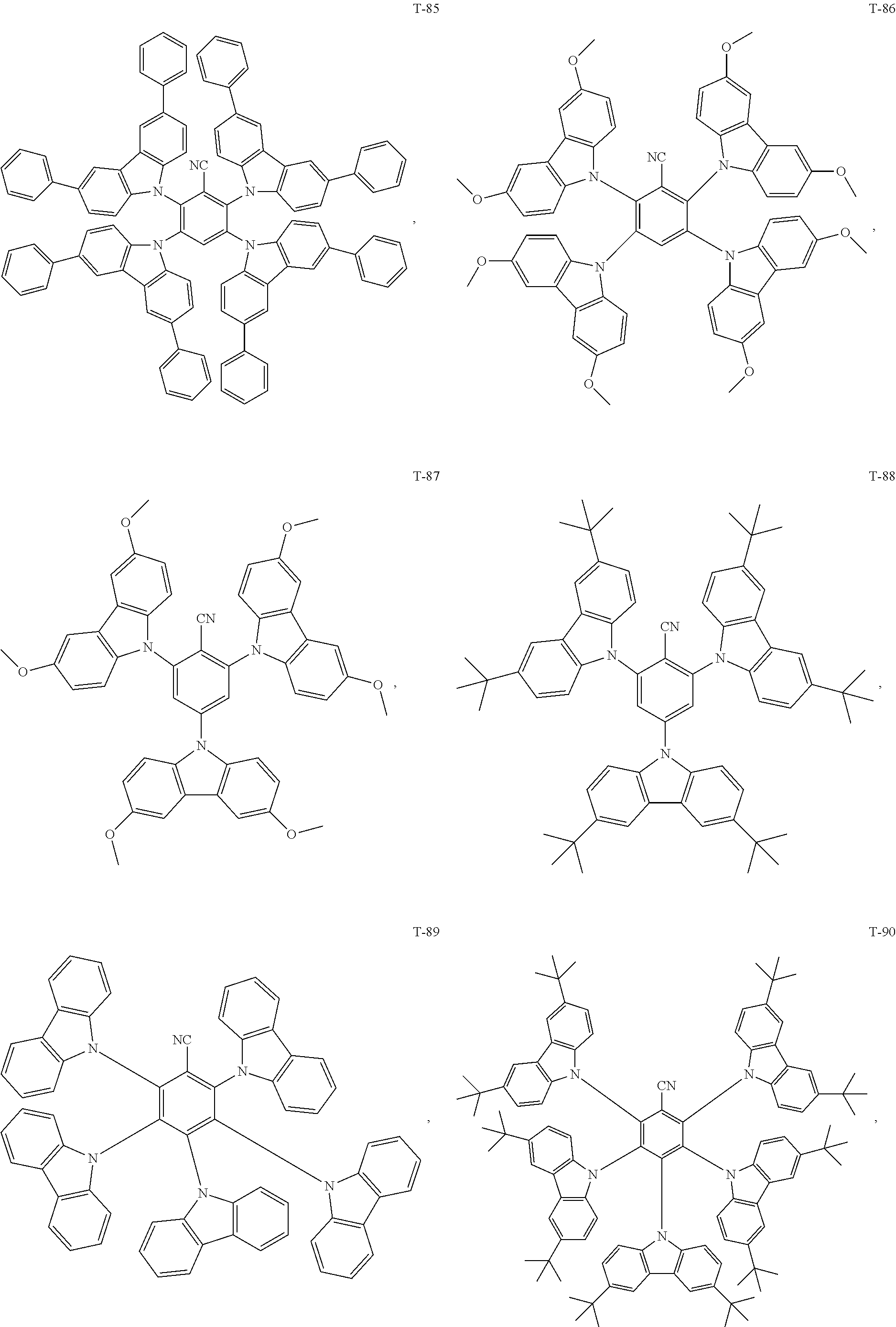

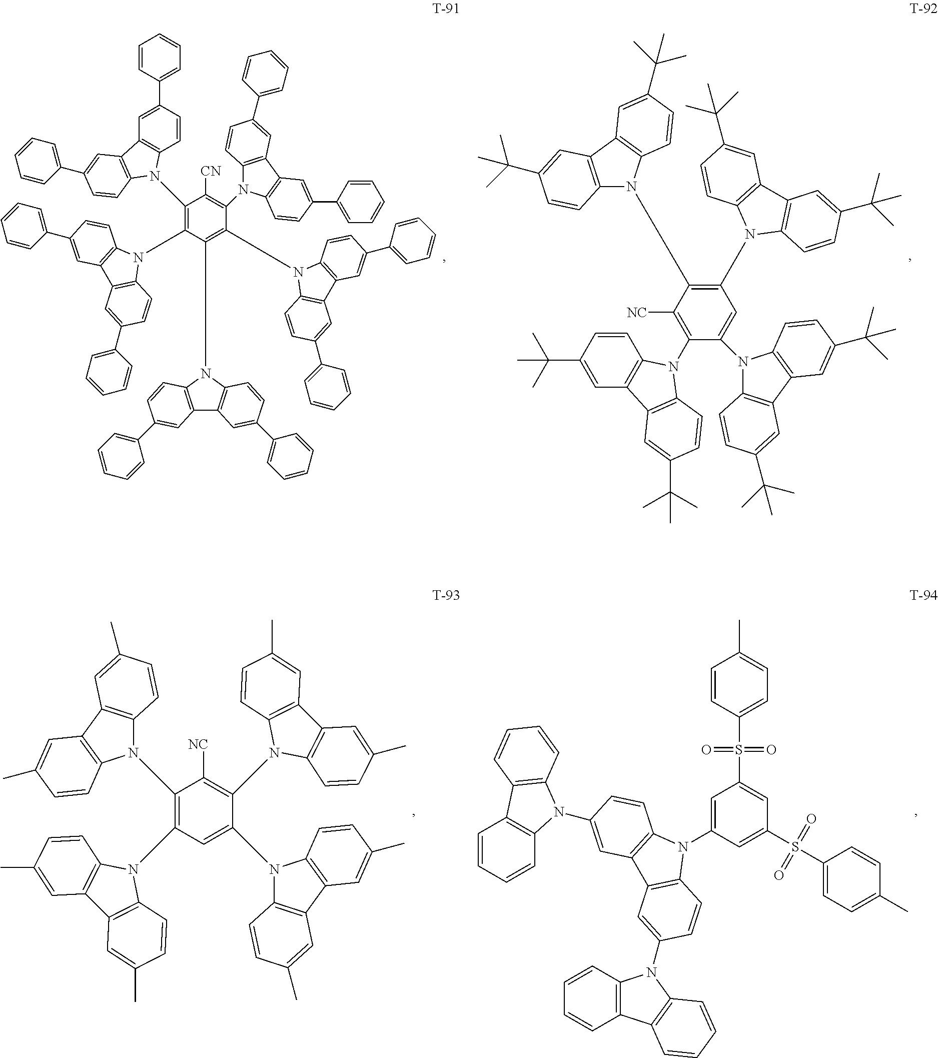

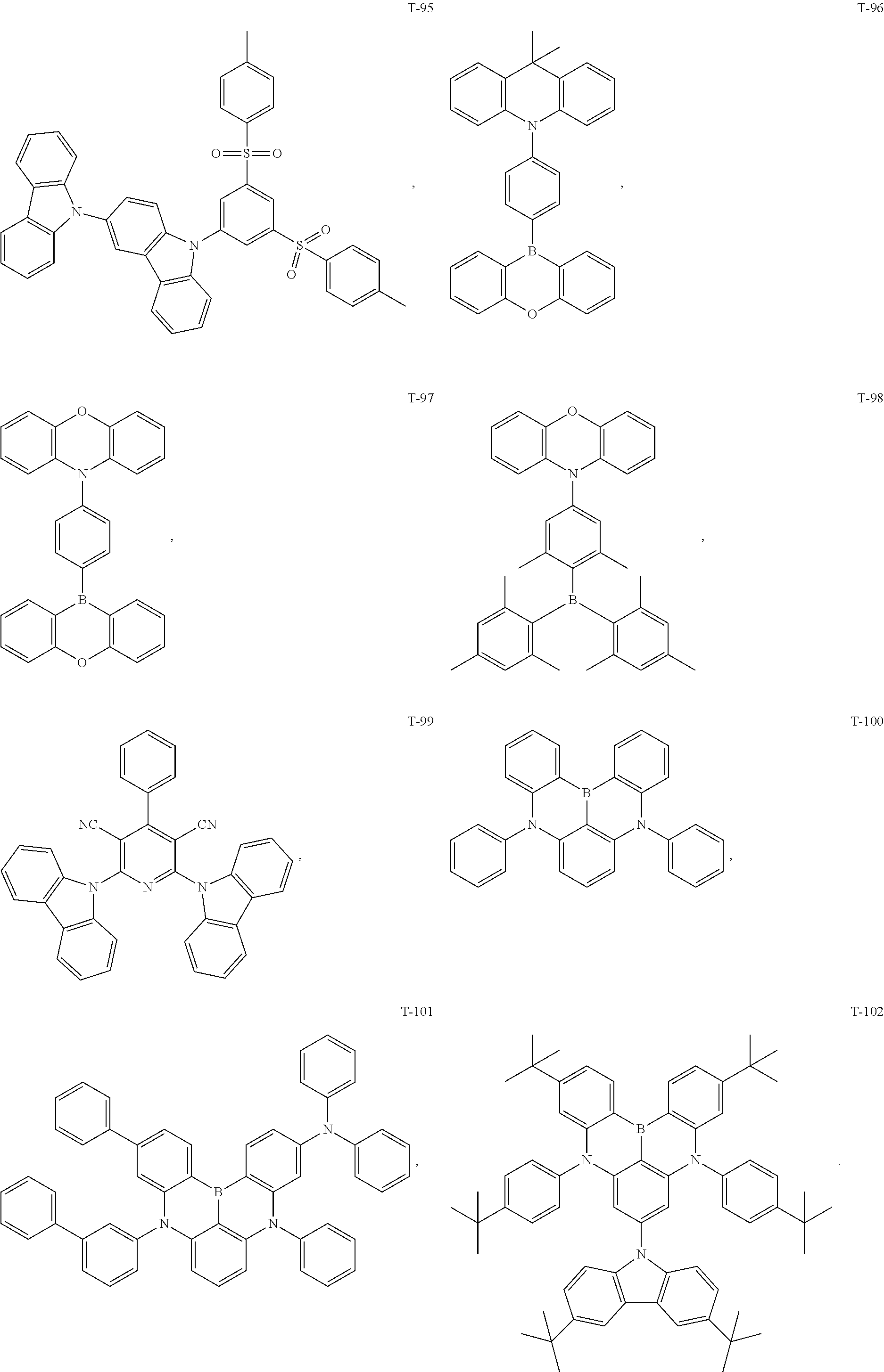

13. The organic electroluminescent device according to claim 1, wherein a thickness of the light emitting layer is 1 nm to 60 nm.

14. The organic electroluminescent device according to claim 13, wherein the thickness of the light emitting layer is 30 nm.

15. A preparation method of an organic electroluminescent device, comprising: forming a light emitting layer by co-evaporation of a triplet-triplet annihilation material source and a thermally activated delayed fluorescence material source.

16. A display apparatus comprising the organic electroluminescent device according to claim 1.
